(19) United States
(12) Patent Application Publication
(10) Pub. No.: US 2020/0407874 A1
(43) Pub. Date: Dec. 31, 2020

(54) METHOD FOR PURIFICATION OF SILICON

(71) Applicant: Silicor Materials Inc., Palo Alto, CA (US)

(72) Inventors: Alain Turenne, Kitchener (CA); Dan Smith, Brampton (CA); Damon Dastgiri, Scarborough (CA); Fritz G. Kirscht, Berlin (DE); Anthony Tummillo, Toronto (CA); Chunhui Zhang, Mississauga (CA); Kamel Ounadjela, Belmont, CA (US)

(21) Appl. No.: 17/018,048

(22) Filed: Sep. 11, 2020

Related U.S. Application Data
(63) Continuation of application No. 16/032,078, filed on Jul. 11, 2018, now abandoned.
Application No. 16/032,078 is a continuation of application No. 14/374,382, filed on Jul. 24, 2014, now abandoned.
(60) Provisional application No. 61/591,073, filed on Jan. 26, 2012.

(51) Int. Cl. C30B 29/06; C30B 33/00; C30B 11/00; C30B 11/02

(52) U.S. Cl. CPC C30B 29/06; C30B 33/00; C30B 11/02; C30B 11/003; C30B 11/002

(57) ABSTRACT

The present invention relates to the purification of silicon. The present invention provides a method for purification of silicon. The method includes recrystallizing starting material-silicon from a molten solvent comprising aluminum to provide final recrystallized-silicon crystals. The method also includes washing the final recrystallized-silicon crystals with an aqueous acid solution to provide a final acid-washed-silicon. The method also includes directionally solidifying the final acid-washed-silicon to provide final directionally solidified-silicon crystals.

### CLAIM OF PRIORITY

This application claims the benefit of priority to U.S. patent application Ser. No. 16/032,078, filed on Jul. 11, 2018, which is a continuation of U.S. patent application Ser. No. 14/374,382, filed Jul. 24, 2014 and now abandoned, which is a National Stage Entry of PCT/US13/23215, filed Jan. 25, 2013, which claims priority to U.S. Provisional Patent Application No. 61/591,073, filed on Jan. 26, 2012, the contents of each of which are hereby incorporated by reference herein in their entireties.

### BACKGROUND OF THE INVENTION

The purification of silicon is an important step in many commercial and industrial processes. The achievement of economical removal of impurities from silicon, thereby increasing its purity, is a major goal in the optimization of these processes. However, efficient methods of separating impurities from silicon, especially on a large-scale, are often both elusive and difficult to employ.

Solar cells are currently utilized as an energy source by using their ability to convert sunlight to electrical energy. Silicon is used almost exclusively as the semiconductor material in such photovoltaic cells. A significant limitation currently on the use of solar cells has to do with the cost of purifying silicon to a high enough grade (e.g. solar grade) that it can be used for the manufacture of solar cells. In view of current energy demands and supply limitations, there is an enormous need for a more cost efficient way of purifying metallurgical grade (MG) silicon (or any other silicon having greater impurities than solar grade) to a high enough grade that it can be used for the manufacture of solar cells.

Several techniques for making purified silicon are known. Most of these techniques operate on the principle that while silicon is solidifying from a molten solution, undesirable impurities tend to remain in the molten solution. For example, the float zone technique can be used to make monocrystalline ingots, and uses a moving liquid zone in a solid material, moving impurities to edges of the material. In another example, the Czochralski technique can be used to make monocrystalline ingots, and uses a seed crystal that is slowly pulled out of a solution, allowing the formation of a monocrystalline column of silicon while leaving impurities in the solution. In yet another example, the Bridgeman or heat exchanger techniques can be used to make multicrystalline ingots, and use a temperature gradient to cause directional solidification.

Crystallization of silicon is one method used to remove undesired impurities. In a crystallization, silicon with impurities is dissolved in a solvent and then caused to crystallize back out of the solution, forming a purer silicon. While crystallization can be an economical manner of purification, certain shortcomings can cause losses in purity and inefficiencies. For example, in a process to crystallize silicon using a metallic solvent such as aluminum, valuable silicon material is left in the aluminum mother liquor along with the impurities. Repeated attempts to fractionally crystallize the silicon can result in a proportionally increasing loss of silicon. In another example, silicon may not cleanly crystallize out of aluminum, but rather crystallize first as the relatively pure desired material, and then upon those crystals a combination of the silicon and impurities such as aluminum form. Sometimes this effect can be accentuated in situations where the yield of the crystalline silicon from the aluminum solution is attempted to be maximized. In other cases, inherent properties of the system of the silicon and the aluminum are such that cleanly stopping the crystallization before the undesired materials are deposited on the pure crystals is difficult or not possible. Even in situations where the crystallization is cleanly stopped before undesired materials crystallize on the surface of the silicon crystals, molten mother liquor that remains on the silicon crystals when they are removed from the mother liquor can solidify, causing a similar negative effect.

Various techniques for making silicon crystals for solar cells utilize a crucible to hold silicon during the molten manufacturing stage. However, there are several disadvantages to the use of standard crucibles. Unfortunately, most crucibles break after a single use due to, for example, the changing size or shape of the molten silicon as it solidifies. Methods of generating monocrystalline ingots can include the use of a quartz crucible, which is a costly and brittle material. Methods of generating multicrystalline ingots generally use a larger crucible, and due to the expense of quartz, these crucibles are often made of cheaper materials such as fused silica or other refractory materials. Despite being made of cheaper materials, large crucibles made of fused silica or other refractories are still costly to produce, and can generally only be used once. The combination of high expense and limited life of crucibles limits the economic efficiency of silicon purification apparatus and methods.

In addition, the material in contact with or nearest a crucible can be contaminated from the crucible or from the coatings of the crucible as it solidifies; this impure material may be trimmed off the solid material after solidification is complete. By solidifying the materials into larger shapes, the surface area of the material that is exposed to air or the crucible or other contaminants during the process can be minimized, therefore material wasted by trimming off material made impure by contamination can be minimized. In another example, the last-to-freeze material often has the highest contaminant concentration can be located at the surfaces of a solidified material, and often these surfaces are also trimmed off a solidified material before use. By having a smaller ratio of surface area to volume, this wasted material is minimized by using larger shapes. Advantages of larger scale have encouraged the use of larger crucibles for formation of ingots from molten materials, especially where the intended use for the resulting ingots requires high-quality ingots. However, the use of a larger crucible can require the purchase of a larger furnace which can be a significant expense.

### SUMMARY OF THE INVENTION

The present invention relates to the purification of silicon. The present invention provides a method for purification of silicon. The method includes recrystallizing starting material-silicon from a molten solvent comprising aluminum to provide final recrystallized-silicon crystals. The method also includes washing the final recrystallized-silicon crystals with an aqueous acid solution to provide a final acid-washed-silicon. The method also includes directionally solidifying the final acid-washed-silicon to provide final directionally solidified-silicon crystals.

Embodiments of the present invention include benefits and advantages such as, for a given cost, lower amounts of impurities and more consistent concentrations of impurities in the purified silicon. The method can provide a purified silicon of more consistent quality at a given cost, which can make the product of the method more valuable than the product of other methods. The method can be more efficient than other methods. Another benefit can include the production of purified silicon that can be used to generate higher quality products, which can be more valuable than other purified silicon products made at similar cost. Embodiments of the method can provide an ingot of superior quality for lower cost, which can be divided into silicon blocks of overall higher quality than those provided by other methods. If used to make solar cells, the silicon blocks derived from the ingot can produce more efficient solar cells at lower cost.

In embodiments that recycle mother liquor in the crystallization steps, the method can waste less of the silicon to be purified, and can make more efficient use of the aluminum solvent. For the acid-washing step, the dissolved or reacted impurities that exit the process can be sold as a value product. In the acid-wash, recycling the aqueous acid and the water backwards through the purification steps can save materials, reducing costs, and can reduce waste. By using cascading steps of dissolution in the acid-wash beginning with the weakest dissolving mixture, exothermic chemical reactions or dissolution can be more easily controlled than in other methods. Some embodiments of the crucible and method can also produce more blocks in a single batch of blocks in a given furnace than similar crucibles and methods. In one example, reusability of the directional solidification apparatus can help enable the method to provide an economically more efficient way of purifying silicon. The reusability of the directional solidification apparatus can help to reduce waste, and can provide a more economical way to use larger crucibles for directional solidification. In some embodiments the directional solidification and the method overall can benefit from the economics of scaling. Additionally, the heater present in some embodiments of the directional solidification apparatus offers a convenient and efficient way to heat the silicon, maintain the temperature of the silicon, control the cooling of the silicon, or a combination thereof, which can allow precise control over the temperature gradient and the corresponding directional solidification of the silicon.

The present invention provides a method for purification of silicon. The method includes recrystallizing starting material-silicon from a molten solvent comprising aluminum to provide final recrystallized-silicon crystals. The method includes washing the final recrystallized-silicon crystals with an aqueous acid solution to provide a final acid-washed-silicon. The method also includes directionally solidifying the final acid-washed-silicon to provide final directionally solidified-silicon crystals.

In some embodiments, the method for purification of silicon can further include sand blasting or ice blasting the final directionally solidified-silicon crystals to provide sand- or ice-blasted final directionally solidified-silicon crystals. The average purity of the sand- or ice-blasted final directionally solidified-silicon crystals is greater than the average purity of the final directionally solidified-silicon crystals.

In some embodiments, the method for purification of silicon can further include removing a portion of the final directionally solidified-silicon crystals to provide a trimmed final directionally solidified-silicon crystals. The average purity of the trimmed final directionally solidified-silicon crystals is greater than the average purity of the final directionally solidified-silicon crystals.

In some embodiments of the method for purification of silicon, the recrystallization of starting material-silicon can include contacting the starting material-silicon with a solvent metal comprising the aluminum. The contacting can be sufficient to provide a first mixture. The recrystallization of starting material-silicon can also include melting the first mixture. The melting of the first mixture can be sufficient to provide a first molten mixture. The recrystallization can also include cooling the first molten mixture. The cooling can be sufficient to form the final recrystallized-silicon crystals and a mother liquor. The recrystallization of starting material-silicon can also include separating the final recrystallized-silicon crystals and the mother liquor. The separation can provide the final recrystallized-silicon crystals.

In some embodiments of the method for purification of silicon, the recrystallization of starting material-silicon can include contacting the starting material-silicon with a first mother liquor. The contacting can be sufficient to provide a first mixture. The recrystallization can also include melting the first mixture. The melting can be sufficient to provide a first molten mixture. The recrystallization can also include cooling the first molten mixture. The cooling can be sufficient to form first silicon crystals and a second mother liquor. The recrystallization can include separating the first silicon crystals and the second mother liquor. The separating can provide the first silicon crystals. The recrystallization can also include contacting the first silicon crystals with a first solvent metal comprising the aluminum. The contacting can be sufficient to provide a second mixture. The recrystallization can also include melting the second mixture. The melting can be sufficient to provide a second molten mixture. The recrystallization can also include cooling the second molten mixture. The cooling can be sufficient to form the final recrystallized-silicon crystals and the first mother liquor. The recrystallization of starting material-silicon can also include separating the final recrystallized-silicon crystals and the first mother liquor. The separating can provide the final recrystallized-silicon crystals.

In some embodiments of the method for purification of silicon, the recrystallization of starting material-silicon can include contacting the starting material-silicon with a second mother liquor. The contacting can be sufficient to provide a first mixture. The recrystallization can include melting the first mixture. The melting can be sufficient to provide a first molten mixture. The recrystallization can include cooling the first molten mixture. The cooling can form first silicon crystals and a third mother liquor. The recrystallization can also include separating the first silicon crystals and the third mother liquor. The separation can provide the first silicon crystals. The recrystallization can also include contacting the first silicon crystals and a first mother liquor. The contacting can be sufficient to provide a second mixture. The recrystallization can also include melting the second mixture. The melting can be sufficient to provide a second molten mixture. The recrystallization can also include cooling the second molten mixture. The cooling can form second silicon crystals and the second mother liquor. The recrystallization can include separating the second silicon crystals and the second mother liquor. The separating can provide the second silicon crystals. The recrystallization can include contacting the second silicon crystals with a first solvent metal comprising the aluminum. The contacting can be sufficient to provide a third mixture. The recrystallization can include melting the third mixture. The melting can be sufficient to provide a third molten mixture. The recrystallization can include cooling the third molten mixture. The cooling can form the final recrystallized-silicon crystals and the first mother liquor. The recrystallization of starting material-silicon can also include separating the final recrystallized-silicon crystals and the first mother liquor. The separating can provide the final recrystallized-silicon crystals.

In some embodiments of the method for purification of silicon, the washing of the final recrystallized-silicon can include combining the final recrystallized-silicon with an acid solution sufficiently to allow the final recrystallized-silicon to react at least partially with the acid solution. The combining can provide a first mixture. The washing can also include separating the first mixture. The separation can provide the final acid-washed silicon.

In some embodiments of the method for purification of silicon, the washing of the final recrystallized-silicon can include combining the final recrystallized-silicon with an acid solution sufficiently to allow the final recrystallized-silicon to react at least partially with the acid solution. The combining can provide a first mixture. The washing can include separating the first mixture. The separating can provide an acid-washed silicon and the acid solution. The washing can include combining the acid-washed silicon with a rinse solution. The combining can provide a fourth mixture. The washing can include separating the fourth mixture. The separating can provide a wet purified silicon and the rinse solution. The washing can include drying the wet purified silicon. The drying can be sufficient to provide the final acid-washed-silicon.

In some embodiments of the method for purification of silicon, the washing of the final recrystallized-silicon can include combining the final recrystallized-silicon with a weak acid solution sufficiently to allow the first complex to react at least partially with the weak acid solution. The combining can provide a first mixture. The washing can include separating the first mixture. The separating can provide a third silicon-aluminum complex and the weak acid solution. The washing can include combining the third silicon-aluminum complex with a strong acid solution sufficiently to allow the third complex to react at least partially with the strong acid solution. The combining can provide a third mixture.

The washing can include separating the third mixture. The separating can provide a first silicon and the strong acid solution. The washing can include combining the first silicon with a first rinse solution. The combining can provide a fourth mixture. The washing can include separating the fourth mixture. The separating can provide a wet purified silicon and the first rinse solution. The washing can include drying the wet purified silicon. The drying can be sufficient to provide the final acid-washed-silicon. In some embodiments, the method of washing can further include separating the first mixture, to provide a second silicon-aluminum complex and the weak acid solution; combining the second silicon-aluminum complex with a medium acid solution sufficiently to allow the second complex to react at least partially with the medium acid solution, to provide a second mixture; and separating the second mixture, to provide a third silicon-aluminum complex and the medium acid solution. In some embodiments, the method of washing can further include separating the fourth mixture, to provide a second silicon and the first rinse solution; combining the second silicon with a second rinse solution, to provide a fifth mixture; and separating the fifth mixture, to provide the wet silicon and the second rinse solution.

In some embodiments of the method for purification of silicon, the washing of the final recrystallized-silicon can include combining the final recrystallized-silicon with a weak HCl solution sufficiently to allow the first complex to react at least partially with the weak HCl solution. The combining can provide a first mixture. The washing can include separating the first mixture. The separating can provide a third silicon-aluminum complex and the weak HCl solution. The washing can include combining the third silicon-aluminum complex with a strong HCl solution sufficiently to allow the third complex to react at least partially with the strong HCl solution. The combining can provide a third mixture. The washing can include separating the third mixture. The separating can provide a first silicon and the strong HCl solution. The washing can include combining the first silicon with a first rinse solution. The combining can provide a fourth mixture. The washing can include separating the fourth mixture. The separating can provide a wet purified silicon and the first rinse solution. The washing can include drying the wet purified silicon. The drying can be sufficient to provide the final acid-washed-silicon. The washing can include removing portions of the weak HCl solution from the weak HCl solution to maintain the pH and specific gravity of the weak HCl solution. The washing can include transferring portions of strong HCl solution to the weak HCl solution to maintain the pH of the weak HCl solution, the volume of the weak HCl solution, the specific gravity of the medium HCl solution, or a combination thereof. The washing can include adding portions of a bulk HCl solution to the strong HCl solution to maintain the pH of the strong HCl solution, the volume of the strong HCl solution, the specific gravity of the strong HCl solution, or a combination thereof. The washing can include transferring portions of the first rinse solution to the strong HCl solution to maintain the pH of the strong HCl solution, the volume of the strong HCl solution, the specific gravity of the strong HCl solution, or a combination thereof. The washing can also include adding fresh water to the second rinse solution to maintain the volume of the second rinse solution.

In some embodiments of the method for purification of silicon, the washing of the final recrystallized-silicon can include combining the final recrystallized-silicon with a weak HCl solution sufficiently to allow the first complex to react at least partially with the weak HCl solution. The combining can provide a first mixture. The washing can include separating the first mixture. The separating can provide a second silicon-aluminum complex and weak HCl solution. The washing can include combining the second silicon-aluminum complex with a medium HCl solution sufficiently to allow the second complex to react at least partially with the medium HCl solution. The combining can provide a second mixture. The washing can include separating the second mixture. The separating can provide a third silicon-aluminum complex and a medium HCl solution. The washing can include combining the third silicon-aluminum complex with a strong HCl solution sufficiently to allow the third complex to react at least partially with the strong HCl solution. The combining can provide a third mixture. The washing can include separating the third mixture. The separating can provide a first silicon and a strong HCl solution. The washing can include combining the first silicon with a first rinse solution. The combining can provide a fourth mixture. The washing can include separating the fourth mixture. The separating can provide a second silicon and a first rinse solution. The washing can include combining the second silicon with a second rinse solution. The combining can provide a fifth mixture. The washing can include separating the fifth mixture. The separating can provide a wet purified silicon and a second rinse solution. The washing can include drying the wet purified silicon. The washing can be sufficient to provide the final acid-washed-silicon. The washing can include removing portions of the weak HCl solution from the weak HCl solution to maintain the pH and specific gravity of the weak HCl solution. The washing can include transferring portions of medium HCl solution to the weak HCl solution to maintain the pH of the weak HCl solution, the volume of the weak HCl solution, the specific gravity of the weak HCl solution, or a combination thereof. The washing can include transferring portions of strong HCl solution to the medium HCl solution to maintain the pH of the medium HCl solution, the volume of the medium HCl solution, the specific gravity of the medium HCl solution, or a combination thereof. The washing can include adding portions of a bulk HCl solution to the strong HCl solution to maintain the pH of the strong HCl solution, the volume of the strong HCl solution, the specific gravity of the strong HCl solution, or a combination thereof. The washing can include transferring portions of the first rinse solution to the strong HCl solution to maintain the pH of the strong HCl solution, the volume of the strong HCl solution, the specific gravity of the strong HCl solution, or a combination thereof. The washing can include transferring portions of the second rinse solution to the first rinse solution to maintain the volume of the first rinse solution. The washing can also include adding fresh water to the second rinse solution to maintain the volume of the second rinse solution.

In some embodiments of the method for purification of silicon, the directional solidification of the final acid-washed-silicon includes two sequential directional solidifications, to provide the final directionally solidified-silicon crystals.

In some embodiments of the method for purification of silicon, the directional solidification of the final acid-washed-silicon includes performing a directional solidification of the final acid-washed-silicon in a crucible. The crucible can include an interior for the production of an ingot. The ingot the crucible can produce can include a multiplicity of blocks. The crucible can also include an exterior shape that approximately matches the interior shape of a furnace wherein the molten material that solidifies to form the ingot is produced.

In some embodiments, the blocks of the ingot can form a grid, wherein compared to a grid in a square-shaped crucible, the percentage of side or center blocks relative to the percentage of corner blocks is increased. In some embodiments, the perimeter of the crucible can include approximately eight major sides, wherein the eight sides comprise two sets of approximately opposing first sides of approximately equal length, and two sets of approximately opposing second sides of approximately equal length, wherein the first sides alternate with the second sides.

In some embodiments of the method for purification of silicon, the directional solidification of the final acid-washed-silicon includes performing a directional solidification of the final acid-washed-silicon in a crucible that includes an interior for the production of an ingot. The crucible can include an exterior shape approximately matching the interior shape of a furnace wherein molten material that solidifies to form the ingot is produced. The ingot can include a multiplicity of blocks. The multiplicity of blocks included in the ingot can form a grid. The exterior shape of the crucible matching the interior shape of the furnace can allow the generation of a larger number of blocks than the number of blocks that can be generated from the furnace using a crucible with a square shape. The interior shape of the furnace can include an approximately round shape. The perimeter of the crucible comprises approximately eight major sides, wherein the eight sides comprise two sets of approximately opposing longer sides of approximately equal length, and two sets of approximately opposing shorter sides of approximately equal length. The longer sides can alternate with the shorter sides.

In some embodiments of the method for purification of silicon, the directional solidification of the final acid-washed-silicon includes performing a directional solidification of the final acid-washed-silicon in an apparatus that includes a directional solidification mold. The directional solidification mold can include at least one refractory material. The apparatus can include an outer jacket. The apparatus can include an insulating layer. The insulating layer can be disposed at least partially between the directional solidification mold and the outer jacket.

In some embodiments of the method for purification of silicon, the directional solidification of the final acid-washed-silicon can include providing a directional solidification apparatus. The apparatus can include a directional solidification mold including at least one refractory material. The apparatus can include an outer jacket. The apparatus can also include an insulating layer disposed at least partially between the directional solidification mold and the outer jacket. The directional solidification can include at least partially melting the final acid-washed-silicon. The melting can provide a first molten silicon. The directional solidification can also include directionally solidifying the first molten silicon in the directional solidification mold. The directional solidification can provide a second silicon. In some embodiments, the directional solidification can also include positioning a heater over the directional solidification mold. The positioning can include positioning one or more heating members selected from a heating element and an induction heater over the directional solidification mold.

In some embodiments of the method for purification of silicon, the directional solidification of the final acid-washed-silicon can include providing a directional solidification apparatus. The apparatus can include a directional solidification mold. The directional solidification mold can include a refractory material. The directional solidification mold can include a top layer. The top layer can include a slip-plane refractory. The top layer can be configured to protect the remainder of the directional solidification mold from damage when directionally solidified silicon is removed from the mold. The directional solidification mold can include an outer jacket. The outer jacket can include steel. The directional solidification mold can include an insulating layer. The insulating layer can include insulating brick, a refractory material, a mixture of refractory materials, insulating board, ceramic paper, high temperature wool, or a mixture thereof. The insulating layer can be disposed at least partially between one or more side walls of the directional solidification mold and one or more side walls of the outer jacket. One or more side walls of the directional solidification mold can include aluminum oxide. A bottom of the directional solidification mold can include silicon carbide, graphite, or a combination thereof. The apparatus can also include a top heater. The top heater can include one or more heating members. Each of the heating members can include a heating element or an induction heater. The heating element can include silicon carbide, molybdenum disilicide, graphite, or a combination thereof. The top heater can include insulation. The insulation can include insulating brick, a refractory, a mixture of refractories, insulating board, ceramic paper, high temperature wool, or a combination thereof. The top heater can include an outer jacket. The outer jacket can include stainless steel. The insulation can be disposed at least partially between the one or more heating members and the top heater outer jacket. The apparatus can be configured to be used more than twice for the directional solidification of silicon.

### BRIEF DESCRIPTION OF THE FIGURES

In the drawings, which are not necessarily drawn to scale, like numerals describe substantially similar components throughout the several views. Like numerals having different letter suffixes represent different instances of substantially similar components. The drawings illustrate generally, by way of example, but not by way of limitation, various embodiments discussed in the present document.

FIG. 1 illustrates a block flow diagram of a method of purifying silicon, according to some embodiments.

FIG. 2 A illustrates a block flow diagram of a single pass recrystallization, according to some embodiments.

FIG. 2B illustrates a block flow diagram of a double pass recrystallization, according to some embodiments.

FIG. 3 illustrates a block flow diagram of a triple pass recrystallization cascade process, according to some embodiments.

FIG. 4 illustrates a diagram of a triple pass recrystallization cascade process, according to some embodiments.

FIG. 5 illustrates a diagram of a triple pass recrystallization cascade process, according to some embodiments.

FIG. 6 illustrates a first pass detail of a recrystallization cascade process, according to some embodiments.

FIG. 7 illustrates a block flow diagram of a triple pass recrystallization cascade process, according to some embodiments.

FIG. 8 illustrates a diagram of a quadruple pass recrystallization cascade process, according to some embodiments.

FIG. 9 shows a general flow diagram of the acid washing step, according to some embodiments.

FIG. 10 shows a flow diagram of the acid washing step, according to some embodiments.

FIG. 11 shows a decision tree describing when to remove portions of the weak acid solution in the acid washing step, according to some embodiments.

FIG. 12 shows a flow diagram of the acid washing step, according to some embodiments.

FIG. 13 shows a top-view of a 32 block 156 mm×156 mm crucible according to some embodiments.

FIG. 14 shows top-view of a 32 block 156 mm×156 mm ingot in a crucible according to some embodiments.

FIG. 15 shows a side-view of the crucible 100 according to some embodiments.

FIG. 16 illustrates a cross-sectional view of a mold, an outer jacket and an insulating layer of an apparatus for directional solidification of silicon, according to some embodiments.

FIG. 17 illustrates a cross-sectional view of a mold, an outer jacket and an insulating layer of an apparatus for directional solidification of silicon, according to some embodiments.

FIG. 18 illustrates a cross-sectional view of a heater of an apparatus for directional solidification of silicon, according to some embodiments.

FIG. 19 illustrates a 3D projection of an apparatus for directional solidification of silicon, including a heater positioned on top of a mold, according to some embodiments.

FIG. 20 illustrates an isometric view of a heater of an apparatus for directional solidification of silicon, according to some embodiments.

FIG. 21 illustrates an isometric view of a mold of an apparatus for directional solidification of silicon, according to some embodiments.

FIG. 22 illustrates a silicon ingot generated by an apparatus and method of the present invention, according to some embodiments.

### DETAILED DESCRIPTION OF THE INVENTION

Reference will now be made in detail to certain claims of the disclosed subject matter, examples of which are illustrated in the accompanying drawings. While the disclosed subject matter will be described in conjunction with the enumerated claims, it will be understood that they are not intended to limit the disclosed subject matter to those claims. On the contrary, the disclosed subject matter is intended to cover all alternatives, modifications, and equivalents, which can be included within the scope of the presently disclosed subject matter as defined by the claims.

References in the specification to “one embodiment,” “an embodiment,” “an example embodiment,” etc., indicate that the embodiment described can include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

In this document, the terms “a” or “an” are used to include one or more than one and the term “or” is used to refer to a nonexclusive “or” unless otherwise indicated. In addition, it is to be understood that the phraseology or terminology employed herein, and not otherwise defined, is for the purpose of description only and not of limitation. Furthermore, all publications, patents, and patent documents referred to in this document are incorporated by reference herein in their entirety, as though individually incorporated by reference. In the event of inconsistent usages between this document and those documents so incorporated by reference, the usage in the incorporated reference should be considered supplementary to that of this document; for irreconcilable inconsistencies, the usage in this document controls.

In the methods of manufacturing described herein, the steps can be carried out in any order without departing from the principles of the invention, except when a temporal or operational sequence is explicitly recited. Recitation in a claim to the effect that first a step is performed, then several other steps are subsequently performed, shall be taken to mean that the first step is performed before any of the other steps, but the other steps can be performed in any suitable sequence, unless a sequence is further recited within the other steps. For example, claim elements that recite “Step A, Step B, Step C, Step D, and Step E” shall be construed to mean step A is carried out first, step E is carried out last, and steps B, C, and D can be carried out in any sequence between steps A and E, and that the sequence still falls within the literal scope of the claimed process. A given step or sub-set of steps can also be repeated, or carried out simultaneously with other steps. In another example, claim elements that recite “Step A, Step B, Step C, Step D, and Step E” can be construed to mean Step A is carried out first, Step B is carried out next, Step C is carried out next, Step D is carried out next, and Step E is carried out last.

Furthermore, specified steps can be carried out concurrently unless explicit claim language recites that they be carried out separately. For example, a claimed step of doing X and a claimed step of doing Y can be conducted simultaneously within a single operation, and the resulting process will fall within the literal scope of the claimed process.

### Definitions

The singular forms “a,” “an” and “the” can include plural referents unless the context clearly dictates otherwise.

As used herein, in some examples, terms such as “first,” “second,” “third,” and the like, as applied to other terms such as “mother liquor,”, “crystals,” “molten mixture,” “mixture,” “rinse solution,” “molten silicon,” and the like, are used simply as generic terms of differentiation between steps, and do not by themselves indicate priority of steps or order of steps, unless otherwise clearly indicated. For example, in some examples a “third mother liquor” may be an element, while no first or second mother liquor may be elements of the example. In other examples, a first, second, and third mother liquor may all be elements of an example.

The term “about” can allow for a degree of variability in a value or range, for example, within 10%, within 5%, or within 1% of a stated value or of a stated limit of a range. When a range or a list of sequential values is given, unless otherwise specified any value within the range or any value between the given sequential values is also disclosed.

The term “solvent” as used herein refers to a liquid that can dissolve a solid, liquid, or gas. Nonlimiting examples of solvents are molten metals, silicones, organic compounds, water, alcohols, ionic liquids, and supercritical fluids.

The term “independently selected from” as used herein refers to referenced groups being the same, different, or a mixture thereof, unless the context clearly indicates otherwise. Thus, under this definition, the phrase “X1, X2, and X3 are independently selected from noble gases” would include the scenario where, for example, X1, X2, and X3 are all the same, where X1, X2, and X3 are all different, where X1 and X2 are the same but X3 is different, and other analogous permutations.

The term “air” as used herein refers to a mixture of gases with a composition approximately identical to the native composition of gases taken from the atmosphere, generally at ground level. In some examples, air is taken from the ambient surroundings. Air has a composition that includes approximately 78% nitrogen, 21% oxygen, 1% argon, and 0.04% carbon dioxide, as well as small amounts of other gases.

The term “room temperature” as used herein refers to ambient temperature, which can be, for example, between about 15° C. and about 28° C.

As used herein, “mixture” refers to a combination of two or more substances in physical contact with one another. For example, components of a mixture can be physically combined as opposed to chemically reacting.

As used herein, “melting” refers to a substance changing from a solid to a liquid when exposed to sufficient heat.

As used herein, “purifying” refers to the physical or chemical separation of a chemical substance of interest from foreign or contaminating substances.

As used herein, “contacting” refers to the act of touching, making contact, or of bringing substances into immediate proximity.

As used herein, “crystallizing” includes the process of forming crystals (crystalline material) of a substance, from solution. The process separates a product from a liquid feed stream, often in extremely pure form, by cooling the feed stream or adding precipitants that lower the solubility of the desired product so that it forms crystals. The pure solid crystals are then separated from the remaining liquor by decantation, filtration, centrifugation or other means.

As used herein, “crystalline” includes the regular, geometric arrangement of atoms in a solid.

As used herein, “separating” refers to the process of removing a substance from another (e.g., removing a solid or a liquid from a mixture). The process can employ any suitable technique known to those of skill in the art, e.g., decanting the mixture, skimming one or more liquids from the mixture, centrifuging the mixture, filtering the solids from the mixture, or a combination thereof.

As used herein, “mother liquor” or “mother liquid” refers to the solid or liquid obtained after solids (e.g., crystals) are removed from a mixture of a solution of solids in a liquid. Depending on the thoroughness of the removal, the mother liquor can include an unappreciable amount of these solids.

As used herein, “silicon” refers to the chemical element that has the symbol Si and atomic number 14. As used herein, “metallurgical grade silicon” or “MG silicon” or “MG Si” refers to relatively pure (e.g., at least about 96.0 wt. %) silicon.

As used herein, “molten” refers to a substance that is melted, wherein melting is the process of heating a solid substance to a point (called the melting point) where it turns into a liquid.

As used herein, “solvent metal” refers to one or more metals, or an alloy thereof, which upon heating, can effectively dissolve silicon, resulting in a molten liquid. Suitable exemplary solvent metals include, e.g., copper, tin, zinc, antimony, silver, bismuth, aluminum, cadmium, gallium, indium, magnesium, lead, an alloy thereof, and combinations thereof.

As used herein, an “alloy” refers to a homogeneous mixture of two or more elements, at least one of which is a metal, and where the resulting material has metallic properties. The resulting metallic substance usually has different properties (sometimes significantly different) from those of its components.

As used herein, “liquidus” refers to a line on a phase diagram above which a given substance is stable in the liquid phase. Most commonly, this line represents a transition temperature. The liquidus can be a straight line, or it can be curved, depending upon the substance. The liquidus is most often applied to binary systems such as solid solutions, including metal alloys. The liquidus can be contrasted to the solidus. The liquidus and solidus do not necessarily align or overlap; if a gap exists between the liquidus and solidus, then within that gap, the substance is not stable as either a liquid or a solid.

As used herein, “solidus” refers to a line on a phase diagram below which a given substance is stable in the solid phase. Most commonly, this line represents a transition temperature. The solidus can be a straight line, or it can be curved, depending upon the substance. The solidus is most often applied to binary systems such as solid solutions, including metal alloys. The solidus can be contrasted to the liquidus. The solidus and liquidus do not necessarily align or overlap. If a gap exists between the solidus and liquidus, then within that gap, the substance is not stable as singly either a solid or a liquid; such is the case, for example, with the olivine (fosterite-fayalite) system.

As used herein, “dross” refers to a mass of solid impurities floating on a molten metal bath. It appears usually on the melting of low melting point metals or alloys such as tin, lead, zinc or aluminum, or by oxidation of the metal(s). It can be removed, e.g., by skimming it off the surface. With tin and lead, the dross can also be removed by adding sodium hydroxide pellets, which dissolve the oxides and form a slag. With other metals, salt fluxes can be added to separate the dross. Dross is distinguished from slag, which is a (viscous) liquid floating on the alloy, by being solid.

As used herein, “slag” refers to by-product of smelting ore to purify metals. They can be considered to be a mixture of metal oxides; however, they can contain metal sulfides and metal atoms in the elemental form. Slags are generally used as a waste removal mechanism in metal smelting. In nature, the ores of metals such as iron, copper, lead, aluminum, and other metals are found in impure states, often oxidized and mixed in with silicates of other metals. During smelting, when the ore is exposed to high temperatures, these impurities are separated from the molten metal and can be removed. The collection of compounds that is removed is the slag. A slag can also be a blend of various oxides and other materials created by design, such as to enhance the purification of the metal.

As used herein, “inert gas” refers to any gas, or combination of gases, that is not reactive under normal circumstances. Inert gases are not necessarily elemental and are often molecular gases. Like the noble gases, the tendency for non-reactivity is due to the valence, the outermost electron shell, being complete in all the inert gases. Inert gases can be, but are not necessarily, noble gases. Exemplary inert gases include, e.g., helium (He), Neon (Ne), Argon (Ar) and nitrogen (N2).

As used herein, “directionally solidifying” refers to the solidification of molten metal so that feed metal is continually available for the portion undergoing solidification.

As used herein, “polycrystalline silicon” or “poly-Si” or “multicrystalline silicon” refers to a material including multiple monocrystalline silicon crystals.

As used herein, “monocrystalline silicon” refers to silicon that has a single and continuous crystal lattice structure with almost no defects or impurities.

As used herein, “ingot” refers to a mass of cast material. In some examples, the shape of the material allows the ingot to be relatively easily transported. For example, metal heated past its melting point and molded into a bar or block is referred to as an ingot.

As used herein, “boule” refers to a single-crystal ingot synthetically produced. For example, in the Czochralski or “CZ” process, a seed crystal is used to create a larger crystal, or ingot. This seed crystal is dipped into the pure molten silicon and slowly extracted. The molten silicon grows on the seed crystal in a crystalline fashion. As the seed is extracted the crystal grows and eventually a large, circular boule is produced.

As used herein, “optional” refers to something that either is done or is present, or is not done or is not present. For example, an optional step is a step that either is performed, or is not performed. In another example, an optional ingredient is an ingredient that either is present, or is not present.

As used herein, “acid solution” refers to a solution containing acid of any concentration.

As used herein, “aluminum trichloride” refers to AlCl3.

As used herein, “batch” refers to a non-continuous production or use; something made or used in a single operation.

As used herein, “bins” refers to containers for holding, transporting, storing, or using materials. A bin need not have an unbroken solid body, a bin can have perforations or holes.

As used herein, “continuous” refers to non-batch production or use, an uninterrupted manufacture or use. A continuous process need not be infinitely continuous, but should be substantially continuous while the method containing the process is in operation.

As used herein, “crystal” refers to a solid having a highly regular structure. A crystal can be formed by the solidification of elements or molecules.

As used herein, “first complex”, “second complex”, and “third complex refers to a combination of more than one thing, particularly materials, compounds, or chemical elements. The complex can be macroscopic, e.g. the term does not require nor forbid the combination of chemical elements on a molecular or atomic scale. The complex can be of inconsistent distribution. The complex can be an alloy, or can contain an alloy.

As used herein, “dissolving chemical” refers to at least one dissolving chemical, and can refer to more than one dissolving chemical. Dissolving chemical can refer to a chemical that reacts with at least one impurity, dissolves at least one impurity, or a combination thereof.

As used herein, “dry” refers to at least partial removal of water, and can refer to something that has had a substantial majority of water removed from it.

As used herein, “extruded” refers to being squeezed or pushed out of a hole, including by the force of gravity, including by the force of liquid pressure caused by gravity, including a solid being pushed out of a hole by liquid pressure generated by the force of gravity or by other means.

As used herein, “fresh water” refers to water that has not yet been used to wash impurities or chemicals from a material to be purified.

As used herein, “head space” refers to the volume of air above something, generally but not necessarily in an enclosed environment.

As used herein, “heater” refers to a device that can impart heat to something else.

As used herein, “material to be purified” can be at least one material, and can be several materials, and the several materials can be combined into alloys, chemical compounds, crystals, or combinations thereof.

As used herein, “mixture” refers to two or more things being combined. The combination can be such that intimate contact between the two things exists.

As used herein, “molten” refers to liquid, particularly the liquid phase of a material that is solid at room temperature.

As used herein, “peroxide” refers to a compound with an oxygen-oxygen single bond, and includes hydrogen peroxide.

As used herein, “pH” refers to a measure of the acidity or basicity of a solution. It approximates the negative base-ten logarithm of the molar concentration of dissolved hydrogen ions, e.g. H+.

As used here, “polyaluminum chloride”, also abbreviated as PAC, refers to a compound of the formula AInCl(3n-m)(OH)m. It can also be referred to as aluminum chlorohydrate.

As used herein, “react” refers to having a chemical reaction with, or in the context of an acid solution or dissolving solution and impure silicon, to dissolve.

As used herein, “sensor” refers to a device that can detect a characteristic or property of something else.

As used herein, “separation” or “separate” refers to the at least partial removal of one thing from another.

As used herein, “settling tank” refers to a tank designed to allow solid material settle to the bottom, so that liquid can be removed from the tank with less solid than it contained when it entered the tank. In some examples, settling tanks can be conical, and can have a valve at the bottom to allow the release of solids.

As used herein, “specific gravity” refers to the density of a substance relative to the density of water. Specific gravity can refer to the density of the substance being measured divided by the density of water measured at approximately 3.98 degrees Celsius and at one atmosphere pressure.

As used herein, “steam” refers to gaseous water or water vapors.

As used herein, “tank” refers to a container that can be but is not necessarily open at the top.

As used herein, “valve” refers to a device for allowing or stopping the flow of something through something else.

As used herein, “block” refers to a piece of an ingot that can be any shape. Generally, a block is square-shaped.

As used herein, “side block” refers to a block that shares one side with the perimeter of an ingot.

As used herein, “center block” refers to a block that does not share a side with the perimeter of an ingot.

As used herein, “corner block” refers to a block that shares two sides with the perimeter of an ingot.

As used herein, “coating” refers to a layer of material that covers at least part of another material, wherein the layer can be as thick, thicker, or thinner than the material that it covers.

As used herein, “counter-sunk” refers to a manner of installing a screw, bolt, or similar hardware wherein a secondary conical or semi-conical hole of wider circumference is made closer to the surface of a material approximately above a primary cylindrical hole of a particular circumference in that material, such that the hardware does not protrude above the surface in which it is installed, or such that the hardware protrudes less above the surface in which it is installed than if there was not a secondary hole.

As used herein, “counter-bored” refers to a manner of installing a screw, bolt, or similar hardware wherein a secondary cylindrical hole of wider circumference is made closer to the surface of a material approximately above a primary cylindrical hole of a particular circumference in that material, such that the hardware does not protrude above the surface in which it is installed, or such that the hardware protrudes less above the surface in which it is installed than if there was not a secondary hole.

As used herein, “crucible” refers to a container that can hold molten material, that can hold material as it is melted to become molten, and that can hold molten material as it solidifies or crystallizes or a combination thereof.

As used herein, “curve” refers to a surface that is approximately curved, or follows an approximate arc shape, and need not be completely curved. In approximating whether a surface is curved, the average is considered, such that a surface that in some parts (including one part), several parts, or in all parts follows a straight line or lines can be a curved surface if overall the surface follows an approximate arc.

As used herein, “grid” refers to at least two blocks, the pattern of the edges of the blocks forming generally a pattern of regularly spaced horizontal and vertical lines.

As used herein, “internal angle” refers to the angle formed between two surfaces that is the smaller angle of the two angles.

As used herein, “flat side” refers to a side that is approximately straight, is minimally curved overall, and need not be completely flat. In approximating straightness, the average is considered, such that a side that curves slightly back and forth several times can be a flat side if overall the side follows an approximately straight line.

As used herein, “furnace” refers to a machine, device, apparatus, or other structure that has a compartment for heating a material.

As used herein, “furnace capacity” refers to the volume of a compartment of a furnace.

As used herein, “perimeter” refers to the outer edge of an object or shape. As used herein, “round” refers to a shape that does not have sharp corners, for example a shape that does not have 90-degree corners. A round shape can be circular or oblong. A round shape can include a square shape with the edges rounded-off.

As used herein, “conduit” refers to tube-shaped hole through a material, where the material is not necessarily tube-shaped. For example, a hole running through a block of material is a conduit. The hole can be of greater length than diameter. A conduit can be formed by encasing a tube (including a pipe) in a material.

As used herein, “directional solidification” refers to crystallizing a material starting in approximately one location, proceeding in an approximately linear direction (e.g. vertically, horizontally, or perpendicular to a surface), and ending in approximately another location. As used in this definition, a location can be a point, a plane, or a curved plane, including a ring or bowl shape.

As used herein, “fan” refers to any device or apparatus which can move air.

As used herein, “heating element” refers to a piece of material which generates heat. In some embodiments, a heating element can generate heat when electricity is allowed to flow through that material.

As used herein, “induction heater” refers to a heater which adds heat to a material via the inducement of electrical currents in that material. Generally, such electrical currents are generated by allowing an alternating current to travel through a coil of metal that is proximate to the material to be heated.

As used herein, “melt” refers to undergoing the phase transition from solid to liquid, or to a molten material.

As used herein, “oil” refers to a substance that is liquid at ambient temperature, that is hydrophobic, and that has a boiling point above 300° C. Examples of oils include but are not limited to vegetable oils and petroleum oils.

As used herein, “refractory material” refers to a material which is chemically and physically stable at high temperatures. Examples of refractory materials include but are not limited to aluminum oxide, silicon oxide, magnesium oxide, calcium oxide, zirconium oxide, chromium oxide, silicon carbide, graphite, or a combination thereof.

As used herein, “hot face refractory” refers to a refractory material.

As used herein, “conducting refractory” refers to a refractory material that can conduct heat.

As used herein, “side” or “sides” can refer to one or more sides, and unless otherwise indicated refers to the side or sides of an object as contrasted with one or more tops or bottoms of the object.

As used herein, “silicon” refers to the element Si, and can refer to Si in any degree of purity, but generally refers to silicon that is at least 50% by weight pure, preferably 75% by weight pure, more preferably 85% pure, more preferably 90% by weight pure, and more preferably 95% by weight pure, and even more preferably 99% by weight pure.

As used herein, “slip-plane refractory” refers to a refractory material that decreases friction and decreases sticking between the solid silicon and the directional solidification mold.

As used herein, “tube” refers to a hollow pipe-shaped material. A tube generally has an internal shape that approximately matches its outer shape. The internal shape of a tube can be any suitable shape, including round, square, or a shape with any number of sides, including non-symmetrical shapes.

As used here, “recrystallization” refers to a process of dissolving an impure material in a solvent and crystallizing the material back out of the solvent, such that the material that is crystallized back out of the solvent has a higher purity than the impure material that was dissolved in the solvent.

### Method for Purification of Silicon

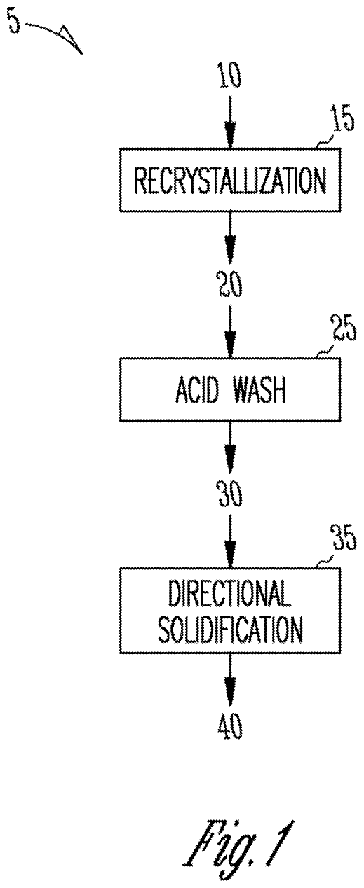

The present invention relates to the purification of silicon. The present invention provides a method for purification of silicon. Referring to FIG. 1, a block flow diagram 5 is shown, giving a general overview of the method of silicon purification of the present invention. The method includes recrystallizing 15 starting material-silicon 10 from a molten solvent comprising aluminum to provide final recrystallized-silicon crystals 20. The method also includes washing 25 the final recrystallized-silicon crystals 20 with an aqueous acid solution to provide a final acid-washed-silicon 30. The method also includes directionally solidifying 35 the final acid-washed-silicon 30 to provide final directionally solidified-silicon crystals 40.

### Recrystallizing

The method of purifying silicon includes recrystallizing starting material-silicon from a molten solvent comprising aluminum to provide final recrystallized-silicon crystals. The recrystallizing can be any suitable recrystallization process, wherein the recrystallization solvent includes aluminum, to provide final recrystallized-silicon crystals that are more pure than the starting material-silicon. In some embodiments, a single recrystallization can be performed to transform starting material-silicon to final recrystallized-silicon crystals. In other embodiments, the starting material-silicon can be recrystallized multiple times before providing the final recrystallized-silicon crystals. In some embodiments, the aluminum solvent can be pure, or can include impurities. The impurities in the aluminum can be silicon or other impurities. In embodiments with multiple recrystallizations, the recrystallizations can be a cascading process, wherein the aluminum solvent can be recycled backwards through the process, such that the first recrystallization uses the least pure aluminum as the recrystallization solvent, and the last recrystallization uses the most pure aluminum as the recrystallization solvent. As silicon crystals move forward through the cascading process, they are recrystallized from purer solvent metal. By recycling the aluminum solvent, waste is minimized. Since the amount of impurities in the solvent and in the material being recrystallized can negatively affect the purity of the product, using the purest aluminum solvent for the last recrystallization helps to maximize the purity of the final recrystallized-silicon crystals. Some examples of a suitable recrystallization can be found in U.S. patent application Ser. No. 12/729,561, hereby incorporated by reference in its entirety.

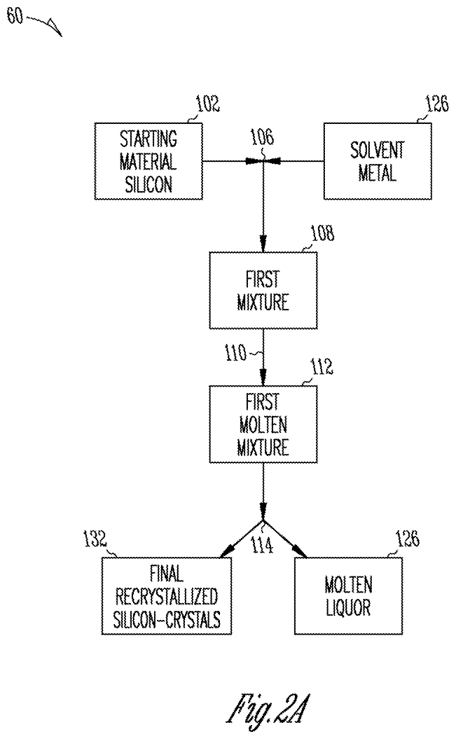

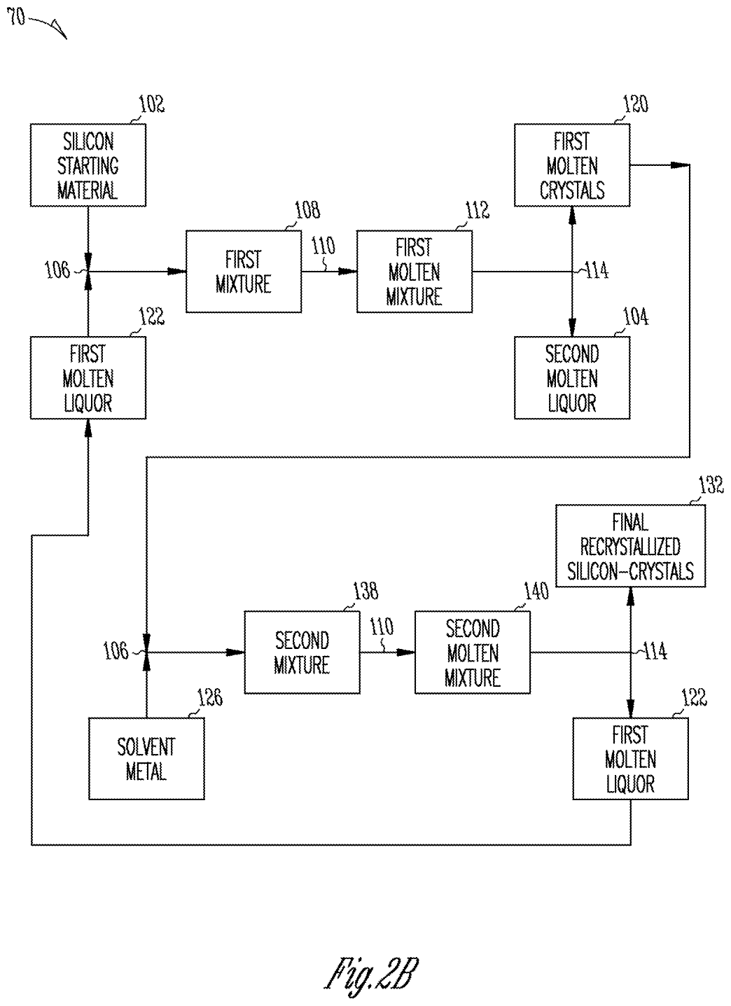

Referring to FIG. 2A, a block flow diagram 60 of a method of recrystallizing silicon is shown, according to some embodiments. The recrystallization of the starting material-silicon can include contacting 106 the starting material-silicon 102 with a solvent metal that includes aluminum 126. The contacting can be sufficient to provide a first mixture, 108. The method can include melting 110 the first mixture. The melting 110 can be sufficient to provide a first molten mixture 112. The method can include cooling the first molten mixture. The cooling can be sufficient to form the final recrystallized-silicon crystals 132 and a mother liquor 126. The method can include separating 114 the final recrystallized-silicon crystals 132 and the mother liquor 126. The separating can provide the final recrystallized-silicon crystals 132.

Referring to FIG. 2B, a block flow diagram 70 of a method of recrystallizing silicon is shown, according to some embodiments. The recrystallization of starting material-silicon can include contacting 106 the starting material-silicon 102 with a first mother liquor 122. The contacting 106 can be sufficient to provide a first mixture 108. The method can include melting 110 the first mixture. The melting can be sufficient to provide a first molten mixture 112. The method can include cooling the first molten mixture. The cooling can be sufficient to form first silicon crystals 120 and a second mother liquor 104. The method can include separating 114 the first silicon crystals 120 and the second mother liquor 104. The separating can provide the first silicon crystals 120. The method can include contacting 106 the first silicon crystals 120 with a first solvent metal comprising the aluminum 126. The contacting 106 can be sufficient to provide a second mixture 138. The method can include melting 110 the second mixture 138. The melting 110 can be sufficient to provide a second molten mixture 140. The method can include cooling the second molten mixture. The cooling can be sufficient to form the final recrystallized-silicon crystals 132 and the first mother liquor 122. The method can also include separating 114 the final recrystallized-silicon crystals 132 and the first mother liquor 122, to provide the final recrystallized-silicon crystals. It is to be understood that all discussion herein regarding a three-pass or greater recrystallization cascade and variations thereof applies also to a two-pass recrystallization cascade embodiments, such as that illustrated in FIG. 2B; when applicable all discussion herein regarding a three-pass or greater recrystallization cascade and variations thereof also applies to a one-pass recrystallization embodiment, such as that illustrated in FIG. 2A.

In one embodiment, the recrystallization of starting material-silicon can include contacting the starting material-silicon with a second mother liquor. The contacting can be sufficient to provide a first mixture. The method can include melting the first mixture.

The melting can be sufficient to provide a first molten mixture. The method can include cooling the first molten mixture to form first silicon crystals and a third mother liquor. The method can include separating the first silicon crystals and the third mother liquor. The separating can provide the first silicon crystals. The method can include contacting the first silicon crystals and a first mother liquor. The contacting can be sufficient to provide a second mixture. The method can include melting the second mixture. The method can be sufficient to provide a second molten mixture. The method can include cooling the second molten mixture to form second silicon crystals and the second mother liquor. The method can include separating the second silicon crystals and the second mother liquor. The separating can provide the second silicon crystals. The method can include contacting the second silicon crystals with a first solvent metal comprising the aluminum. The contacting can be sufficient to provide a third mixture. The method can include melting the third mixture. The melting can be sufficient to provide a third molten mixture. The method can include cooling the third molten mixture to form the final recrystallized-silicon crystals and the first mother liquor. The method can include separating the final recrystallized-silicon crystals and the first mother liquor, to provide the final recrystallized-silicon crystals.

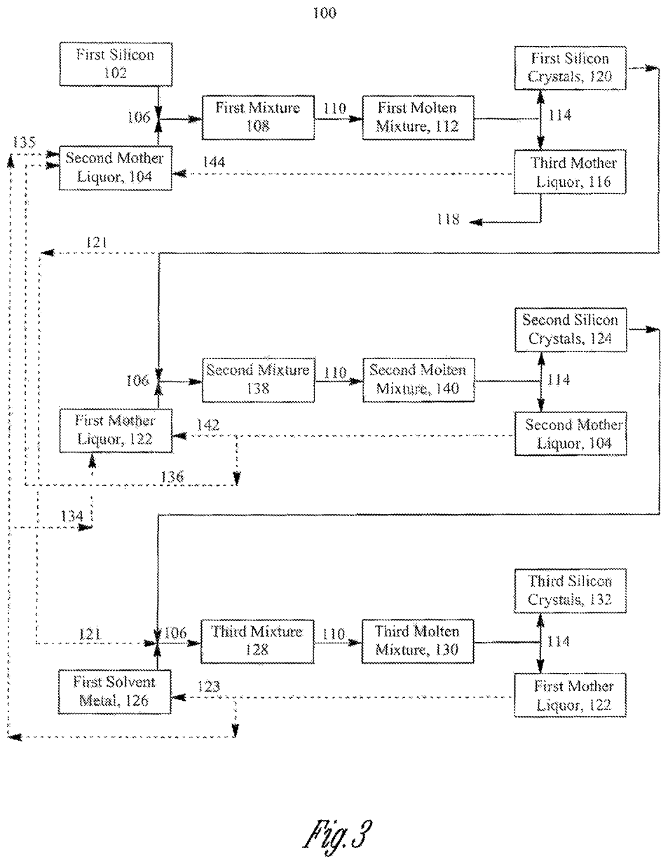

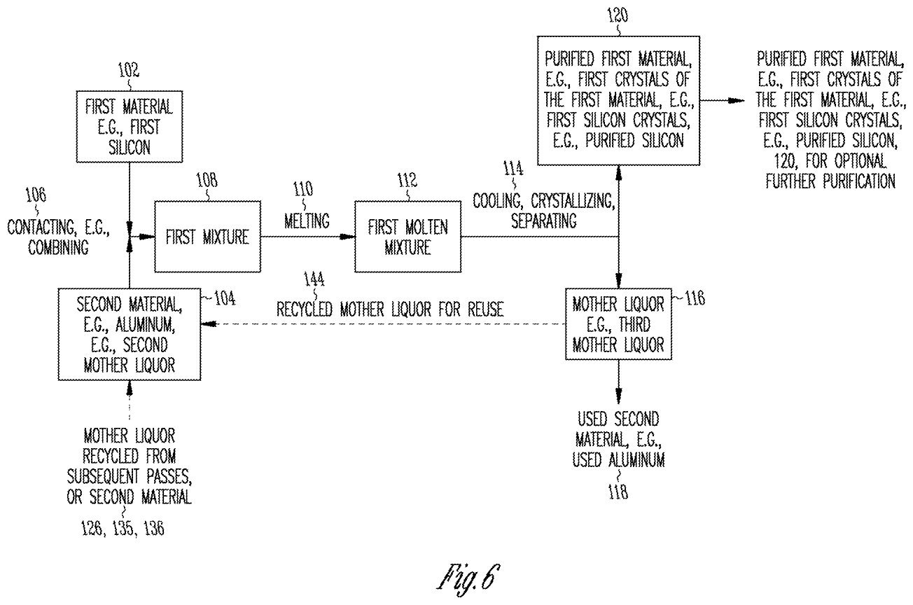

Referring to FIGS. 3, 6, and 7, a block flow diagram 100 of a method of recrystallizing silicon utilizing a cascade process is shown, according to some embodiments. A starting material-silicon 102 (e.g. a first silicon) can contact 106 a solvent metal including aluminum such as second mother liquor 104 to form a first mixture 108. The first mixture 108 can be melted 110 to form a first molten mixture 112. The first molten mixture 112 can then be cooled and separated 114 into first silicon crystals 120 and a mother liquor such as third mother liquor 116. The third mother liquor 116 can then be removed from the process and sold 118 for use in other industries or all or a portion of it can be recycled 144 back with second mother liquor 104. One example of an industry for which the third mother liquor 116 would be of value would be the aluminum foundry industry for use in aluminum silicon alloys for castings.

In some embodiments, the feedstock or metallurgical grade silicon (e.g. the starting material-silicon) can include less than about 15 ppmw boron, less than about 10 ppmw boron, or less than about 6 ppmw boron, for example. The solvent metal can be aluminum. The aluminum can be P1020 aluminum and include a boron level of less than about 1.0 ppmw, less than about 0.6 ppmw, or less than about 0.4 ppmw.

The contacting of silicon or silicon crystals to a mother liquor or a solvent metal can occur in any suitable manner known to those of skill in the art. The manner of contacting can include adding the silicon or silicon crystals to a mother liquor, and can also include adding the mother liquor to the silicon or silicon crystals. Methods of addition that avoid splashing or that avoid loss of material are encompassed by the envisioned manners of contacting. The contacting can be performed with or without stirring or agitation. The contacting can generate agitation. The contacting can be designed to generate agitation. The contacting can occur with or without heating. The contacting can generate heat, can be endothermic, or can generate no heat or loss of heat.

Optional stirring or agitation can be performed in any suitable manner known to those of skill in the art. Stirring can include mechanical stirring with paddles or other stirring devices. Agitation can include agitating by the injecting and bubbling of gases, and can also include the physical agitation of a container, including swirling or shaking. The addition of one material to another can cause agitation, and the manner of addition can be designed such as to produce agitation. The injection of a liquid into another liquid can also produce agitation.

The melting of a mixture of silicon or silicon crystals in a mother liquor or a solvent metal can occur in any suitable manner known to those of skill in the art. The manner of melting can include adding heat to the mixture by any suitable method to cause the desired melting of the silicon or silicon crystals. The heating can continue after a molten mixture has been achieved. The manner of melting can be conducted with or without agitation. The manner of melting can also include the silicon or silicon crystals melting as a result of being exposed to a mother liquor or solvent metal that is at a high enough temperature, e.g., at a temperature at or above the melting point of the silicon or silicon crystals; thus, the contacting of silicon or silicon crystals with a mother liquor or a solvent metal to produce a mixture can be combined with the step of melting the mixture of silicon or silicon crystals to provide a molten mixture. The melting temperature of a mixture can be inconsistent or variable, changing as the composition of the molten material changes.

Methods of adding heat to a mixture include any suitable method known by those of skill in the art. These methods include, for example, heating with a furnace or heating by injecting hot gases into a mixture, or heating with a flame generated from burning gases. Inductive heating can be used. The method of heating can be radiant heat. The method of heating can be by the conduction of electricity through the material to be heated. Also included are the use of plasma to heat, the use of an exothermic chemical reaction to heat, or the use of geothermal energy to heat. The mixing of the silicon or silicon crystals with the mother liquor or solvent metal can, depending of the impurities of the silicon and the content of the mother liquor, produce heat or absorb heat, which can in some embodiments result in the corresponding adjustment of the source of heating being beneficial.

Optionally, gas can be injected into the molten mixture before cooling, including chlorine gas, other halogen gas or halide-containing gas, or any suitable gas. The cooling of the molten mixture can be conducted in any suitable manner known to those of skill in the art. Included are cooling by removal from a source of heat, which includes cooling by exposure to room temperature or to temperatures below the temperature of the molten mixture. Included are cooling by pouring into a non-furnace container and being allowed to cool at below-furnace temperatures. In some embodiments, the cooling can be rapid; however, in other embodiments, the cooling can be gradual, therefore it can be advantageous to expose the cooling molten mixture to a source of cooling that is only incrementally lower than the current temperature of the molten mixture. The source of cooling can be gradually lowered in temperature as the molten mixture is cooled, and in some cases this could be achieved via sensitive or general monitoring of the temperature of the molten mixture as it is cooled. The purity of the resulting crystallized silicon can improve by cooling the mixture as slowly as possible, therefore all suitable manners of gradual cooling are envisioned to be encompassed by the present invention. Also included are more rapid methods of cooling, including refrigeration mechanisms. Exposure of the container holding the molten material to cooler materials, such as a liquid cooler than the molten mixture, such as water, or such as another molten metal, or such as a gas, including ambient or refrigerated air, are included. The addition of cooler materials to the molten mixture are included, such as the addition of another cooler mother liquor, or the addition of a cooler solvent metal, or the addition of another cooler material that can be removed from the mixture later, or that alternatively can be left in the mixture.

The mother liquor resulting from the cooling of a molten mixture and subsequent separation of silicon crystals and the mother liquor is envisioned to be optionally recycled to any prior step in the process. Once crystallization of silicon has occurred from a mother liquor, generally at least some amount of silicon will remain dissolved in the mother liquor, along with the impurities which are desired to stay dissolved in the mother liquor. To cool the molten mixture to a point where all or most of the silicon is crystalline can be in some cases not possible, or can negatively impact the purity of the resulting silicon crystals, or can be inefficient. In some embodiments, the purity of the silicon crystals produced by only allowing less than all, or less than a majority, of the silicon to crystallize out of a molten mixture, can be significantly or at least partially improved. The energy required to heat and melt solvent metal can be economically inefficient, compared to combining hot mother liquors with mother liquors in prior steps, or compared to reusing hot mother liquors. The energy required to cool a molten mixture to a certain temperature in order to attain a certain yield of silicon crystals can be inefficient compared to not cooling the mother liquor to such a low temperature and accepting a lower yield of silicon crystals but then recycling the mother liquor.

The advantageous leaving of desired and undesired materials in the mother liquors is envisioned to be encompassed by some embodiments of the present invention; thus, in some embodiments the recycling of mother liquor to be used again in the same crystallization step or in earlier crystallization steps is a sometimes useful aspect. By recycling mother liquors, the silicon that is still present in the mixture of the mother liquor is conserved and wasted less than if the mother liquor is simply discarded or sold as by-product. In some embodiments the same or nearly the same degree of purity of silicon crystals can be achieved using a recycled mother liquor, or by using a mother liquor that has some recycled mother liquor in it, than if the mother liquor had no recycled mother liquor, or even than if the solvent from which crystallizing was occurring was pure solvent metal. Therefore, all degrees and variations of the recycling of mother liquors are encompassed within the scope of the present invention.

The separation of the mother liquor from the silicon solids can take place by any suitable method known to those of skill in the art. Any variation of draining or siphoning the liquid solvent away from the desired solids are encompassed within embodiments of the methods described herein. These methods include decantation, or the pouring of the mother liquor away from the desired solids. For a decantation, the desired solids can be held in place by gravity, by adhesion to themselves or to the sides of the container, by the use of a grate or mesh-like divider that selectively holds back solids, or by applying physical pressure to the solids to hold them in place. Methods of separation include centrifugal separation. Also included are filtration, using any filter medium, and with or without the use of a vacuum, and with or without the use of pressure. Also included are chemical means, such as dissolution or chemical transformation of the solvent, including using acid or base.

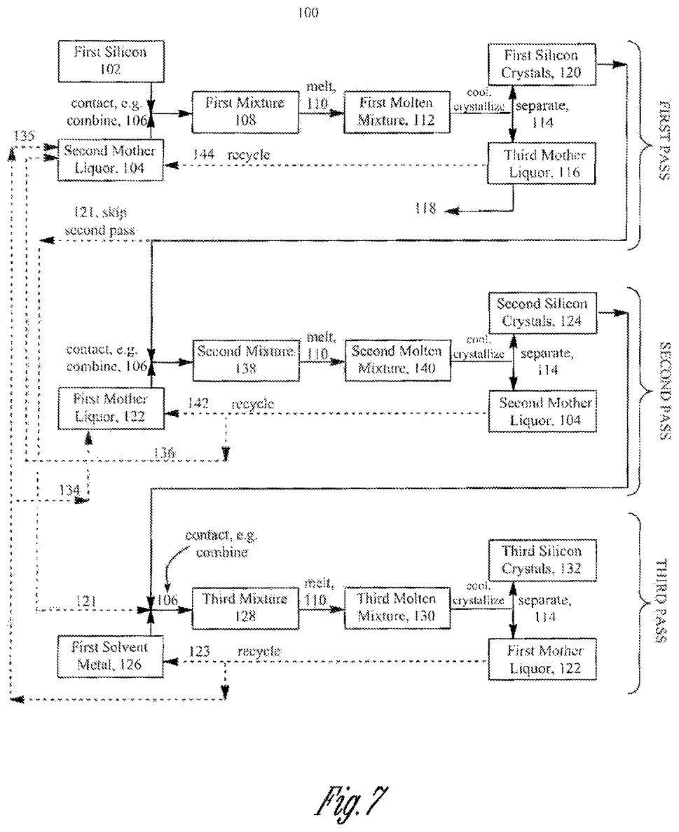

Referring to FIGS. 3 and 7, the first silicon crystals 120 can then be optionally contacted 106 with a first mother liquor 122 to form a second mixture 138. The second mixture 138 can be optionally melted to form a second molten mixture 140. The second molten mixture can be optionally cooled and separated 114 into second silicon crystals 124 and the second mother liquor 104. The second mother liquor 104 can then be directed back 136 in the process to contact a starting material-silicon 102 or all or a portion of the second mother liquor 104 can be recycled 142 back to the first mother liquor 122. The steps from contacting the first silicon crystals to obtaining second silicon crystals are optional, in that they can be either skipped or these steps can be performed a number of times (e.g. 1, 2, 3, 4, etc.). If these steps are not performed 121, the recrystallization can be a two pass process, and first silicon crystals 120 are then subsequently contacted with first solvent metal 126.

In another embodiment, the steps from contacting the first silicon crystals to obtaining second silicon crystals are performed. In these embodiments, step 121 is not performed. Thus, after the first molten mixture 112 is cooled and separated 114 into first silicon crystals 120 and a third mother liquor 116, the first silicon crystals 120 can then be contacted 106 with a first mother liquor 122 to form a second mixture 138. The second mixture 138 can be melted to form a second molten mixture 140. The second molten mixture can be cooled and separated 114 into second silicon crystals 124 and the second mother liquor 104. The second mother liquor 104 can then be directed back 136 in the process to contact a starting material-silicon 102 or all or a portion of the second mother liquor 104 can be recycled 142 back to the first mother liquor 122.

In another embodiment, the steps from contacting the first silicon crystals to obtaining second silicon crystals are independently either performed or not performed. Thus, after the first molten mixture 112 is cooled and separated 114 into first silicon crystals 120 and a third mother liquor 116, the first silicon crystals 120 can then be optionally contacted 106 with a first mother liquor 122 to form a second mixture 138, or alternatively, the first silicon crystals 120 can then be contacted 106 with a first mother liquor 122 to form a second mixture 138. The second mixture 138 can be optionally melted to form a second molten mixture 140, or alternatively, the second mixture 138 can be melted to form a second molten mixture 140. The second molten mixture can be optionally cooled and separated 114 into second silicon crystals 124 and the second mother liquor 104, or alternatively, the second molten mixture can be cooled and separated 114 into second silicon crystals 124 and the second mother liquor 104. The second mother liquor 104 can then be directed back 136 in the process to contact a starting material-silicon 102 or all or a portion of the second mother liquor 104 can be recycled 142 back to the first mother liquor 122.

The second silicon crystals 124 can be contacted 106 with a first solvent metal 126 to form a third mixture 128. The third mixture 128 can be melted 110 to form a third molten mixture 130. The third molten mixture 130 can then be cooled and separated 114 into final recrystallized-silicon crystals (e.g. third silicon crystals) 132 and the first mother liquor 122. All or a portion of the first mother liquor 122 can then be directed back 134 in the process to contact the first silicon crystals 120. All or a portion of the first mother liquor 122 can be recycled 123 back to the first solvent metal 126. In some embodiments of the present invention, the batch or continuous recycling 123 of all or part of mother liquor 122 back to the first solvent metal 126 can cause the element 126 to include solvent metal that is less than completely pure because of dilution with mother liquor; all variations of the steps of recycling of mother liquors are included within the scope of the present invention. All or a portion of the first mother liquor can be alternatively or additionally recycled 135 back to the second mother liquor.

In some embodiments, the steps from contacting the first silicon crystals to obtaining second silicon crystals are not performed. Thus, after the first molten mixture 112 is cooled and separated 114 into first silicon crystals 120 and a third mother liquor 116, the first silicon crystals 120 can be 121 contacted 106 with a first solvent metal 126 to form a third mixture 128. The third mixture 128 can be melted 110 to form a third molten mixture 130. The third molten mixture 130 can then be cooled and separated 114 into final recrystallized-silicon crystals 132 and the first mother liquor 122. The first mother liquor 122 can then be directed back 134 in the process to contact the first silicon crystals 120. All or a portion of the first mother liquor 122 can be recycled 123 back to the first mother liquor.

Creating the first silicon crystals 120 can be called the first pass.

Forming the second silicon crystals 124 can be called the second pass.

Similarly, the part of the method forming the final recrystallized-silicon crystals 132 can be called the third pass. There is no limit to the number of passes envisioned within the method of the present invention.

A repeated pass can be performed in order to more efficiently use the mother liquor by increasing the number of crystallizations achieved from a mother liquor, by increasing the amount of silicon recovered from the mother liquor, or by increasing the yield of silicon crystals before entering the next pass in the process, and there is no limit to the number of repetitions of a pass envisioned within the method of the present invention. If a repeated pass is performed, the respective mother liquor can be reused in all or in part in repetitions of that pass. A repeated pass can be performed sequentially, or in parallel. If a repeated pass is performed sequentially, it can be performed in one single container, or it can be performed in several containers in sequence. If a repeated pass is performed in parallel, several containers can be used, allowing several crystallizations to occur in parallel. The terms “sequence” and “parallel” are not intended to rigidly restrict the order in which the steps are performed, by rather to approximately describe doing steps one at a time or near to the same time.

A repeated pass, e.g. a repetition of the first, second, third, or of any pass, can more efficiently make use of several mother liquors of decreasing purity including by reusing all or part of a mother liquor in a pass. To make an existing mother liquor more pure, one way can be to add additional solvent metal (that is more pure than the mother liquor) to the mother liquor. Adding another more pure mother liquor to the mother liquor can be another way to increase its purity, such as that derived from, e.g., a later crystallization step in the process. Part or all of the mother liquor that has been used in a particular pass can also be discarded or used in an earlier pass or used in an earlier repetition of the same pass.

One possible reason for the repetition of passes and corresponding reuse of mother liquors can be to make the mass balance for the cascading steps even out for part or all of the entire process. Silicon of suitable purity can be added to any stage of the cascade, and can be added with or without silicon from a prior pass, and as with the repetition of the steps, one possible reason to do this can be to make the mass balance of the cascading steps balance in part or in whole.

The mother liquor can be entirely reused without any enhancement of purity of the mother liquor in a repeated pass. Alternatively, the mother liquor can be partially reused with enhancement of purity in a repeated pass, using more pure solvent metal or mother liquor from a subsequent step to enhance the purity of the mother liquor. For example, a first pass could be repeated in parallel, using two different containers, with mother liquor flowing toward the beginning of the process from the first instance of the pass to the first repetition of the pass, with silicon being added to both the first instance of the pass and the repeated instance of the pass, and with silicon being removed from both the first instance of the pass and the repetition of the pass to be carried on to subsequent passes. In another example, a first pass could be repeated in parallel, using two different containers, with part of the mother liquor flowing towards the beginning of the process from the first instance of the pass to the first repetition of the pass, and with another part of the mother liquor flowing towards the beginning of the process to a prior step without being reused in the repetition of the pass, with silicon being added to both the first instance of the pass and the repeated instance of the pass, and with silicon being removed from both the first instance of the pass and the repetition of the pass to be carried on to subsequent passes.

Also, a first pass could be repeated in sequence, using one container, in which after the first crystallization and separation, part of the used mother liquor from that pass is retained for reuse and some mother liquor from a later pass is added, and in the repeated pass another crystallization is performed with additional silicon. After the repetition, the mother liquor can entirely move on to another prior step. Alternatively, after the repetition, only part of the mother liquor can move on to another prior step, with the rest of the mother liquor being retained for reuse in the pass. At least part of the mother liquor can eventually be moved on to a prior step, otherwise the impurities of that mother liquor can build to intolerable levels, and also the mass balance of the cascade can be difficult to maintain. In another example, a first pass could be repeated in sequence, using one container, in which after the first crystallization and separation, all of the used mother liquor from that pass is retained for reuse in the repeated pass, and in the repeated pass another crystallization is performed with additional silicon.

A subsequent pass can be performed in the same or different container or as the prior pass. For example, the first pass can occur in the same container as the second pass. Or, the first pass can occur in a different container as the second pass. A pass can be repeated in the same container. For example, the first instance of the first pass could occur in a particular container, and then the first repetition of the first pass could occur in the same container. The economies of large scale processing can make reuse of the same container for multiple subsequent or simultaneous passes advantageous in some embodiments. In some embodiments, it can be economically beneficial to move a liquid from container to container rather than to move a solid, therefore embodiments of the present invention encompass all variations of the reuse of containers and also all variations of the use of different containers. Therefore, a subsequent pass can be performed in a different container as the prior pass. A repeated pass can be performed in the same container as an earlier performance of that pass.

The impurities of the mother liquor as it moves towards the beginning of the process grow to higher concentrations, including in boron and in other impurities. The mother liquors can be reused as needed in each step of the crystallization (forming the crystals) to balance the mass throughout of the process. The number of reuses can be a function of the solvent metal (e.g., aluminum) to silicon ratio utilized, the desired chemistry, and the desired throughput of the system.

As described in further depth below, after providing the final recrystallized-silicon crystals, residual solvent metal can be dissolved or otherwise removed from the crystals by using an acid, base or other chemical.

Any powder, remaining solvent metal or foreign contaminant can be removed by mechanical means as well. Hydrochloric acid (HCl) can be used to dissolve solvent metal off of cascaded flakes or crystals. Spent HCl can be sold as polyaluminum chloride (PAC) or aluminum chloride to, among other things, treat waste water or drinking water. To dissolve aluminum off of flakes, a counter-current system can be used with multiple tanks moving flakes from clean to dirty, and acid from clean to spent, in opposite directions. A bag house can be used to pull loose powder away from flakes and V-grooved slots and vibration can be used to separate balls of powder, foreign contaminates or non-dissolved aluminum from the flakes after the acid leaching.

At any time during the methods disclosed herein, the silicon crystals or flakes can be melted. A gas or slag can be contacted with the molten silicon. About 0.5-50 wt % slag can be added to the silicon. A slag containing some amount of SiO₂ can be utilized, for example. Flakes can be melted in a furnace, which can include slag addition, and slag addition can occur before or after flake melting. Flakes can be melted using slag addition. Flakes can be melted under vacuum, inert atmosphere or standard atmosphere. Argon can be pumped through the furnace to create an argon blanket or a vacuum furnace can be used. The flakes can be melted to above about 1410° C. The molten silicon can be held between about 1450° C. and about 1700° C. Slag or dross can be removed from the surface of the bath during slagging, while holding the silicon molten in the furnace, or during gas injection. In some examples, the molten silicon can be then poured into a mold for directional solidification. The molten silicon can be filtered through a ceramic filter first.

The mother liquor can be filtered with a ceramic foam filter or can be gas injected at any stage of the process. Ceramic materials low in contaminates, such as boron or phosphorus, are examples of materials that can be used to hold and melt the molten silicon. The gas can be oxygen, argon, water, hydrogen, nitrogen, chlorine, or other gases that contain these compounds can be used, or a combination thereof, for example. The gas can be injected through a lance, rotary degasser, or porous plug into the molten silicon. 100% Oxygen gas can be injected into the molten silicon. Gas can be injected for about 30 minutes to about 12 hours. Gases can be injected before, after, or during slagging. The gas can be 100% oxygen injected at 30-40 L/min through a lance into the molten silicon for 4 hours.

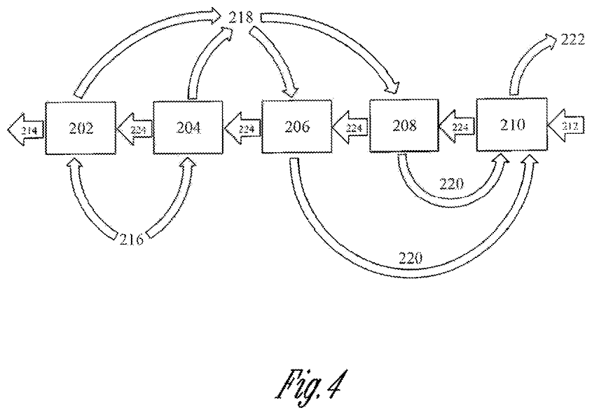

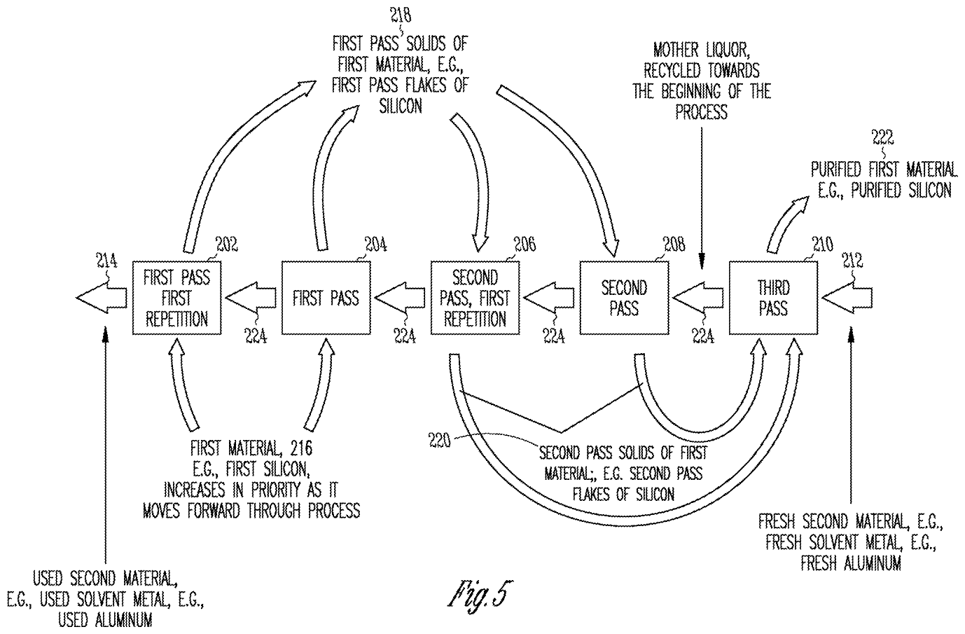

Referring to FIGS. 4 and 5, a diagram 200 of a method of recrystallizing a first material utilizing a triple pass cascade is shown, according to some embodiments. In a specific embodiment, the first material is silicon, and the solvent metal is aluminum. Starting material-silicon 216 can be fed into the beginning of a first pass 204 recrystallizing process. Silicon 216 can be subsequently or simultaneously fed into a first repetition of the first pass 202 process. First pass 202 and 204 can be performed in the same furnace sequentially where some percentage of mother liquor 224 is placed back into or left in the same furnace and some percentage of mother liquor 214 is removed. Alternatively, first pass 202 and 204 can be performed in different furnaces. The resultant flakes from the single pass can either be removed from each of 202 and 204 and combined into 218, or the flakes resulting from process 202 can be fed into process 204, and the flakes resulting from process 204 become flakes 218. The resultant single pass flakes 218 can be fed into second pass 208 and 206 processes, which result in second pass flakes 220. Second pass 206 and 208 can be performed in the same furnace. Sequentially, some percentage of mother liquor 224 can be remelted in the furnace and some percentage of mother liquor 224 can be sent to the single pass 204.

Second pass 206 and 208 can be performed in difference furnaces. FIGS. 4 and 5 illustrate flakes 218 entering the first instance of the second pass 208 and the first repetition of the second pass 206 simultaneously, as well as second pass flakes 220 leaving both process steps 202 and 204 to enter the third pass 210; however, the steps can occur in series. The second pass flakes 220 can then be fed into a third pass 210 recrystallizing process to produce third pass flakes 222 (e.g. final recrystallized-silicon). New solvent metal 212 starts in the process at the third pass 210 and is fed through the process in mother liquor 224 in the opposite direction as the silicon, resulting in a eutectic or mother liquor 214 that can be sold off as a useful by-product. In this way, the solvent metal in the mother liquor 224 decreases in purity and runs through the system in the opposite direction as the silicon 218, 220, 222, which increases in purity.

### Acid Washing

The method of purifying silicon includes washing the final recrystallized-silicon crystals with an aqueous acid solution to provide a final acid-washed-silicon. In the washing step, any suitable washing with an aqueous acid solution can be used to provide the final acid-washed-silicon. In some embodiments, a cascading dissolution and washing process is used. The washing step, including dissolution and washing processes, can contain single or multiple stages. Water and dissolving chemicals can be recycled through the process towards the beginning of the process. Although a series of steps are described in example embodiments below, including acid washing, water washing, and drying, to produce a final acid-washed-silicon from the final recrystallized-silicon crystals of the recrystallization step, it is to be understand that any suitable process of dissolving aluminum or other undesired impurities from the final recrystallized silicon to give a final acid-washed silicon is encompassed as an example of an embodiment of the acid-washing steps of the method of the present invention. Some examples of suitable acid-washing steps can be found in U.S. patent application Ser. No. 12/760,222, hereby incorporated by reference in its entirety.

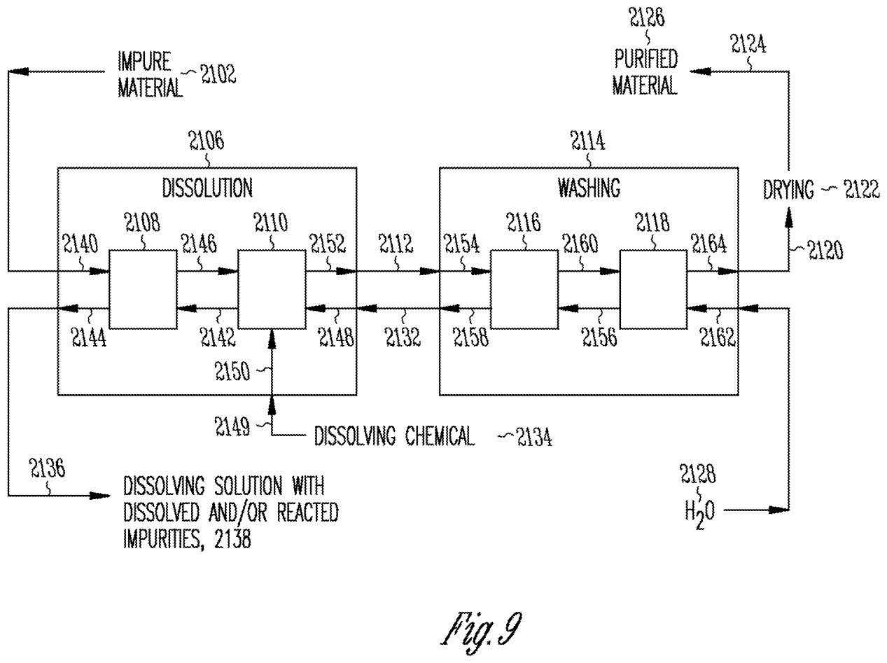

Referring to FIG. 9, a general flow diagram of a specific embodiment 2100 of the washing steps of the present invention is shown, which takes final crystallized silicon as a starting material and produces a final acid-washed silicon as a product. Impure material 2102 (starting as final recrystallized-silicon crystals) can move through the process in the forward direction as water 2128 and dissolving chemical 2134 can move through the process in the opposite, or backwards, direction. Impure material 2102 can enter the acid wash process 2104 by beginning a dissolution phase 2106. The dissolution phase 2106 can include multiple cascading dissolution stages, including dissolution stage one 2108 and dissolution stage two 2110. The dissolution phase 2106 can selectively dissolve or react with an impurity or impurities in the material to be purified. Next, the material to be purified can exit 2112 the dissolution phase 2106 and enter a washing phase 2114. The washing phase 2114 can include multiple cascading stages, including first washing stage 2116 and second washing stage 2118. The washed material can then exit 2120 the washing phase and enter 2120 a drying phase 2122. After being dried, the material can exit 2124 the drying phase 2122, providing a dried purified material 2126 (e.g. final acid washed-silicon).

Although as described above the dissolution phase can include multiple cascading stages, the dissolution phase can alternatively include one dissolving stage. Rinse water from the washing phase and aqueous acid can enter the single dissolving stage, such that the desired concentration of aqueous acid is formed. To maintain the pH, volume, concentration, or specific gravity of a single dissolving stage, the acid solution can be transferred completely or in portions out of the single dissolving stage and out of the dissolving phase. Impure material beginning the process can enter directly into the single dissolving stage. Additionally, more than two dissolving stages can alternatively be included in the dissolution phase. The last stage of the dissolution phase can generally be the phase in which rinse water from the washing phase and bulk dissolving chemical will be added to form the strong acid solution.

Although as described above the washing phase can include multiple cascading stages, the washing phase can alternatively include one washing stage. Fresh water can enter the single dissolving stage, and material to be washed from the dissolution phase can directly enter the single washing stage. After separation of the material and the rinse water in the single dissolving stage, the rinse water can directly enter the dissolution phase. Additionally, more than two washing stages can alternatively be included in the washing phase. The last stage of the dissolution phase can generally be the phase in which fresh water can be added.

The dissolution phase can allow selective dissolution or reaction with multiple impurities as the material to be purified passes through the dissolution phase. Alternatively, the dissolution phase can allow selective dissolution or reaction with one impurity as the material to be purified passes through the dissolution phase.

The drying can take place by any suitable manner known to those in the art. The drying can include drying by blowing air across the material, drawing air across a material such as by vacuum, the use of heating, centrifugal force, dipping or immersing in organic solvents miscible with water, shaking, allowing to drip-dry, or a combination thereof. Any suitable number of drying phases is encompassed within embodiments of the present invention.

Still referring to FIG. 9, as the material to be purified moves through the process in the forward direction, water 2128 can enter 2130 the end of the washing phase 2114. Water can pass through the washing phase 2114, removing acid and the dissolved or reacted impurities from the purified material; thus, the water can exit 2132 the washing stage 2114 containing acid and dissolved or reacted impurities. The water can enter 2132 the end of the dissolution phase 2106. In the dissolution phase 2106, the water can be combined with bulk acid 2134 in an amount sufficient to generate a dissolving solution of the desired concentration. The dissolving solution can pass through the dissolution phase 2106, becoming a progressively less strong acid solution as it dissolves and reacts with the impurities in the material to be purified. The acid solution can exit 2136 the dissolution phase 2106, providing an acid solution containing the dissolved and/or reacted impurities 2138.

The acid can be any suitable acid known to those in the art. The acid can include any suitable concentration of acid in any suitable solvent. The acid can include HCl, H₂PO₄, H₂SO₄, HF, HNO₃, HBr, H₃PO₂, H₃PO₃, H₃PO₄, H₃PO₅, H₄P₂O₆, H₄P₂O₇, H₅P₃O₁₀, or a combination thereof. At least one of the acid solutions can include a peroxide compound, such as H₂O₂.

The impurities can be only dissolved in the acid solution, and not reacted. Alternatively, the impurities can be only reacted by the acid solution, and not dissolved. Alternatively, the impurities can be both dissolved and reacted with the acid solution. Also, the impurities can be first dissolved, and then reacted with the acid solution, such that the impurities do not appreciably react with the acid prior to dissolution. Also, the impurities can be first reacted, and then dissolved with the acid solution, such that the impurities do not appreciably dissolve prior reacting with the acid. Reacting with the acid solution can include transformation into a different compound or combination with a different element or compound. Thus, in situations where an impurity first is reacted prior to dissolution, possibly the dissolution can be characterized as dissolving a compound other than the impurity, due to the chemical transformation of the impurity prior to dissolution.

After impure material 2102 enters 2104 the dissolution phase 2106, the material can enter 2140 the first dissolution stage 2108 and can be combined with a weaker acid solution to provide a mixture. The impure material and the acid solution can be allowed to mix for a sufficient time and at a sufficient temperature to allow at least partial dissolution or reaction of the acid solution with the impurities. The combination can be then separated, such that the acid solution that contains the dissolved or reacted impurities can remain in the first dissolution stage 2108 or can exit 2144 the stage partially or completely, and material that has had at least some of its impurities reacted or dissolved away can exit 2146 the first dissolution stage 2108. Water from the wash phase can be added 2148 in portions or completely to the second dissolution stage 2110 and portions of acid 2134 can be added 2149 to the dissolution phase, which can enter 2150 the second dissolution stage 2110, sufficient to generate a dissolving solution of the desired concentration in the second dissolving stage 2110. The material to be purified can enter 2146 the second dissolution stage 2110 and combine with a stronger dissolving solution to provide a mixture. The impure material and the acid solution can be allowed to mix for a sufficient time and at a sufficient temperature to allow at least partial dissolution or reaction of the acid solution with the impurities. The combination can be then separated, such that acid solution that contains the dissolved or reacted impurities can remain in the second dissolution stage 2110 or can exit 2142 the stage partially or completely, and material that has had at least some of its impurities reacted or dissolved away can exit 2152 the second dissolution stage 2110, and subsequently can exit 2112 the dissolution phase 2106.

A sufficient time or a sufficient temperature as described above can include any suitable time or temperature as known to those of skill in the art. The sufficiency of time can be determined by the limitations of the physical process of combination as well as the reaction or dissolution time. The reaction or dissolution of the impurity with the dissolving solution can produce heat as an exothermic reaction or dissolution. Alternatively, the reaction of dissolution of the impurity with the dissolving solution can reduce heat as an endothermic reaction or dissolution. The heat generated or taken by a dissolution or reaction can be used in certain embodiments to help to control the sufficient temperature of the reaction. In other embodiments, the heat generated or taken by a dissolution or reaction can be counteracted by heating or refrigerating or other heat-controlling means to achieve the sufficient temperature. The sufficient time can sometimes be exceeded without negatively affecting the method. Likewise, a shorter time than a time adequate to completely, mostly, or more than at least partially dissolve or react with the impurity can be sometimes still be a sufficient time under the present invention. The temperature of the dissolution or reaction can affect the amount of time that is sufficient. Likewise, the amount of time used can affect the temperature that is deemed sufficient.

After the material enters 2112 the washing phase 2114, the material can enter 2154 the first washing stage 2116 and can be combined with rinse solution that contains some acid and dissolved or reacted impurities. The material and the rinse solution can be allowed to mix for a sufficient time and at a sufficient temperature to allow at least some of the dissolved or reacted impurities or the dissolving chemical to enter the rinse solution. The combination can be then separated, such that rinse solution that contains the dissolved or reacted impurities or acid can remain in the first washing stage 2116 or can exit 2158 partially or completely the first washing stage 2116, and can subsequently partially or completely exit the washing phase 2114. The material that has had some of the reacted or dissolved impurities or acid washed away can exit 2160 the first washing stage 2116 and can enter 2160 the second washing stage 2118, where it can be combined with a second rinse solution that can be fed 2162 by water entering 2130 the washing phase 2114 and subsequently entering 2162 the second washing stage 2118. The material and the rinse solution can be allowed to mix for a sufficient time and at a sufficient temperature to allow at least some of the dissolved or reacted impurities or the acid to enter the rinse solution. The combination can then be separated, such that rinse solution that contains the dissolved or reacted impurities or acid can remain in the second washing stage 2118 or can exit 2156 partially or completely the second washing stage 2118, and material that has had some of the reacted or dissolved impurities or acid washed away can exit 2164 the second washing stage 2118, and subsequently can exit 2120 the dissolution phase 2114.

In embodiments of the present invention, combining to form a mixture can occur by any suitable means known to those of skill in the art. Combining includes pouring, dipping, immersing, pouring two streams together, blending, or any other suitable means. Mixing in embodiments of the present invention can include mixing by any suitable means, including by agitation, stirring, injecting gases into the liquid to create stirring, dipping, tea-bagging, repeatedly tea-bagging, or by simply allowing the combined materials to sit together without any agitation, or with very slight agitation, or by any combination thereof. The agitation can be coincident with the combination means.

In embodiments of the present invention, combinations can be separated by any suitable means known to those of skill in the art, including decanting, filtering, or removing a perforated basket or bin containing a solid from a liquid-containing tank and allowing at least some of the liquid to drain back into the tank, or a combination thereof.

In embodiments of the present invention, the temperature of any stage of the process can be influenced by a heater or a cooler.

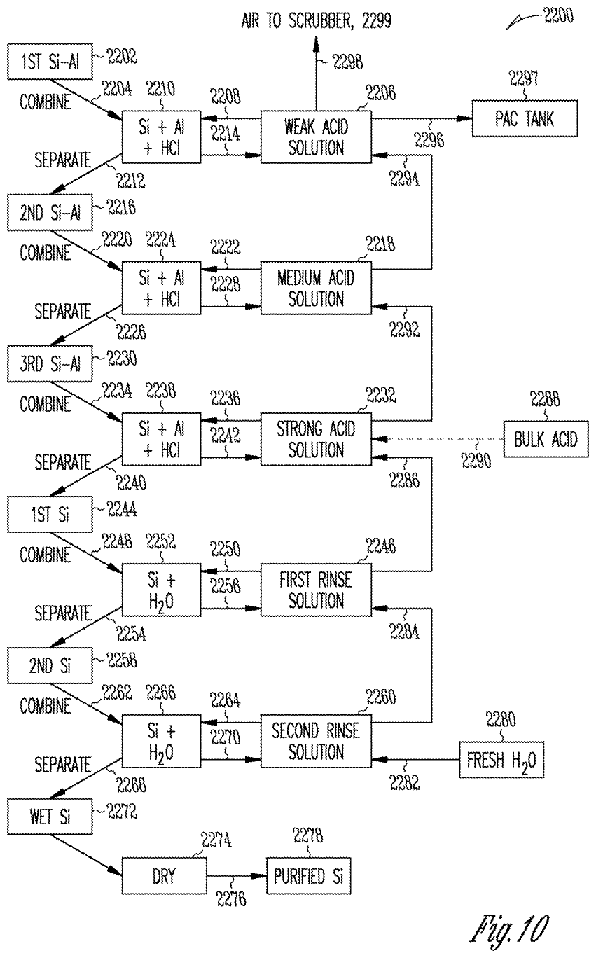

Referring to FIG. 10, a flow diagram of a method 2200 for acid washing silicon in a specific embodiment of the present invention is shown. A first silicon-aluminum complex 2202 (e.g. the final recrystallized silicon) and a weak acid solution 2206 can be combined 2204 and 2208 to provide a first mixture 2210. The first mixture 2210 can be allowed to exist for sufficient time and at sufficient temperature such that the first complex 2202 at least partially reacts with the weak acid solution 2206, wherein reacting can include dissolving. The first mixture 2210 can then be separated 2212 and 2214, providing a second silicon-aluminum complex 2216 and the weak acid solution 2206. Next, the second silicon-aluminum complex 2216 and a medium acid solution 2218 can be combined 2220 and 2222 to provide a second mixture 2224. The second mixture 2224 can be allowed to exist for sufficient time and at sufficient temperature such that the second complex 2216 at least partially reacts with the medium acid solution 2218, wherein reacting can include dissolving. The second mixture 2224 can then be separated 2226 and 2228, providing a third silicon-aluminum complex 2230 and the medium acid solution 2218. Next, the third silicon-aluminum complex 2230 and a strong acid solution 2232 can be combined 2234 and 2236 to provide a third mixture 2238. The third mixture 2238 can be allowed to exist for sufficient time and at sufficient temperature such that the third complex 2230 at least partially reacts with the strong acid solution 2232, wherein reacting can include dissolving. The third mixture 2238 can then be separated 2240 and 2242, providing a first silicon 2244 and the strong acid solution 2232. The first silicon 2244 and a first rinse solution 2246 can then be combined 2248 and 2250, providing a fourth mixture 2252. The fourth mixture 2252 can be allowed to exist for sufficient time and at sufficient temperature such that at least some of the dissolved or reacted impurities or acid solution that can be part of the first silicon 2244 enters the first rinse solution 2246. The fourth mixture 2252 can then be separated 2254 and 2256, providing a second silicon 2258 and the first rinse solution 2246. The second silicon 2258 and a second rinse solution 2260 can be then combined 2262 and 2264, providing a fifth mixture 2266. The fifth mixture 2266 can be allowed to exist for sufficient time and at sufficient temperature such that at least some of the dissolved or reacted impurities or acid solution that can be part of the second silicon 2258 enters the second rinse solution 2260. The fifth mixture 2266 can then be separated 2268 and 2270, providing a wet purified silicon 2272 and the second rinse solution 2260. The wet purified silicon can then be dried 2274, sufficient to provide 2276 a purified silicon 2278.

One skilled in the art will recognize that the preceding discussion of FIG. 9 including that regarding single or multiple stages, multiple or single impurities, drying methods, dissolving or reacting in any order, sufficient time and temperature, and separation, applies equally to the embodiment depicted in FIG. 10.

Although the embodiment described above has three dissolving stages in the dissolution phase, embodiments of the present invention also encompass dissolution phases with only one or with any suitable number of dissolving stages. Also, although the embodiment described above has two washing stages in the washing phase, embodiments of the present invention also encompass washing phases with only one or with any suitable number of washing stages. Likewise, although the embodiment described above has one drying phase, embodiments of the present invention also encompass any suitable number of drying phases.

The silicon-aluminum complex (e.g. final recrystallized-silicon, or any silicon-aluminum complex in embodiments of the present invention) can include silicon crystals, and an alloy of silicon and aluminum. At least one of a series of steps of combining to provide a mixture and then separating can provide a more pure silicon or silicon-aluminum complex than the silicon or silicon-aluminum complex that went into the series of steps. At least one of a series of steps of combining with acid solution to provide a mixture and then separating can provide a silicon with less aluminum than the silicon-aluminum complex that went into the series of steps.

Still referring to the specific embodiment depicted in FIG. 10, fresh water 2280 can be added 2282 to the second rinse solution 2260 to maintain the volume of the second rinse solution 2260. Portions of the second rinse solution 2260 can be transferred 2284 to the first rinse solution 2246 to maintain the volume of the first rinse solution 2246. Portions of the first rinse solution 2246 can be transferred 2286 to the strong acid solution 2232 to maintain the pH of the strong acid solution 2232, to maintain the volume of the strong acid solution 2232, to maintain the specific gravity of the strong acid solution 2232, or a combination thereof. Portions of a bulk acid solution 2288 can be added 2290 to the strong acid solution 2232 to maintain the pH of the strong acid solution 2232, to maintain the volume of the strong acid solution 2232, to maintain the specific gravity of the strong acid solution 2232, or a combination thereof. The bulk acid solution can be, for example, HCl. The bulk acid solution can be 32% HCl. The bulk acid solution can be any suitable concentration of acid. The strong acid solution 2232 can have, for example, a pH of between approximately −0.5 and 0.0, and a specific gravity of approximately 1.01-1.15. Portions of the strong acid solution 2232 can be transferred 2292 to the medium acid solution 2218 to maintain the pH of the medium acid solution 2218, to maintain the volume of the medium acid solution 2218, to maintain the specific gravity of the medium acid solution 2218, or a combination thereof. The medium acid solution can have, for example, a pH of between approximately 0.0 and 3.0, and a specific gravity of approximately 1.05-1.3. Portions of the medium acid solution 2218 can be transferred 2294 to the weak acid solution 2206 to maintain the pH of the weak acid solution 2206, to maintain the volume of the weak acid solution 2206, to maintain the specific gravity of the weak acid solution 2206, or a combination thereof. Portions of the weak acid solution 2206 can be removed 2296 to maintain the pH and specific gravity of the weak acid solution 2206. The weak acid solution 2206 can have, for example, a pH of between approximately 1.0 and 3.0, and a specific gravity of approximately 1.2-1.4. The removed portions of the weak acid solution 2206 can be transferred 2296 to a polyaluminum chloride tank 2297. The polyaluminum chloride tank 2297 can have, for example, a pH between approximately 1.5 and 2.5, and a specific gravity of approximately 1.3. The PAC tank 2297 can also have, for example, a specific gravity of approximately 1.2-1.4. Gas from above the weak acid solution, which can include hydrogen (¾), steam, and acid gas such as for example HCl gas, can be transferred 2298 to a scrubber 2299 to remove impurities before releasing into the environment. The head space above at least one of the medium acid solution, the strong acid solution, or the rinse solutions can be connected to the head space above the weak acid solution, such that the gas removed from the head space of the weak acid solution includes steam or gas originated from the weak acid solution and at least one of the medium acid solution, the strong acid solution, or the first or second rinse solutions.

Embodiments of the present invention encompass optionally transferring portions of fresh water or rinse water from any rinse stage to any solution to maintain or adjust the pH, volume, or specific gravity of that solution. Although specific examples are given herein for the pH and specific gravity of three acid tanks in a three stage acid wash, and for the PAC tank, it is to be understood that the range and values of the pH and specific gravity can vary significantly from these examples and still be encompassed as an embodiment of the present invention. Likewise, the labels “strong”, “medium”, and “weak” are intended to indicate the relationship between the strength of the acid solutions, rather than to limit any particular acid solution to a particular value or range of pH or specific gravity. Thus, in an embodiment with two acid wash stages, in which the acid solutions are labeled “weak” and “strong”, both acid solutions could be characterized as strong acid solutions, although the relationship between the acid solutions is such that one acid solution (“strong”) is stronger than the other (“weak”). Likewise, in an embodiment with two acid wash stages, in which the acid solutions are labeled “weak” and “strong”, both acid solutions could be characterized as weak or medium strength acid solutions, although the relationship between the acid solutions is such that one acid solution (“weak”) is weaker than the other (“strong”).

In some embodiments, the silicon and the rinse solutions can be allowed to mix for approximately 24 hours prior to the separation step. In some embodiments, the silicon and the rinse solutions can be allowed to mix for approximately 1 hour prior to the separation step. In some embodiments, the drying step can be conducted for at least 3 hours. The times of the steps of the present invention can include any suitable times.

At least one of the acid solutions, mixtures, and rinse solutions can be in tanks. The silicon-aluminum complexes, the first and second silicons, and the wet and dry purified silicon can be transferred from tanks using temperature- and chemical-resistant bins that have holes to allow fluids into and out of the bins. The bins can be drained during separation. At least one acid solution tank can hold two bins. At least one tank in which a series of steps of combining and separating occurs can be positioned such that when the contents reach a certain height they overflow into a tank in which an earlier series of steps of combining and separating occur. A tank that includes both an overflow outlet and inlet can have the overflow outlet and inlet positioned on opposite sides of the tank. At least one of the acid solutions, mixtures, and rinse solutions can be in settling tanks. Solids can be removed from settling tanks. Removal of solids can include opening a valve at the bottom of a tank to allow solids to be extruded from the bottom of a tank. Removal of solids can include draining the liquid from the tank and manually or mechanically removing the solids from the bottom of the tank.

As well as encompassing the use of one tank per cascading step, embodiments of the present invention encompass the use of a single tank for the entire process, and the use of less tanks than there are steps in the cascade. For example, one tank could be used for multiple acid dissolution steps, and then one tank could be used for the rinse steps. For example, two tanks could be used for multiple acid dissolution steps, and two tanks could be used for the rinse steps. Another example includes the use of one tank for one or more acid dissolution steps, and the use of the same tank for one or more rinse steps. The acid solutions and the rinse solutions can be added to a tank holding silicon-aluminum complexes or silicon for rinsing. Once the acid dissolution or rinse step is complete, the solution can be removed from the tank and moved to a storage location or discarded, and the next solution can be added to the tank to begin the next cascading step. One or more tank that holds the flakes can be a settling tank. The maintaining of the pH, specific gravity, and volume of the solutions can occur in the one or more tanks that holds the flakes, in the storage location for each particular solution, or both. The silicon-aluminum complexes, the first and second silicons, and the wet and dry purified silicon can be held in one or more particular tanks in any suitable manner, including using temperature- and chemical-resistant bins that have holes to allow fluids into and out of the bins. The bins can be drained during separation, either while inside the tank when the solution is transferred out, or by lifting the bin out of the tank to allow the solution inside the bin to flow back into the tank. A tank can hold two bins, or any suitable number of bins, including one bin. The storage location of at least one of the acid solutions, mixtures, or rinse solutions can be a settling tank. Solids can be removed from settling tanks. Removal of solids can include opening a valve at the bottom of a tank to allow solids to be extruded from the bottom of a tank. Removal of solids can include draining the liquid from the tank and manually or mechanically removing the solids from the bottom of the tank.

At least one of a series of steps of combining with a rinse solution to provide a mixture and then separating can provide a silicon with less product of the reaction of the acid solution and aluminum than the silicon that went into the series of steps.

The dry purified silicon can have approximately 1000-3000 parts per million weight aluminum. At least one of the first, second, or third silicon-aluminum complex, the first or second silicons, the wet silicon, or the dry purified silicon can be independently approximately 400 to 1000 kg. At least one of the first, second, or third silicon-aluminum complex, the first or second silicons, the wet silicon, or the dry purified silicon can be independently approximately 600 to 800 kg. At least one of the first, second, or third silicon-aluminum complex, the first or second silicons, the wet silicon, or the dry purified silicon can be independently approximately 650 to 750 kg.

The specific ranges of pH and specific gravity described above are one or more specific embodiments of the present invention. Embodiments of the present invention encompass any suitable range of pH or specific gravity for the various stages of the method. For example, in a three step acid dissolution, the strong acid solution can have a pH of approximately −0.5 to 4, the medium acid solution can have a pH of approximately 0.0 to 4, and the weak acid solution can have a pH of approximately 0.0 to 5. In another example, the strong acid solution can have a pH of approximately −0.5 to 1, the medium acid solution can have a pH of approximately 0.0 to 3, and the weak acid solution can have a pH of approximately 1.0 to 4.0. In another example, the strong acid solution can have a pH of approximately −0.5 to 0.0, the medium acid solution can have a pH of approximately 0.0 to 2.5, and the weak acid solution can have a pH of approximately 1.5 to 3.0. In another example, in a two stage acid dissolution, the strong acid solution can have a pH of approximately −0.5 to 4, and the weak acid can have a pH of approximately 0.0 to 5. In another example, with a two stage acid dissolution, the strong acid solution can have a pH of approximately −0.5 to 3, and the weak acid solution can have a pH of approximately 0.0 to 4. In another example, with a two stage acid dissolution, the strong acid solution can have a pH of approximately −0.5 to 1.0, and the weak acid solution can have a pH of approximately 1.0 to 3.0. All suitable variations of pH that maintain the relationship between stronger and weaker solutions are envisioned to be encompassed by embodiments of the present invention.

Likewise, for example, in a three step acid wash, the strong acid solution can have a specific gravity of approximately 1.01 to 1.4, the medium acid solution can have a specific gravity of approximately 1.01-1.4, and the weak acid solution can have a specific gravity of approximately 1.01-1.4. In another example, the strong acid solution can have a specific gravity of approximately 1.01-1.3, the medium acid solution can have a specific gravity of approximately 1.01-1.2, and the weak acid solution can have a specific gravity of approximately 1.1-1.4. In another example, the strong acid solution can have a specific gravity of approximately 1.01-1.10, the medium acid solution can have a specific gravity of approximately 1.05-1.15, and the weak acid solution can have a specific gravity of approximately 1.2-1.4. In another example, the strong acid solution can have a specific gravity of approximately 1.05, the medium acid solution can have a specific gravity of approximately 1.09, and the weak acid solution can have a specific gravity of approximately 1.3. In another example, with a two stage acid dissolution, the strong acid solution can have a specific gravity of approximately 1.01-1.4, and the weak acid solution can have a specific gravity of approximately 1.01-1.4. In another example, with a two stage acid dissolution, the strong acid solution can have a specific gravity of approximately 1.01-1.3, and the weak acid solution can have a specific gravity of approximately 1.01-1.4. In another example, with a two stage acid dissolution, the strong acid solution can have a specific gravity of approximately 1.01-1.2, and the weak acid solution can have a specific gravity of approximately 1.1-1.4. All suitable variations of specific gravity are envisioned to be encompassed by embodiments of the present invention.

The removing of portions to maintain pH, volume, specific gravity, or a combination thereof of any step individually can be conducted as a batch process or as a continuous process. Sensors can be used to detect at least one of a liquid height, a pH, a specific gravity, a flow rate, a temperature, or a combination thereof. Any suitable sensor device useful for detecting any characteristic of the solutions suitable for allowing adjustment of their properties by the methods of the present invention are included within embodiments of the present invention.

Sensors suitable for use in a continuous process can differ from those suitable for use in a batch process.

The use of the word “portion” is not intended in any way to limit the scope of the embodiments of the present invention to batch processes.

Moreover, infinitely small portions can be continuously removed in a continuous process; thus, the word “portion” does not limit the present invention to batch processes.

The removed portions of the weak acid can include polyaluminum chloride. The removed portions of the weak acid can include aluminum trichloride. The removed portions of the weak acid solution can include a product of the reaction of aluminum with HCl, water, or a combination thereof. The first polyaluminum chloride tank can include a settling tank. Portions of the contents of the polyaluminum chloride tank can be transferred from the top of the tank to the middle of another polyaluminum chloride tank, wherein the next polyaluminum chloride tank includes a settling tank. The steps of transferring liquid from the top of a settling tank to the middle of another settling tank can be repeated using a sequence of settling tanks until the liquid from the last settling tank in a sequence of settling tanks is sufficiently free of solid material. The steps of transferring liquid from the top of a settling tank to the middle of another settling tank can be repeated using a sequence of settling tanks until the liquid from the last settling tank in a sequence of settling tanks is sufficiently free of solid material to be used in a water purification process.

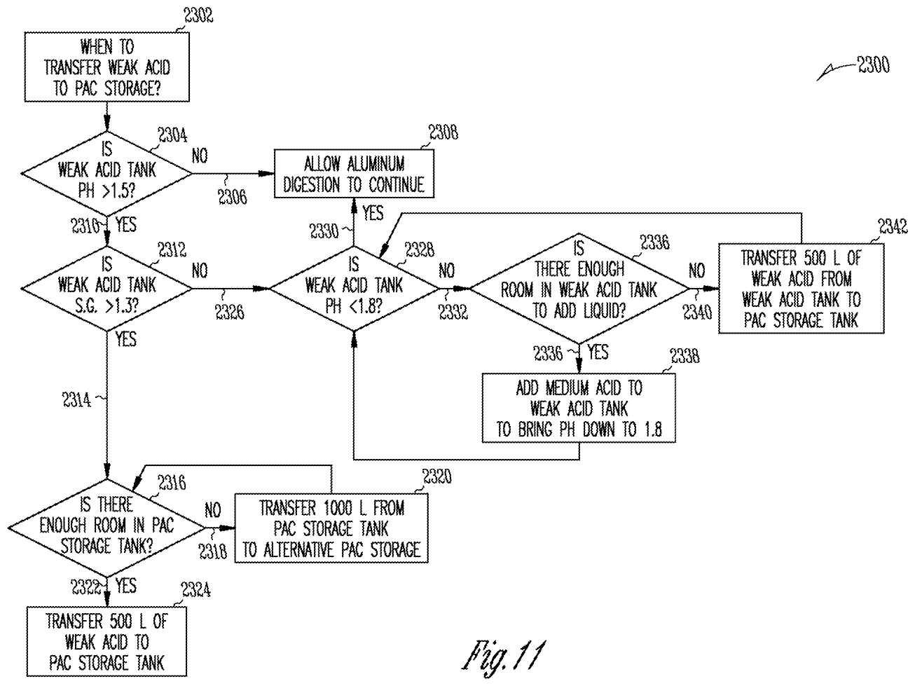

Referring to FIG. 11, a decision tree 2300 describes when to remove portions of the weak acid solution in a specific embodiment of the present invention. A query can be made of when to transfer portions of the weak acid to a polyaluminum chloride tank. First, if the answer to the query 2304 of whether the weak acid tank has a pH of greater than 1.5 is negative, 2306, then aluminum dissolution or reaction can be allowed to continue in the weak acid tank, 2308; if the answer is affirmative, 2310, then the value of the specific gravity of the weak acid tank is queried, 2312. If the answer to the query 2312 of whether the weak acid tank has a pH of greater than 1.3 is affirmative, 2314, then the remaining space in the PAC tank is queried 2316. If the answer to the query 2316 of whether there is adequate space in the PAC storage tank is negative, 2318, then 1000 L can be transferred from the PAC storage tank to an alternative PAC storage tank 2320 and the remaining space in the PAC tank can then be re-queried 2316. If the answer to the query 2316 of whether there is adequate space in the PAC storage tank is affirmative, 2322, then 500 L of weak acid can be transferred to a PAC storage tank, 2324. If the answer to the query 2312 of whether the weak acid tank has a pH of greater than 1.3 is negative, 2326, then the pH of the weak acid tank can be queried, 2328. If the answer to the query 2328 of whether the pH of the weak acid tank is below 1.8 is affirmative, 2330, then aluminum dissolution or reaction can be allowed to continue in the weak acid tank, 2308; if the answer is negative, 2332, then the remaining space in the weak acid tank can be queried 2334. If the answer to the query 2334 of whether there is enough room in the weak acid tank to add liquid is affirmative, 2336, then portions of the medium acid can be added to the weak acid to bring the pH down to 1.8, and the pH of the weak acid tank is re-queried 2328. If the answer to the query 2334 of whether there is enough room in the weak acid tank to add liquid is negative, 2340, then 500 L of weak acid can be transferred from the weak acid tank to the PAC storage tank, 342, and the pH of the weak acid tank can be re-queried, 2328. After reaching decision 2308 to allow aluminum digestion to continue, or reaching decision 2324 to transfer 500 L of weak acid to the PAC storage tank, the decision tree is restarted with query 2302.

Generally, when action 2342 of transferring 500 L of weak acid from the weak acid tank to the PAC storage tank is reached in the decision tree, the quality of the PAC solution can be lowered. Generally, when action 2324 of transferring 500 L of weak acid to the PAC storage tank is reached in the decision tree, the quality of the PAC solution can be improved. However, embodiments of the present invention encompass methods that generate lower quality PAC solution as well as high quality PAC solution. It is to be understood that in an embodiment of the invention with two acid wash steps, decision box 2338 would instruct to add strong acid solution to the weak acid tank to bring the pH down to 1.8.

One of ordinary skill in the art will appreciate that the series of steps shown in the decision tree illustrated in FIG. 11 are not limited to the specific pH levels or transferred volumes given as examples in the Figure. The pH levels used to make decisions, or the respective volumes that are transferred, can vary significantly from the specific examples given and still be encompassed by embodiments of the present invention. For example, decision box 2304 can query whether the pH of the weak acid tank is over approximately 1.0. In another example, decision box 2304 can query whether the pH of the weak acid tank is over approximately 1.3. In another example, decision box 2304 can query whether the pH of the weak acid tank is over approximately 1.8. In another example, decision box 2312 can query whether the specific gravity of the weak acid tank is greater than approximately 1.1. In another example, decision box 2312 can query whether the specific gravity of the weak acid tank is greater than approximately 1.2. In another example, decision box 2312 can query whether the specific gravity of the weak acid tank is greater than approximately 1.4. In another example, decision box 2328 can query whether the weak acid tank has a pH of less than approximately 1.6. In another example, decision box 2328 can query whether the pH of the weak acid tank has a pH of less than approximately 1.7. In another example, decision box 2328 can query whether the pH of the weak acid tank has a pH of less than approximately 2.0. In another example, decision box 2338 can add solution until the pH of the weak acid solution reaches approximately 1.6. In another example, decision box 2338 can add solution until the pH of the weak acid solution reaches approximately 1.7. In another example, decision box 2338 can add solution until the pH of the weak acid solution reaches approximately 2.0. In another example, the volume transferred in decision boxes 2342 or 2324 can be approximately 250 L. In another example the volume transferred in decision boxes 2342 or 2324 can be approximately 750 L. In another example, the volume transferred in decision boxes 2342 or 2324 can be approximately 1000 L. In another example, the volume transferred in decision box 2320 can be approximately 750 L. In another example, the volume transferred in decision box 2320 can be approximately 1250 L. All suitable variations of pH and volume transferred are envisioned to be encompassed by embodiments of the present invention.

The polyaluminum chloride tank described above can contain any suitable material, and is not limited to only polyaluminum chloride solution.

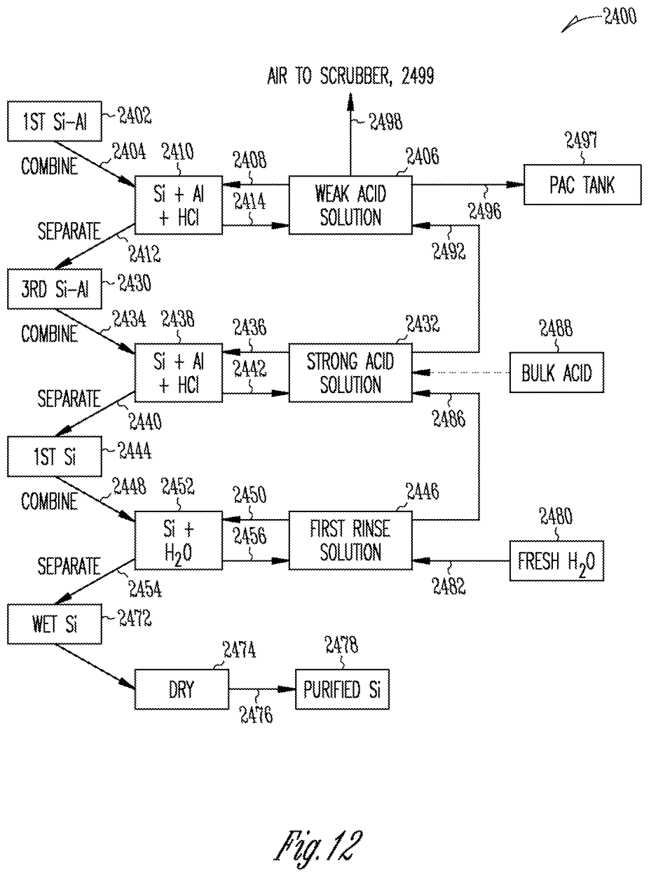

Referring to FIG. 12, a flow diagram of a method 2400 for the acid washing of silicon in a specific embodiment of the present invention is shown. A first silicon-aluminum complex 2402 (e.g. the final recrystallized-silicon) and a weak acid solution 2406 can be combined 2404 and 2408 to provide a first mixture 2410. The first mixture 2410 can be allowed to exist for sufficient time and at sufficient temperature such that the first complex 2402 at least partially reacts with the weak acid solution 2406, wherein reacting can include dissolving. The first mixture 2410 can then be separated 2412 and 2414 (with the possible interposing steps of combining and separating), providing a third silicon-aluminum complex 2430 and the weak acid solution 2406. Next, the third silicon-aluminum complex 2430 and a strong acid solution 2432 can be combined 2434 and 2436 to provide a third mixture 2438. The third mixture 2438 can be allowed to exist for sufficient time and at sufficient temperature such that the third complex 2430 at least partially reacts with the strong acid solution 2432, wherein reacting can include dissolving. The third mixture 2438 can then be separated 2440 and 2442, providing a first silicon 2444 and the strong acid solution 2432. The first silicon 2444 and a first rinse solution 2446 can then be combined 2448 and 2450, providing a fourth mixture 2452. The fourth mixture 2452 can be allowed to exist for sufficient time and at sufficient temperature such that at least some of the dissolved or reacted impurities or acid solution that can be part of the first silicon 2444 enters the first rinse solution 2446. The fourth mixture 2452 can then be separated 2454 and 2456 (with the possible interposing steps of combing and separating), providing a wet purified silicon 2472 and the first rinse solution 2460. The wet purified silicon can then be dried 2474, sufficient to provide 2476 a purified silicon 2478 (e.g. the final acid-washed silicon).

One skilled in the art will recognize that the preceding discussion of FIG. 9 including that regarding single or multiple stages, multiple or single impurities, drying methods, dissolving or reacting in any order, sufficient time and temperature, and separation, applies equally to the embodiment depicted in FIG. 12.

Although the embodiment described above has two dissolving stages in the dissolution phase, embodiments of the present invention also encompass dissolution phases with only one or with any suitable number of dissolving stages, e.g., one, two, three, four, or five dissolving stages. Also, although the embodiment described above has one washing stage in the washing phase, embodiments of the present invention also encompass washing phases with any suitable number of washing stages, e.g., one, two, three, four, or five rinse stages. Likewise, although the embodiment described above has one drying phase, embodiment of the present invention also encompass any suitable number of drying phases.

Still referring to the specific embodiment depicted in FIG. 12, fresh water 2480 can be added 2482 to the first rinse solution 2460 to maintain the volume of the first rinse solution 2460. Portions of the first rinse solution 2446 can be transferred 2486 to the strong acid solution 2432 to maintain the pH of the strong acid solution 2432, to maintain the volume of the strong acid solution 2432, to maintain the specific gravity of the strong acid solution 2432, or a combination thereof. Portions of a bulk acid solution 2488 can be added 2490 to the strong acid solution 2432 to maintain the pH of the strong acid solution 2432, to maintain the volume of the strong acid solution 2432, to maintain the specific gravity of the strong acid solution 2432, or a combination thereof. The bulk acid solution can be, for example, HCl. The bulk acid solution can be 32% HCl. The bulk acid solution can be any suitable concentration of acid. Portions of the strong acid solution 2432 can be transferred 2492 to the weak acid solution 2406 to maintain the pH of the weak acid solution 2406, to maintain the volume of the weak acid solution 2406, to maintain the specific gravity of the weak acid solution 2406, or a combination thereof. Portions of the weak acid solution 2406 can be removed 2496 to maintain the pH and specific gravity of the weak acid solution 2406. The removed portions of the weak acid solution 2406 can be transferred 2496 to a polyaluminum chloride tank 2497. The polyaluminum chloride tank 2497 can have, for example, a pH between approximately 1.5 and 2.5, and a specific gravity of approximately 1.3. The PAC tank 2497 can also have, for example, a specific gravity of approximately 1.2-1.4. Gas from above the weak acid solution, which can include hydrogen (¾), steam, and acid gas such as for example HCl gas, can be transferred 2498 to a scrubber 2499 to remove impurities before releasing into the environment.

The head space above at least one of the medium acid solution, the strong acid solution, or the rinse solutions can be connected to the head space above the weak acid solution, such that the gas removed from the head space of the weak acid solution includes steam or gas originated from the weak acid solution and at least one of the medium acid solution, the strong acid solution, or the first or second rinse solutions.

The entire discussion of variables above regarding the three stage acid dissolution process also applies equally to the two stage acid dissolution process, or to a process with any number of dissolution or rinse stages. Thus, embodiments of the present invention, with one or two or more dissolution stages, and with one or two or more washing stages, encompass optionally transferring portions of fresh water or rinse water from any rinse stage to any solution to maintain or adjust the pH, volume, or specific gravity of that solution. The “strong” and “weak” designators are relative indicators, rather than being restrictive of a certain range of pH. The process can be performed with any number of tanks, including one. The transfers of the liquid can occur in a batch or continuous fashion. Any suitable value of pH or specific gravity for the stages is encompassed by embodiments of the present invention.

### Directional Solidification

The method for purification of silicon also includes directionally solidifying the final acid-washed-silicon to provide final directionally solidified-silicon crystals. The directional solidification can be any suitable directional solidification that allows purification of the silicon to provide the final directional solidified-silicon crystals. The directional solidification can take place in a directional solidification apparatus that can include any directional solidification apparatus, including those described herein, and including standard known directional solidification apparatus. Some examples of suitable crucibles, apparatus, and methods for directional solidification can be found in U.S. patent application Ser. Nos. 12/716,889 and 12/947,936, hereby incorporated by reference in their entirety.

As the silicon solidifies during the directional solidification, impurities tend to prefer to stay in the molten phase as opposed to crystallizing out with the solidifying phase. The ingot can be directionally solidified by applying a temperature gradient to the silicon or inducing a temperature gradient in the silicon as it solidifies (e.g. freezes). The silicon can be directionally solidified from the bottom of the ingot to the top. Heat can be provided on the top of the ingot to form or aid in forming a temperature gradient, for example, or cooling can be provided on the bottom of the ingot to form or aid in forming the temperature gradient. In some examples, the silicon can be directionally solidified into a large multi-ton ingot, for example about 1-3 tons.

During the directional solidification, since the impurities tend to stay in the molten phase, the last part of the molten phase to solidify generally includes the highest concentration of impurities when compared to the rest of the directionally solidified silicon. Thus, after the directional solidification, a portion of the “last-to-freeze” silicon can be removed. “Last-to-freeze” silicon can refer to silicon that solidifies last in the sample ingot or boule and contains the most impurities; therefore, removal of this portion of the silicon can help to produce silicon that is overall more pure (e.g. wherein the average purity of the trimmed silicon is higher than the average purity of the pre-trimmed silicon). In some examples, about 5 to about 30% of the last-to-freeze silicon can be removed.

The directional solidification process can be repeated one or more times by directionally solidifying from bottom to top and removing, for example, about 5% to about 30% of the top of each of the silicon ingots formed. The top of the ingot, before it has frozen, can be removed, for example via pouring or siphoning. The last-to-freeze section can be cut off or can be broken off. The last-to-freeze silicon can be recycled back into the process at any pass. The sides and bottoms of the directionally solidified ingot can be cut off and recycled back into the process. The surface of the solid silicon can be blasted with media, such as sand blasted or ice blasted, or etched between any of the steps. Each additional directional solidification step further can purify the silicon on account of, for example, the differing segregation coefficient of each element. Any of the above steps can be repeated one or more times.

### Crucible Providing Efficient Utilization of Furnace Capacity

In some embodiments, either the melting of the silicon or the directional solidification of the silicon, or both, can be performed in a crucible that is designed to provide an efficient utilization of furnace capacity. In some embodiments, the crucible can approximately match the interior shape of the furnace in which the molten silicon is prepared.

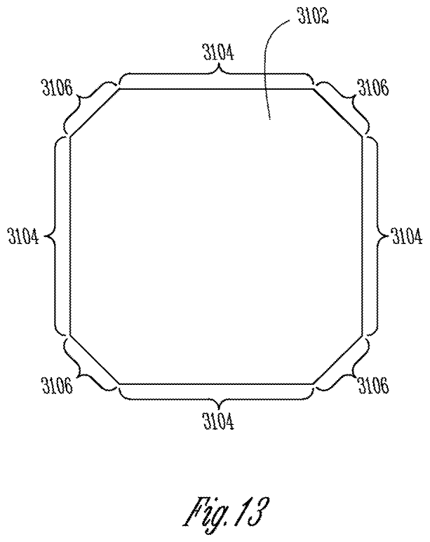

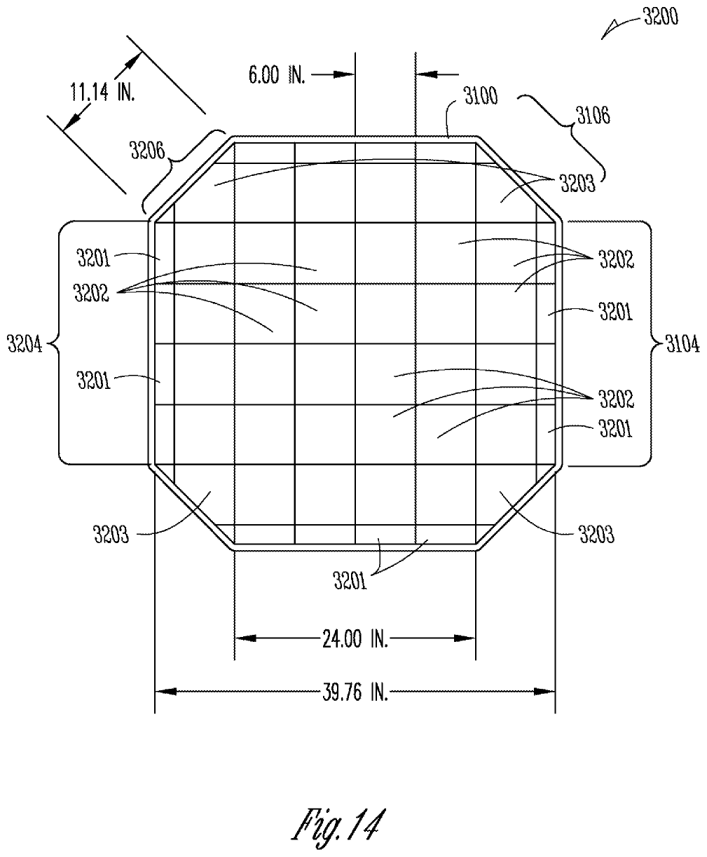

Referring to FIG. 13, a top-view of an embodiment of a crucible of the present invention, crucible 3100, is shown. The crucible 3100 includes an interior 3102 for the production of an ingot. Referring to FIG. 14, a top-view of an ingot 3200 in crucible 3100 is shown. The ingot 3200 can include portions of the perimeter 3201 that are trimmed off after the molten material goes through solidification, crystallization, or a combination thereof. The ingot 3200 includes a multiplicity of blocks 3202. The blocks 3202 can be formed from ingot 3200 using a cutting device. The ingot can include silicon. The molten material can include molten silicon. The blocks 3202 are arranged within the ingot 3200 in a grid. The exterior shape of crucible 3100 approximately matches the interior shape of a furnace in which ingots are produced, which can be a furnace with an interior compartment with an approximately round shape. By approximately matching the interior shape of the furnace, crucible 3100 can fit a larger quantity of molten material in the furnace, thus can more efficiently utilize the capacity of the furnace. By approximately matching the interior shape of an approximately round furnace, the crucible 3100 can generate an ingot 3200 that give a larger number of blocks 3202 than the number of blocks that can be generated from the furnace using a crucible with a square shape. When compared to a grid in an ingot from a square-shaped crucible, in ingot 3200 the percentage of side or center blocks relative to the percentage of corner blocks can be greater, and the percentage of side blocks relative the to percentage of center blocks can be increased. See Table 2. When compared to a square-shaped crucible, the percentage of corner blocks in ingot 3200 from crucible 3100 has been reduced.

TABLE 1

| | Blocks per Ingot | | | |
|---|---|---|---|---|
| | 16 | 25 | 32 | 36 |
| | blocks, | blocks, | blocks, | blocks, |
| | square | square | crucible | square |
| | crucible | crucible | 100 | crucible |
| Side | 50% | 48% | 50% | 44% |
| Corner | 25% | 16% | 0% | 11% |
| Center | 25% | 36% | 50% | 44% |

Some embodiments of crucible of the present invention include an ingot that includes blocks. The blocks are joined together in the ingot that results from the crucible. They become separate blocks by being cut apart from one another after the casting process is complete. The blocks can be cut in a grid pattern. The cutting can be done by any suitable cutting device known to those in the art. An example of a suitable cutting device is a saw that uses abrasive material, such as diamond, or cutting teeth, attached to a band that turns in a continuous loop. The cutting may include cooling with water to prevent overheating of the blade. Another example of a suitable cutting device is a wire saw which uses steel wire with cooling fluid and SiC grit or steel wire coated with diamond grit and a cooling fluid.

The causes of the inferior quality of an ingot can include in some examples the proximity of the solidified or crystallized material to the walls of the crucible. The crucible can be coated with or include a material that prevents the material from sticking to the crucible, allowing for easy removal of the solid. While helpful to prevent sticking, the coating or constituent of the crucible can diffuse into the molten material, affecting the purity of the solid material closest to the walls of the crucible. Therefore, when less of an ingot contacts the walls of the crucible, less material is contaminated by diffusion from a constituent or coating of the crucible. Additionally, the top surface of the silicon in the crucible in the corners can solidify last, and last-to-freeze material in a crystallization can contain the highest levels of impurities. The last-to-freeze portions of an ingot can be removed prior to use, e.g. with a cutting device, prior to use of the ingot. When less of an ingot contacts the walls of the crucible, less material is wasted by needing to trim it from the ingot prior to use. The present invention includes ingots that have less corners, such that they include less blocks that share two edges with the perimeter of the crucible. The present invention can thus produce a smaller percentage of lower quality product and can result in less waste or in less recycled silicon.

Again referring to FIG. 13, the crucible 3100 includes a perimeter which includes eight sides, 3104 and 3106. The eight sides include two sets of approximately opposing first sides 3104 which are of approximately equal length. The eight sides also include two sets of approximately opposing second sides 3106 which are of approximately equal length. The eight sides of crucible 3100 correspond to eight sides of the ingot 3200 that is formed from the crucible 3100, including first sides 3204 and second sides 3206. The first sides 3104 and the second sides 3106 are approximately flat. The first sides 3104 are longer than the second sides 3106. The first sides 3104 alternate with the second sides 3106. In a specific embodiment, the height of crucible 100 can be 2-20 cm taller than other crucibles, which can allow, for example, the same amount of silicon as a 36-block 750 kg square crucible could hold. Generally, in the present invention the height of the crucible can be made taller so that, e.g., lower density material such as lower density silicon can be used economically, such that that more material can be loaded into the crucible.

In a specific embodiment, the first sides 3204 can be for example about 5 to 40 inches, or about 10 to 30 inches, or about 24 inches. The second sides 3206 can be approximately 5-15 inches, for example 11.14 inches. The dimensions of the blocks 3202 can be about 6 inches×about 6 inches. The thickness of the sides of the crucible can be for example about 0.25 to about 2 inches, or about 0.5 to about 1 inches, or about 0.67 inches. The thickness of the material removed from the sides of the ingot 200 can be for example about 0.5-4 inches, or about 1-2 inches, or about 1.88 inches.

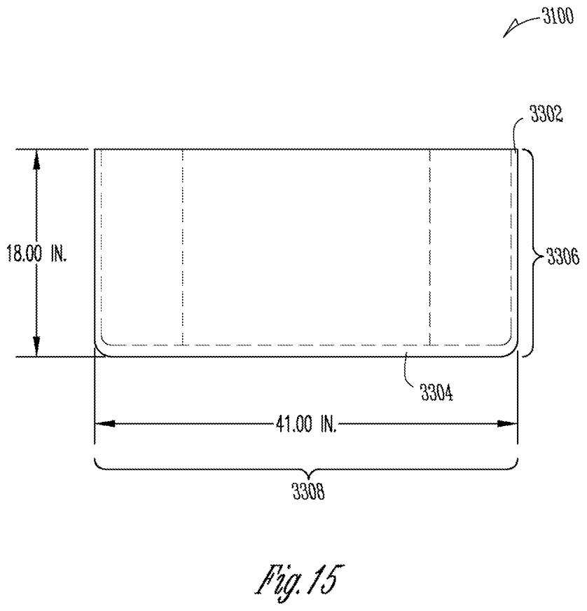

Referring to FIG. 15, a side view of the crucible 3100 in a specific embodiment is shown. The width of the crucible 3308 can be for example about 20-60 inches, or about 35-45 inches, or about 41 inches. The height of the crucible 3306 can be for example about 5-40 inches, or about 15-25 inches, or about 18.00 inches. The sides 3302 can be for example about 0.25 to about 4 inches thick, or about 0.5-1 inches thick, or about 0.67 inches thick. The crucible can have a bottom 3304.

In some embodiments, the crucible can include first sides and second sides that are approximately the same length. The crucible can include first sides that are curved, or that include curves, and the crucible can independently include second sides that are curved, or that include curves. Therefore, the crucible can include first sides that are curved, and second sides that are approximately straight; the crucible can also include second sides that are curved, and first sides that are approximately straight. The curve of a side can include multiple approximately flat surfaces that taken together form an arc shape, or that form more than one arc. The curve of a side can include one single curve. The curve of a side can include multiple curved surfaces that taken together form an arc shape, or that form more than one arc.

In some embodiments, the overall design can include a furnace that has four crucibles in it and only one corner in each crucible is reduced in area.

In some embodiments, the crucible can be made from or include, for example, silica, SiC, quartz, graphite, SSi₃N₄, or a combination thereof. The choice of constituents or coatings can include, for example, non-sticking properties, as well as heating resistant properties. The crucible can include a coating that contains Si₃N₄, graphite, or SiO₂ which can coat the crucible partially, completely, or to any degree in-between. The crucible can include internal angles between sides included in the perimeter of approximately 110-160 degrees. The crucible can include internal angles between sides included in the perimeter of approximately 125-145 degrees. The crucible can also include outer or inner corners and edges that are curved.

The present invention provides a method of using a crucible with an interior shape for the production of ingots, including the crucible as described above, wherein the exterior shape of the crucible approximately matches the interior shape of a furnace in which the molten material that generates the ingot is produced. The interior shape of the furnace can be approximately round. The interior shape of the furnace can be modified to fit the crucible.

In one specific embodiment, the dimensions of the crucible are such that the method can generate about 32 with dimensions of about 156 mm×about 156 mm from a furnace with an approximately 450 kg capacity and designed for production of about 25 blocks having dimensions of about 156 mm×about 156 mm using a standard square crucible. In another embodiment, the dimensions are such that that the method can generate about 21 blocks having dimensions of about 180 mm×about 180 mm blocks from a furnace with an approximately 450 kg capacity and designed for production of about 25 blocks using a standard square crucible.

The present invention can provide a method for improving the throughput of high-quality material. The present invention can provide a method for efficient and cost-effective quality control of the resulting ingots. Referring to the specific embodiment depicted in FIG. 14, the extra 4 half-blocks 3203 can be used for destructive and nondestructive testing to improve quality and speed up throughput time of wafer manufacturing. Measuring only 4 corner blocks 3203, rather than all the blocks 3202, can save time and related costs, including: saving measurement time, saving time needed for block cleaning after conducting measurements, and saving time needed for block cleaning before conducting block cutting post measurements. This can help to achieve higher throughput while maintaining necessary material quality.

The following measurements are included among those that can be conducted to help to control the quality of the material generated: a) measurement of axial (bottom-to-top) resistivity profiles on blocks, complemented by b) mapping recombination lifetime (bottom-to-top) and, in cases of high-carbon feedstock or at poor carbon control of the casting tool, the additional step c) infrared (IR) scanning for silicon carbide particles (bottom-to-top). Having the 4 corner blocks on which to conduct these measurements can have a beneficial outcome. Measurement a) can give reliable information about the growth front of the total ingot if specific growth characteristics of individual casting tools are known (this can be determined for every casting tool).

Subsequent wafering can be based on information about the growth front.

Measurement b) can allow measurement of the lifetime as a function of the distance from the crucible walls which, in turn, can give some guidance on potential measures to be initiated for material quality improvement in the wafer level. Measurement c) can give orientation information about the ingot.

The modification of the furnace to fit the crucible can be any suitable modification known to those skilled in the art. The modification can include making the bolts, washers, or plates of a box that holds or surrounds the ceramic crucible thinner. The box holding the crucible can be made from graphite plates. The modification can also include counter-sinking or counter-boring into the graphite plate a nut that is part of the box, or otherwise reducing the profile of hardware that holds the box together. Joints between the graphite plates can be dadoed, mortised, or dovetailed. A bottom graphite plate that holds the crucible can be enlarged. A stainless steel cage for holding the movable elements can be made octagonal with diagonals added to the corners or the size of the diagonals can be enlarged. The insulation of a cage can be made thinner. The heating elements can be moved closer to a wall of the furnace or the heater cage. The graphite nuts holding heating elements together can be counter-sunk or counter-bored. Angled graphite washers can be used on the diagonal support plates to maintain a flat surface or custom shapes can be used to maintain flat section to fasten the graphite plates together. Corner extensions can be added to a corner piece of the heating element to move the heating elements out on all sides, including moving the heating elements out 3″ on all sides. A lip for sealing the bottom of the cage can be made smaller. The modification could also include lowering the stand that holds the crucible to allow for a taller crucible. The legs that support the crucible stand can be upgraded to support the extra weight by adding another leg, moving the legs further apart or threaded into a thicker cooling plate. Other insulating materials can be used for the insulating steel cage other than rigidized graphite felt so that the section can be made thinner. Two insulation materials can be used with one material used away from the hot face in a two layer design. The second insulating material would have better insulating properties so that a thinner cross section can be used for the cage.

### Directional Solidification Assembly

In some embodiments, either the melting of the silicon or the directional solidification of the silicon, or both, can be performed in a directional solidification assembly. The assembly can include any suitable directional solidification assembly. In some embodiments, the directional solidification assembly can include the crucible described above, wherein the shape of the crucible allows an efficient utilization of furnace capacity. In other embodiments, the directional solidification assembly does not include a crucible designed to enter a furnace, and instead the melting of the silicon occurs within a different crucible, such as a crucible designed to approximately match the interior shape of the furnace or an other crucible, and is then transferred to the directional solidification apparatus. Any feature of the bottom mold portion of the directional solidification assembly described in this section can be included in embodiments of the crucible designed for efficient furnace capacity utilization described above.

### Directional Solidification Apparatus—Bottom Mold

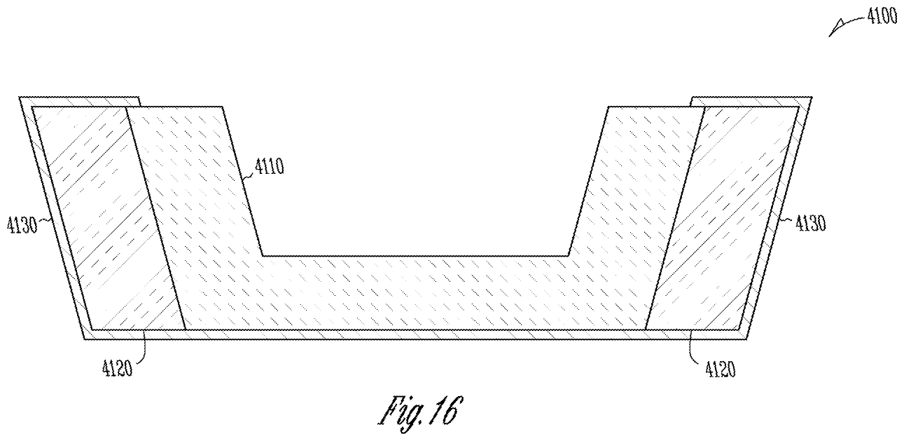

FIG. 16 illustrates an embodiment of the directional solidification apparatus. A side-view cut-away of the apparatus 4100 is shown. Apparatus 4100 includes a directional solidification mold 4110, which includes at least one refractory material. The at least one refractory material is configured to allow directional solidification of silicon within the mold. The apparatus 4100 also includes an outer jacket 4130. Additionally, the apparatus 4100 includes an insulating layer 4120, disposed at least partially between the directional solidification mold 4110 and the outer jacket 4130. The apparatus 4100 can be used more than once for the directional solidification of silicon.

The overall three-dimensional shape of an embodiment of the directional solidification apparatus can be similar to a thick-walled large bowl, having a circular shape.

Alternatively, the overall shape can be similar to a large bowl, having a square shape, or a hexagon, octagon, pentagon, or any suitable shape, with any suitable number of edges. In other embodiments, the overall shape of the apparatus can be any suitable shape for directional solidification of silicon. In one embodiment, the bottom mold can hold about 1 metric tonne of silicon, or more. In one embodiment, the bottom mold can hold about 1.4 metric tonnes of silicon, or more. In another embodiment, the bottom mold can hold about 2.1 metric tonnes of silicon, or more. In another embodiment, the bottom mold can hold approximately 1.2, 1.6, 1.8, 2.0, 2.5, 3, 3.5, 4, 4.5, or 5 metric tonnes of silicon, or more.

In preferred embodiments of the directional solidification apparatus, the apparatus is approximately symmetrical about a center vertical axis. An embodiment in which the materials included in the apparatus or the shape of the apparatus deviate from close symmetry about a center axis is still included as a preferred embodiment; the preference for symmetry is approximate, as will readily be understood by one of skill in the art. In some embodiments, the apparatus is not symmetrical about a center vertical axis. In other embodiments, the apparatus is partially approximately symmetrical about a center vertical axis and partially non-symmetrical about a center vertical axis. In embodiments that include non-symmetric features, any suitable feature can be included that is described herein, including features described as being part of an embodiment that is approximately symmetric about a center axis in whole or in part.

As shown in FIG. 16, the directional solidification mold 4110 has a greater than 90 degree internal angle between the bottom of the directional solidification mold and the sides of the directional solidification mold, referred to as a draft herein. The draft allows a piece of silicon solidified in the mold to be removed without having to break the silicon or the directional solidification mold. In a preferred embodiment, the directional solidification mold has a draft, as shown in FIG. 16, sufficient to allow the removal of silicon from the mold as described. However, in alternative embodiments, the directional solidification has no draft, or has the reverse of a draft. In alternative embodiments with no draft, the apparatus preferably will have a cut through the middle that allows it to be easily parted into two halves for removal of the solid silicon. The two halves can then be rejoined to again form a whole, and the apparatus reused. However, embodiments that can be broken into two halves are not restricted to those embodiments that lack draft. All embodiments discussed herein can either include or not include the ability to be separated into halves for easy removal of the solid silicon.

The embodiment of the directional solidification mold 4110 shown in FIG. 16 includes a refractory material. The refractory material can be any suitable refractory material. The refractory material can be aluminum oxide, silicon oxide, magnesium oxide, calcium oxide, zirconium oxide, chromium oxide, silicon carbide, graphite, or a combination thereof. The directional solidification mold can include one refractory material. The directional solidification mold can include more than one refractory material. The refractory material or materials that are included in the directional solidification mold can be mixed, or they can be located in separate parts of the directional solidification mold, or a combination thereof. The one or more refractory materials can be arranged in layers. The directional solidification mold can include more than one layer of one or more refractory materials. The directional solidification mold can include one layer of one or more refractory materials. The sides of the refractory can be a different material than the bottom of the refractory. The sides of the directional solidification mold as compared to the bottom of the directional solidification mold can be different thicknesses, include different compositions of material, include different amounts of material, or a combination thereof. In one embodiment, the sides of the directional solidification mold include a hot face refractory, and the bottom of the directional solidification mold includes a conducting refractory. The sides of the directional solidification mold can include aluminum oxide. The bottom of the directional solidification mold can include a heat-conductive material, such as, for example, silicon carbide, graphite, steel, stainless steel, cast iron, copper, or a combination thereof.

In some embodiments, the material or materials that are included in the sides of the directional solidification mold can extend from a height of the external-bottom of the directional solidification mold and upwards, and the material or materials that are included in the bottom of the directional solidification mold can extend vertically from a vertical position corresponding to the inside of one side of the directional solidification mold across the bottom to the a vertical position corresponding to the inside of the opposite side. In another embodiment, the material or materials that are included in the sides of the directional solidification mold can extend from a height of the internal-bottom of the directional solidification mold and upwards, while the material or materials that are included in the bottom of the directional solidification mold can extend vertically from a vertical position corresponding to the outside of one side of the directional solidification mold across the bottom of the directional solidification mold to a vertical position corresponding to the outside of the opposite side of the directional solidification mold. In another example, the material or materials that are included in the sides of the directional solidification mold can extend from a height above the height of the bottom of the directional solidification mold and upwards, while the material or materials that are included in the bottom of the directional solidification mold can extend vertically across the bottom of the directional solidification mold from a vertical position corresponding to one external side of the directional solidification mold to a vertical position corresponding to the other external side of the directional solidification mold, and also extend up the sides above the height of the bottom of the directional solidification mold. In another example, the material or materials that are included in the sides of the directional solidification mold can extend from a height of the internal-bottom of the directional solidification mold and upwards, while the material or materials that are included in the bottom of the directional solidification mold can extend vertically from the inner side of a side of the outer jacket across the inner-bottom of the outer jacket to the inner side of the opposite side of the outer jacket, or the material or material or materials that are included in the bottom of the directional solidification mold can extend vertically from in-between the inner side of a side of the outer jacket and the vertical position corresponding to the outer side of the directional solidification mold, across the bottom of the directional solidification mold, to in-between the opposite inner side of the outer jacket and the vertical position corresponding to the outer side of the opposite side of the directional solidification mold.

The insulating layer 4120 of apparatus 4100 shown in FIG. 16 can include an insulating material. The insulating material can be any suitable material. For example, the insulating material can be insulating brick, a refractory material, a mixture of refractory materials, insulating board, ceramic paper, high temperature wool, or a combination thereof. Insulating board can include high temperature ceramic board. The insulating layer can include more than one insulating material. The insulating material or materials that are included in the insulating layer 4120 can be blended, mixed, or they can be located in separate parts of the insulating layer, or a combination thereof. The one or more insulating materials can be arranged in layers. In one example, the insulating layer can include more than one layer of one or more insulating materials. In another example, the insulating layer can include one layer of one or more insulating materials. The sides of the insulating layer can be a different material than the bottom of the insulating layer. For example, the sides of the insulating layer as compared to the bottom of the insulating layer can be different thicknesses, include different compositions of material, or a combination thereof. In one embodiment, the insulating layer is disposed between the bottom of the directional solidification mold and the outer jacket. In a preferred embodiment, the insulating layer is disposed at least partially between the sides of the directional solidification mold and the sides of the outer jacket, and the insulating layer is not disposed between the bottom of the directional solidification mold and the bottom of the outer jacket, as depicted in FIG. 16.

The insulating layer 4120 of apparatus 4100 is shown in FIG. 16 disposed between the sides of the outer jacket of the apparatus and the sides of the directional solidification mold of the apparatus. As shown, the sides of the insulating layer extend from a height corresponding to the inner side of the bottom of the outer jacket and upwards. Embodiments of the directional solidification apparatus also can include configurations of the insulating layer 4120 in which the insulating layer extends from a height corresponding to the bottom of the inside of the directional solidification mold and upwards. In another example, the insulating layer extends from in-between the inner side of the bottom of the outer jacket and the height of the inner side of the bottom of the outer jacket and upwards. In another embodiment, the insulating layer extends from above the height corresponding to the bottom of the inside of the directional solidification mold and upwards.

The outer jacket 4130 of apparatus 4100 shown in FIG. 16 can include any suitable material to enclose the insulating layer and the directional solidification mold. The outer jacket can include one or more materials. In one embodiment, the outer jacket includes steel. In another embodiment, the outer jacket includes steel, stainless steel, copper, cast iron, a refractory material, a mixture of refractory materials, or a combination thereof. Different portions of the outer jacket can include different materials, different thicknesses of materials, different compositions of materials, or a combination thereof.

In some embodiments, the outer jacket can include structural members. The structural members can add strength and rigidity to the apparatus and can include any suitable material. For example, the structural members can include steel, stainless steel, copper, cast iron, a refractory material, a mixture of refractory materials, or a combination thereof. In one example, the outer jacket can include one or more structural members that extend from the outside of the outer jacket in a direction that is away from the center of the apparatus, and that extend horizontally around the circumference or perimeter of the apparatus. The one or more horizontal structural members can be located, for example, at the upper edge of the outside of the outer jacket, at the bottom edge of the outside of the outer jacket, at any position in-between the top and bottom edges of the outside of the outer jacket. In one example, the apparatus includes three horizontal structural members, with one located at the upper edge of the outer jacket, one located at the bottom edge of the outer jacket, and one located in-between the upper and lower edges of the outer jacket. The outer jacket can include one or more structural members on the outside of the outer jacket that extend from the outside of the of the outer jacket in a direction that is away from the center of the apparatus, and that extend vertically from the bottom of the outside of the outer jacket to the top of the outside of the outer jacket. In one example, the outer jacket can include eight vertical structural members. The vertical structural members can be evenly spaced around the circumference or perimeter of the outer jacket. In another example, the outer jacket includes both vertical and horizontal structural members. The outer jacket can include structural members that extend across the bottom of the outer jacket. The structural member on the bottom can extend from one outer edge of the bottom of the outer jacket to another edge of the bottom of the outer jacket. A structural members on the bottom can also extend partially across the bottom of the outer jacket. Structural members can be strips, bars, tubes, or any suitable structure for adding structural support to the apparatus. A structural member can be attached to the outer jacket via welding, brazing, or any other suitable method. The structural members can be adapted to facilitate transportation and physical manipulation of the apparatus. For example, the structural members on the bottom of the outside of the outer jacket can be tubes of sufficient size, strength, orientation, spacing, or a combination thereof, such that a particular fork-lift or other lifting machine could lift or move or otherwise physically manipulate the apparatus. In another embodiment, the structural members described above as being located on the outside of the outer jacket can alternatively or additionally be located on the inside of the outer jacket.

The outer jacket 4130 is shown in FIG. 16 as extending over the top of the insulating layer 4120 and partially covering the top of the directional solidification mold 4110. However, embodiments of the directional solidification apparatus also encompass a wide range of various structural configurations of the outer jacket 4130 with respect to the insulating layer 4120 and the directional solidification mold 4110. Embodiments can include an outer jacket 4130 extending completely to the inner rim of the top of the directional solidification mold 4110, the outer jacket 4130 extending only part way across the top of the insulating layer 4120, or the outer jacket 4130 not extending across any part of the insulating layer 4120. Also included are configurations in which the outer jacket 4130 does not extend fully up the side of the outside of the insulating layer. In an embodiment in which the outer jacket extends over any portion of the top of the directional solidification mold or the insulating layer, the portion of the outer jacket that extends over the top can include a material with greater insulating properties than the sides and bottom of the outer jacket. In some embodiments, such a choice of material can encourage formation of a desired temperature gradient in the apparatus.

The top edge of the apparatus 4100 shown in FIG. 16 is depicted with the directional solidification mold 4110 and the insulating layer 4120 at an approximately even height, and with the top of the outer jacket extending over the top of the insulating layer and partially over the top of the directional solidification layer. As discussed above, other configurations of the top of the outer jacket, the top of the insulating layer, and the top of the directional solidification mold are encompassed as embodiments of the directional solidification apparatus, including all suitable arrangements. For example, the insulating layer can extend vertically to a height above the top edge of the directional solidification mold. Alternatively, the directional solidification mold can extend vertically to a height above the top edge of the directional solidification mold. The insulating layer can extend partially or completely over the top edge of the directional solidification mold. Or, the directional solidification mold can extend partially or completely over the top edge of the insulating layer.

The apparatus 4100 shown in FIG. 16 is depicted with particular relative thicknesses of the directional solidification mold 4110, the insulating layer 4120, and the outer jacket 4130. However, embodiments of the directional solidification apparatus encompass any suitable relative thickness of the mold 4110, insulation 4120, and outer jacket 4130.

The apparatus 4100 in FIG. 16 can be used more than once to directionally solidify silicon. In being able to be used more than once, the apparatus can be reused for directional solidification with no repairs between uses, or with minimal repairs between uses. Minimal repairs can include touching up or reapplying entirely a coating that is part of the inner side of the directional solidification mold, for example repairing a top layer, including a slip-plane refractory coating. Embodiments of the directional solidification apparatus also include an apparatus that can be used more than twice for directional solidification of silicon. Also included are apparatus that can be used more than three, four, five, six, twelve, or more times, for the directional solidification of silicon.

In some embodiments the apparatus only includes a bottom mold. In other embodiments, the directional solidification apparatus includes both a bottom mold and a top heater.

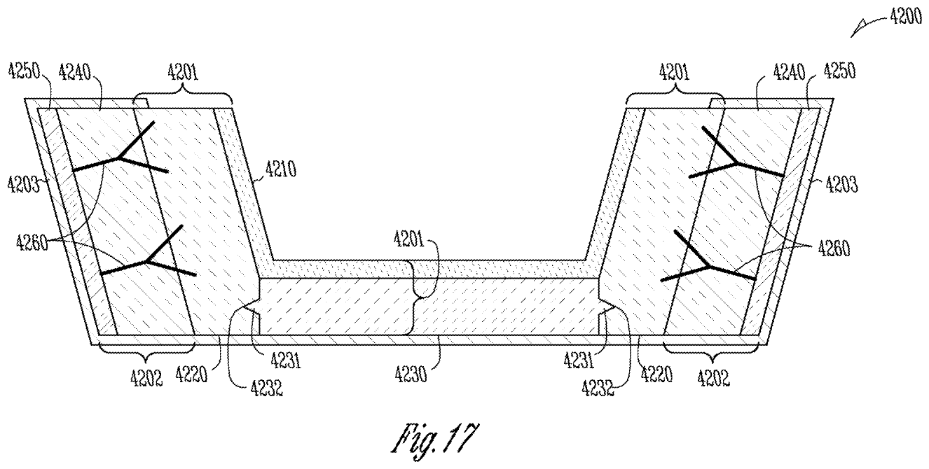

FIG. 17 illustrates an embodiment of the directional solidification apparatus. A side-view cut-away of the apparatus 4200 is shown. Apparatus 4200 includes a directional solidification mold 4201, which includes at least one refractory material. The at least one refractory material is configured to allow directional solidification of silicon within the mold. The apparatus 4200 also includes an outer jacket 4203. Additionally, the apparatus includes an insulating layer 4202, disposed at least partially between the directional solidification mold 4201 and the outer jacket 4203. The apparatus 4100 can be used more than once for the directional solidification of silicon.

The directional solidification mold 4201 shown in FIG. 17 includes one or more refractory materials. The sides of the directional solidification mold include a hot face refractory 4220. In FIG. 17, the hot face refractory 4220 of the directional solidification mold extends from the inside of the bottom of the outer jacket and upwards; as discussed above, various configurations of the sides of the directional solidification mold are encompassed as embodiments of the directional solidification apparatus. The hot face refractory 4220 can be any suitable refractory material. For example, the hot face refractory 4220 can be aluminum oxide.

In building embodiments of the bottom mold apparatus of the directional solidification apparatus, refractory materials can be applied in a manner similar to applying wet cement. A trawl or other suitable implement, including forms, can be used to manipulate the wet refractory into the desired shape, followed by allowing the refractory material to dry and set.

The bottom of the directional solidification mold 4201 shown in FIG. 17 includes a conducting refractory 4230. In FIG. 17, the conducting refractory 4230 of the directional solidification mold extends vertically in-between a vertical position corresponding to the outside of a side of the directional solidification mold and a vertical position corresponding to the inside of a side of the directional solidification mold, across the bottom of the directional solidification mold, to in-between the a vertical position corresponding to the outside of the opposite side of the directional solidification mold and a vertical position corresponding to the outside of the opposite side of the directional solidification mold; as discussed above, various configurations of the sides of the directional solidification mold are encompassed as embodiments of the directional solidification apparatus. The conducting refractory 4230 can be any suitable material. For example, the conducting refractory can contain silicon carbide. By placing a conducting material on the bottom of the apparatus, cooling of the bottom of molten silicon that is within the directional solidification mold is facilitated. Facile cooling of the bottom of the mold assists in forming and controlling a temperature gradient between the bottom and the top of the directional solidification mold, allowing the desired directional solidification to take place within the mold beginning at the bottom and ending at the top.

In an alternative embodiment, the bottom of the directional solidification mold can include any suitable heat-conducting material for element 4230, including silicon carbide, graphite, copper, steel, stainless steel, graphite, cast iron, or a combination thereof. As with the embodiment shown in FIG. 17, such an embodiment can include a top layer 4210. Alternatively, such an embodiment does not include a top layer 4210.

Conducting refractory 4230 is shown in FIG. 17 with an appendage member 4231 at its outer edge. The appendage member 4231 of the conducting refractory 4230 secures the conducting refractory into a receiving slot 4232 located in the hot face refractory 4220. Securing the hot face refractory to the conducting refractory prevents it from coming loose from the apparatus. In one embodiment, the appendage 4231 and the receiving slot 4232 are included. In another embodiment, they are not included. In other embodiments, alternative means of securing the conducting refractory are included.

The directional solidification mold 4201 shown in FIG. 17 also includes a top layer 4210. The top layer includes at least one slip-plane refractory material. The slip-plane refractory material can include any suitable refractory material. The slip-plane refractory material includes fused silicon dioxide, silicon dioxide, aluminum oxide, silicon nitride, graphite, or a combination thereof. The top layer 4210 is such that it protects the remainder of the directional solidification mold from damage when directionally solidified silicon is removed from the mold. For example, the remainder of the directional solidification mold 4201 in FIG. 17 is the hot face refractory 4220 and the conducting refractory 4230. The top layer 4210 can be of approximately consistent thickness and composition throughout, as shown in FIG. 17. In other embodiments, the top layer can have variable thickness or composition.

Alternatively, some portions of the top layer can be of approximately consistent thickness and composition, and other portions of the top layer can have variable thickness or composition. In protecting the remainder of the directional solidification mold from damage when the solid silicon is removed, and in facilitating the removal of the solid silicon, the top layer can become damaged in part or in full when the silicon is removed. The top layer can be replaced or repaired in-between one or more uses of the apparatus. The top layer can be applied in any suitable manner. The top layer can be applied as a spray, or brushed on. In another example the top layer can be applied using a trawl, and spread like wet cement. After application, the top layer can be allowed to dry and set. In some embodiments, colloidal silica can be used as a binder for the top layer, including for the slip plane refractory spray. The top layer can be heated before it is used to dry it out and prepare it for use.

The insulating layer 4202 of apparatus 4200 shown in FIG. 17 is disposed at least partially between the sides of the directional solidification mold 4201 and the outer jacket 4203. As shown in FIG. 17, the insulating layer of a specific embodiment extends from the inside of the bottom of the outer jacket and upwards. As discussed above, various configurations of the insulating layer are encompassed as embodiments of the directional solidification apparatus. The insulating layer 4202 shown in FIG. 17 includes two layers, inner layer 4240 and outer layer 4250. The layers 4240 and 4250 can include any suitable insulating material. In one embodiment, outer insulating layer 4250 includes ceramic paper and high temperature ceramic board. In one embodiment, outer insulating layer 4250 includes ceramic paper, high temperature wool, high temperature ceramic board, or a combination thereof. In one embodiment, inner insulating layer 4240 includes insulating brick or a refractory material, where the refractory material can include a castable refractory material.

The outer jacket 4203 of apparatus 4200 shown in FIG. 17 includes any suitable material. For example, outer jacket 4203 includes steel or stainless steel. In FIG. 17, the outer jacket is shown extending over the top of the outer layer 4250 and partially over the top of the inner layer 4240; as discussed above, various configurations of the insulating layer are encompassed as embodiments of the directional solidification apparatus.

The apparatus 4200 shown in FIG. 17 includes anchors 4260. The anchors can secure the refractory layers in the apparatus, to prevent them from loosening. For example, in FIG. 17, the anchors 4260 secure the hot face refractory 4220 to the inner layer 4240, and can help to secure the apparatus. In other embodiments, the anchors can be fixed in the outer jacket and can extend through any number of layers to secure them. In other embodiments, the anchors can start and end in any suitable layers. The anchors can include any suitable material. For example, the anchors can include steel, stainless steel, or cast iron. The anchors can be any suitable shape, and in any suitable orientation. By securing the apparatus with anchors 4260, with the appendage 4231 and slot 4232, with a combination thereof, or with an alternative means of securing, the apparatus can have a longer lifetime and can withstand more varied treatments with minimized damage. Additionally, securing the apparatus with anchors 4260, with the appendage 4231 and slot 4232, with a combination thereof, or with alternative securing means, can help to prevent the layers from falling out of the apparatus if the apparatus is inverted.

### Directional Solidification Apparatus—Top Heater

In one embodiment, the directional solidification apparatus also includes a top heater. The top heater can be positioned on top of the bottom mold. The shape of the bottom of the top heater approximately matches the shape of the top of the bottom mold. The top heater can apply heat to the top of the bottom mold, heating the silicon therein. Application of heat to the bottom mold can cause melting of silicon in the bottom mold. Additionally, application of heat to the bottom mold can allow control of the temperature of the silicon in the bottom mold. Also, the top heater can be positioned on top of the bottom mold without heating, serving as an insulator to control the release of heat from the top of the bottom mold. By controlling the temperature or release of heat of the top of the bottom mold, the desired temperature gradient can be more easily accomplished, which can allow a more highly controlled directional solidification. Ultimately, control over the temperature gradient can allow a more effective directional solidification in which the resulting purity of the silicon is maximized. In one embodiment, type B thermocouples can be used to monitor the temperature inside the furnace chamber.

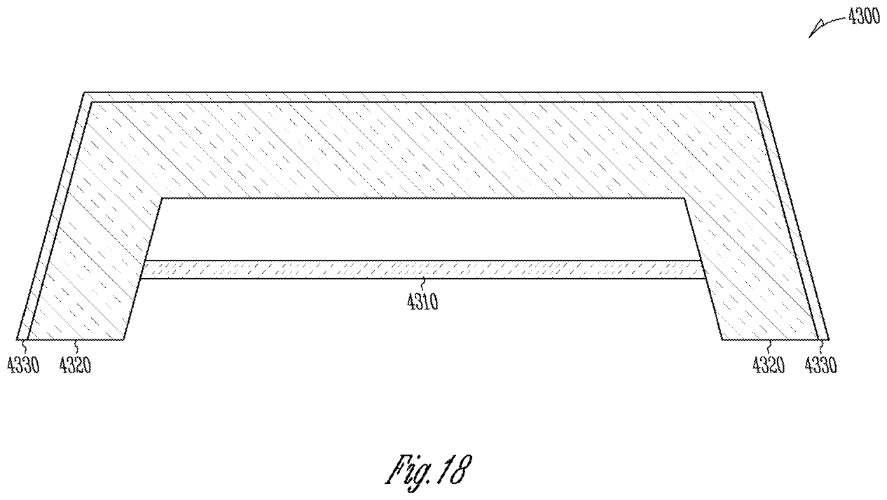

FIG. 18 illustrates a top heater 4300. The top heater can include one or more heating members 4310. Each of the one or more heating members can independently include any suitable material. For example, each of the one or more heating members independently can include a heating element, where the heating element can include silicon carbide, molybdenum disilicide, graphite, or a combination thereof; and, each of the one or more heating members can alternatively independently include an induction heater. In one embodiment, the one or more heating members are positioned at approximately the same height. In another embodiment, the one or more heating members are positioned at different heights.

In one example, the heating elements include silicon carbide, which has certain advantages. For example, silicon carbide heating elements do not corrode at high temperatures in the presence of oxygen. Oxygen corrosion can be reduced for heating elements including corrodible materials by using a vacuum chamber, but silicon carbide heating elements can avoid corrosion without a vacuum chamber. Additionally, silicon carbide heating elements can be used without water-cooled leads. In one embodiment, the heating elements are used in a vacuum chamber, with water-cooled leads, or both. In another embodiment, the heating elements are used without a vacuum chamber, without water-cooled leads, or without both.

In one embodiment, the one or more heating members are induction heaters. The induction heaters can be cast into one or more refractory materials. The refractory material containing the induction heating coil or coils can then be positioned over the bottom mold. The refractory material can be any suitable material. For example, the refractory material can include aluminum oxide, silicon oxide, magnesium oxide, calcium oxide, zirconium oxide, chromium oxide, silicon carbide, graphite, or a combination thereof. In another embodiment, the induction heaters are not cast into one or more refractory materials.

In one embodiment the one or more heating members have an electrical system such that if at least one heating member fails, any remaining functional heating members continue to receive electricity and to produce heat. In one embodiment, each heating member has its own circuit.

The top heater can include insulation, for example top heater 4300 shown in FIG. 18 includes insulation 4320. The insulation can include any suitable insulating material. The insulation can include one or more insulating materials. For example, the insulation can include insulating brick, a refractory, a mixture of refractories, insulating board, ceramic paper, high temperature wool, or a mixture thereof. Insulating board can include high temperature ceramic board. As shown in FIG. 18, the bottom edge of the insulating material and the one or more heating members 4310 are at approximately the same height. Other configurations of the one or more heating members and the insulation are encompassed as embodiments of the directional solidification apparatus. For example, the one or more heating members can include an induction heater, the insulation can include a refractory material, and the one or more heating members can be encased in the refractory material. In such an embodiment, additional insulating material can also be optionally included, where the additional insulation can be refractory material, or the additional insulation can be another suitable insulating material. In another example, the one or more heating members can include an induction heater, and the heating member can be positioned as the heating member is shown in FIG. 18, or in another configuration similarly not encased in refractory material. In another example, the one or more heating members can be positioned above the height of the bottom edge of the insulation. In another example, the bottom edge of the insulation can be positioned above the height of the one or more heating members. In an embodiment in which the one or more heating members are positioned at different heights, the edge of the insulation can be in-between the heights of the heating members, or in any other configuration as described above.

The top heater can include an outer jacket, for example top heater 300 shown in FIG. 18 includes outer jacket 4330. The outer jacket can include any suitable material. For example, the outer jacket can include steel or stainless steel. In another embodiment, the outer jacket includes steel, stainless steel, copper, cast iron, a refractory material, a mixture of refractory materials, or a combination thereof. The insulation 4320 is disposed at least partially between the one or more heating members and the outer jacket. In FIG. 18, the bottom edge of the outer jacket 4330 is shown to be approximately even with the bottom edge of the insulation and with the one or more heating members. However, as discussed with respect to the one or more heating members and the insulation above, various configurations of the outer jacket, the insulation, and the one or more heating members are encompassed as embodiments of the directional solidification apparatus. For example, the edge of outer jacket can extend below the edge of the insulation and the one or more heating members. In another example, the edge of the outer jacket can extend below the edge of the insulation, below the one or more heating members, or a combination thereof. In one example, the outer jacket can extend below the bottom edge of the insulation and continue across either fully or partially covering the bottom edge of the insulation. In some embodiments, the portion of the outer jacket that covers the edge of the insulation can include a material with a relatively low conductivity, such as a suitable refractory, such as aluminum oxide, silicon oxide, magnesium oxide, calcium oxide, zirconium oxide, chromium oxide, silicon carbide, graphite, or a combination thereof. In another example, the outer jacket does not extend below the bottom edge of the insulation or the height of the one or more heating members. In another embodiment, the outer jacket extends below the height of the one or more heating members, but is still above the bottom edge of the insulation. In an embodiment in which the one or more heating members are positioned at different heights, the outer jacket can extend to a height that is in-between the heights of the heating elements, or in any other configuration as described above.

In some embodiments, the top heater outer jacket can include structural members. The structural members can add strength and rigidity to the top heater. The structural members can include steel, stainless steel, copper, cast iron, a refractory material, a mixture of refractory materials, or a combination thereof. In one example, the top heater outer jacket can include one or more structural members that extend from outside of the top heater outer jacket in a direction that is away from the center of the top heater, and that extend horizontally around the circumference or perimeter of the top heater. The one or more horizontal structural members can be located, for example, at the lower edge of the outside of the top heater outer jacket, at the top edge of the outside of the top heater outer jacket, at any position in-between the bottom and top edges of the outside of the top heater outer jacket. In one example, the top heater includes three horizontal structural members, with one located at the bottom edge of the top heater outer jacket, one located at the upper edge of the top heater outer jacket, and one located in-between the lower and upper edges of the top heater outer jacket. The top heater outer jacket can include one or more structural members on the outside of the top heater outer jacket that extend for outside of the top heater outer jacket in a direction that is away from the center of the top heat vertically from the bottom of the outside of the top heater outer jacket to the top of the outside of the top heater outer jacket. In one example, the top heater outer jacket can include eight vertical structural members. The vertical structural members can be evenly spaced around the circumference or perimeter of the top heater. In another example, the top heater outer jacket includes both vertical and horizontal structural members. The top heater outer jacket can include structural members that extend across the top of the top heater outer jacket. The structural member on the top can extend from one outer edge of the top of the top heater outer jacket to another edge of the top of the top heater outer jacket. The structural members on the top can also extend partially across the top of the outer jacket. The structural members can be strips, bars, tubes, or any suitable structure for adding structural support to the top heater. The structural members can be attached to the top heater outer jacket via welding, brazing, or other suitable method. The structural members can be adapted to facilitate transportation and physical manipulation of the apparatus. For example, the structural members on the top of the outside of the top heater outer jacket can be tubes of sufficient size, strength, orientation, spacing, or a combination thereof, such that a particular fork-lift or other lifting machine could lift or move or otherwise physically manipulate the top heater. In another embodiment, the structural members described above as being located on the outside of the top heater outer jacket can alternatively or additionally be located on the inside of the top heater outer jacket. In another embodiment, the top heater can be moved using a crane or other lifting device, using chains attached to the top heater, including chains attached to structural members of the top heater or to non-structural members of the top heater. For example, four chains could be attached to the upper edge of the top heater outer jacket to form a bridle for a crane to lift and otherwise move the top heater.

### Directional Solidification Apparatus—Cooling

As discussed above, by controlling the temperature gradient in the apparatus, a highly controlled directional solidification can be accomplished. High degrees of control over the temperature gradient and the corresponding directional crystallization can allow a more effective directional solidification, providing a silicon of high purity. In various embodiments of the directional solidification apparatus, the directional crystallization proceeds from approximately bottom to top, thus the desired temperature gradient has a lower temperature at the bottom and a higher temperature at the top. In embodiments with a top heater, the top heater is one way to control the entry or loss of heat from the top of the directional solidification mold. Some embodiments of the directional solidification apparatus include a conducting refractory material in the directional solidification mold to induce heat loss from the bottom of the apparatus, while some embodiments also include insulating material on the sides of the directional solidification mold to prevent heat loss therefrom and to both encourage the formation of a vertical thermal gradient and to discourage the formation of a horizontal thermal gradient. In some methods of using the directional solidification apparatus, fans can be blown across the bottom of the apparatus, for example across the bottom of the outer jacket, to control heat loss from the bottom of the apparatus. In some methods of using the directional solidification apparatus, circulation of ambient air without the use of a fan is used to cool the apparatus, including the bottom of the apparatus.

In some embodiments of the directional solidification apparatus, one or more heat transfer fins can be attached to the bottom of the outer jacket to facilitate air cooling of the apparatus. Fans can enhance the cooling effect of cooling fins by blowing across the bottom of the outer jacket. Any suitable number of fins can be used. The one or more fins can absorb heat from the bottom of the apparatus and allow the heat to be removed by air cooling, facilitated by the surface area of the fin. For example, the fins can be made of copper, cast iron, steel, or stainless steel.

In some embodiments of the directional solidification apparatus, there is included at least one liquid conduit. The at least one liquid conduit is configured to allow a cooling liquid to pass through the conduit, thereby transferring heat away from the directional solidification mold. The cooling liquid can be any suitable cooling liquid. The cooling liquid can be one liquid. The cooling liquid can be a mixture of more than one liquid. The cooling liquid can include water, ethylene glycol, diethylene glycol, propylene glycol, an oil, a mixture of oils, or a combination thereof.

In some embodiments, the at least one liquid conduit includes a tube. The tube can include any suitable material. For example, the tube can include copper, cast iron, steel, stainless steel, a refractory material, a mixture of refractory materials, or a combination thereof. The at least one liquid conduit can include a conduit through a material. The conduit can be through any suitable material. For example, the conduit can be through a material that includes copper, silicon carbide, graphite, cast iron, steel, stainless steel, a refractory material, a mixture of refractory materials, or a combination thereof. The at least one liquid conduit can be a combination of a tube and a conduit through a material. In some embodiments, the at least one liquid conduit can be located adjacent to the bottom of the apparatus. The at least one liquid conduit can be located within the bottom of the apparatus. The location of the at least one liquid conduit can include a combination of being adjacent to the bottom of the apparatus and being within the bottom of the apparatus.

The liquid conduit included in some embodiments of the directional solidification apparatus encompasses a variety of configurations that allow a cooling liquid to transfer heat away from the directional solidification mold. A pump can be used to move the cooling liquid. A cooling system can be used to remove heat from the cooling liquid. For example, one or more tubes, including pipes, can be used. The one more tubes can be any suitable shape, including round, square, or flat. The tubes can be coiled. The tubes can be adjacent to the outside of the outer jacket. In preferred embodiments, the tubes can be adjacent to the bottom of the outside of the outer jacket. The tubes can contact the outer jacket such that sufficient surface area contact occurs to allow efficient transfer of heat from the apparatus to the cooling liquid. The tubes can contact the outer jacket in any suitable fashion, including along an edge of a tube. The tubes can be welded, brazed, soldered, or attached by any suitable method to the outside of the outer jacket. The tubes can be flattened to the outside of the outer jacket to enhance the efficiency of heat transfer. In some embodiments, the at least one liquid conduit is one or more conduits running through the bottom of the bottom mold. A conduit running through the bottom of the bottom mold can be a tube encased in a refractory that is included in the directional solidification mold. A tube can enter one part of the outer jacket, run through a refractory material or conductive material or a combination thereof at the bottom of the directional solidification mold, and exit another part of the outer jacket. A tube encased in the bottom refractory or bottom conductive material of the directional solidification mold can be coiled, or arranged in any suitable shape, including moving back and forth one or more times before exiting the bottom of the apparatus.

In another embodiment, the at least one liquid conduit includes a tube encased in a refractory material, a heat-conductive material, or a combination thereof, wherein the material is a block of material large enough for the apparatus to be placed on. The conduit can be through any suitable material. For example, the conduit can be through a material that includes copper, silicon carbide, graphite, cast iron, steel, stainless steel, a refractory material, a mixture of refractory materials, or a combination thereof. The cooling liquid can remove heat from the refractory material on which the bottom mold sits, thereby removing heat from the bottom of the apparatus.

### Directional Solidification Apparatus—General

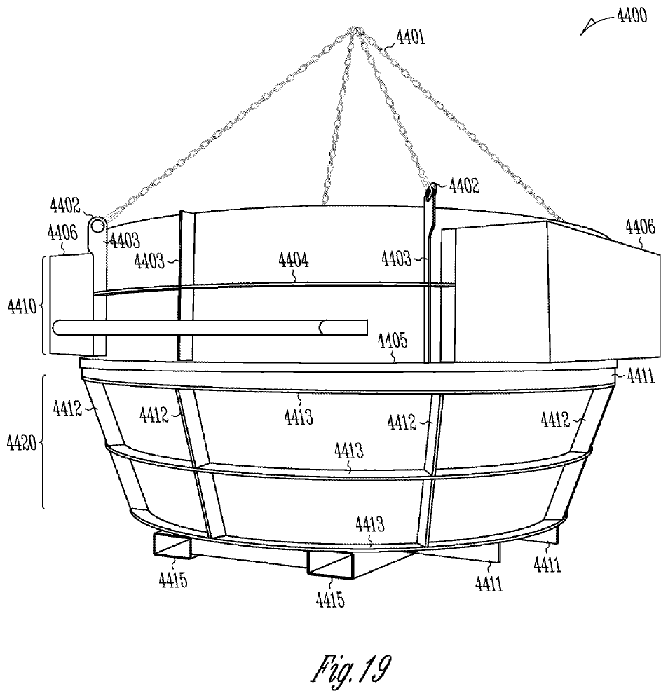

FIG. 19 illustrates a specific embodiment of an apparatus 4400 for directional solidification of silicon, including a top heater part positioned on top of a bottom mold 4420. The top heater includes chains 4401 which are connected to the top heater 4410 via holes 4402 in vertical structural members 4403. The chains 4401 form a bridle, which can allow the top heater to be moved by the use of a crane. The apparatus can also be moved, for example, by placing the bottom half of the apparatus on a scissor lift while leaving the top heater over the bottom half. The apparatus can be moved in any suitable fashion. The vertical structural members 4403 extend vertically from the bottom edge of the outer jacket of the top heater 4410 to the top edge of the stainless steel outer jacket of the top heater 4410. The vertical structural members are located on the outside of the top heater outer jacket and extend from the jacket parallel to a direction that is away from the center of the top heater. The top heater also includes a horizontal structural member 4404, which is located on the outside of the top heater outer jacket and extends from the jacket in a direction that is parallel to a direction that is away from the center of the top heater. The top heater also includes a lip 4405 that is part of the outer jacket of the top heater. The lip protrudes away from the outer jacket of the top heater. The lip can extend inward toward the center axis of the top heater such that it covers insulation of the top heater to any suitable extent. Alternatively, the lip can extend inward only enough to cover the bottom edge of the outer jacket of the top heater. Screen boxes 4406 enclose ends of the heating members that protrude from the outer jacket of the top heater, protecting users from the heat and electricity that can be present in and near the ends of these members.

In the specific embodiment depicted in FIG. 19, insulation 4411 from the bottom mold 4420 is between the top heater 4410 and the bottom mold 4420. At least part of the one or more insulating layers of the bottom mold extends above the height of the outer jacket of the bottom mold. The bottom mold includes vertical structural members 4412. The vertical structural members 4412 are on the outer surface of the outer jacket of the bottom mold, extending away from the outer jacket parallel to a direction that is away from the center of the bottom mold. The vertical structural members 4412 extend vertically from the bottom edge of the outer jacket to the top edge of the outer jacket. The bottom mold also includes horizontal structural members 4413. The horizontal structural members 4413 are on the outer surface of the outer jacket of the bottom mold, extending away from the outer jacket parallel to a direction that is away from the center of the bottom mold. The horizontal structural members 4413 extend horizontally around the circumference of the bottom mold. The bottom mold also includes bottom structural members 4414 and 4415. The bottom structural members 4414 and 4415 extend away from the outer jacket parallel to a direction that is away from the center of the bottom mold. The bottom structural members extend across the bottom of the bottom mold. Some of the bottom structural members 4415 are shaped such that they allow a forklift or other machine to lift or otherwise physically manipulate the apparatus.

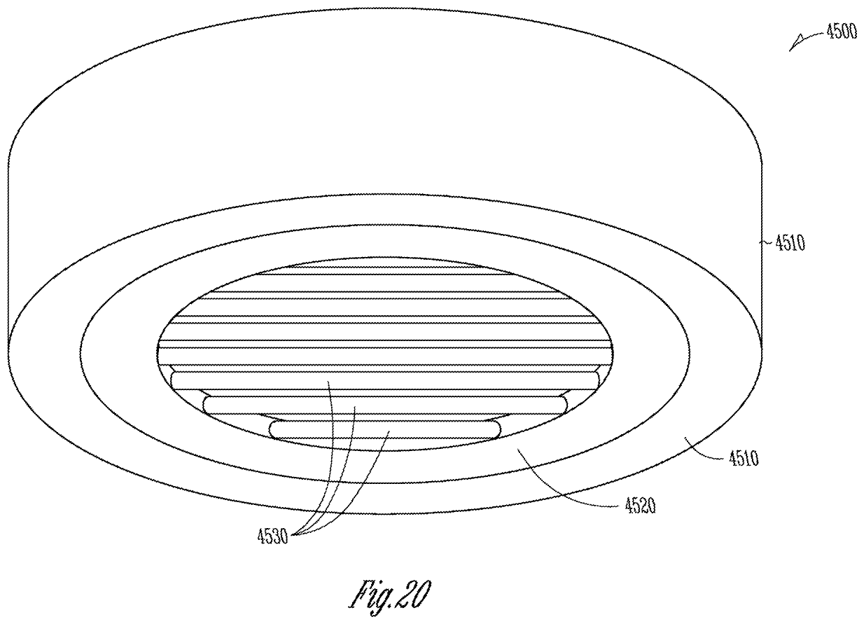

FIG. 20 illustrates a view towards the bottom of a top heater 4500, part of an embodiment of an apparatus for directional solidification of silicon. In this specific embodiment, the outer jacket extends over part of the insulating layer 4520 at the bottom edge of the top heater. The heating members 4530 are at equal heights, and the bottom edge of the outer jacket of the top heater 4510 and the insulation 4520 is below the height of the heating elements.

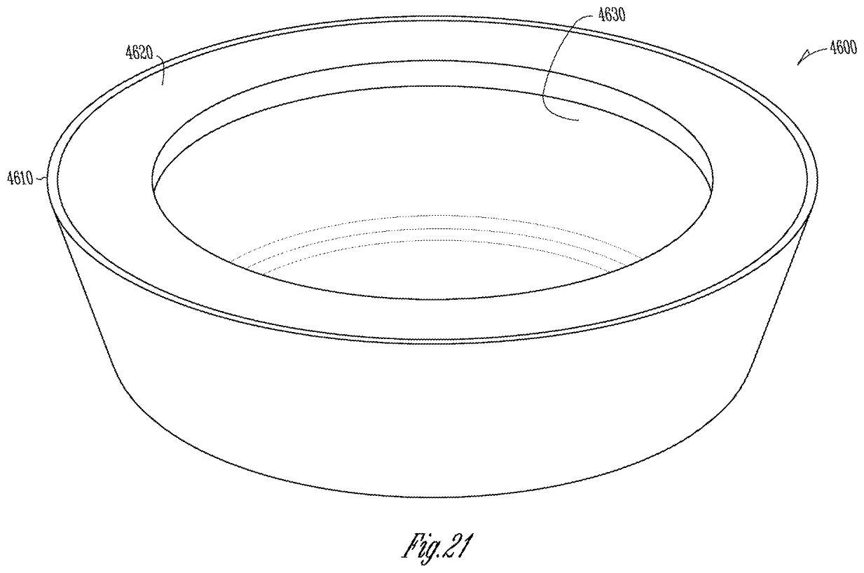

FIG. 21 illustrates a view towards the inside of the directional solidification mold of an embodiment of an apparatus 4600 for the directional solidification of silicon. In this specific embodiment, the edge of the outer jacket 4610 does not extend over the edge of the insulating layer 4620. Rather, the insulating layer 4620 extends over the top edge of the directional solidification mold 4630. The top edge of the directional solidification mold is below the height of the top edge of the insulation 4620 and the outer jacket 4610. The overall three-dimensional shape of the embodiment is similar to that of a large thick-walled bowl.

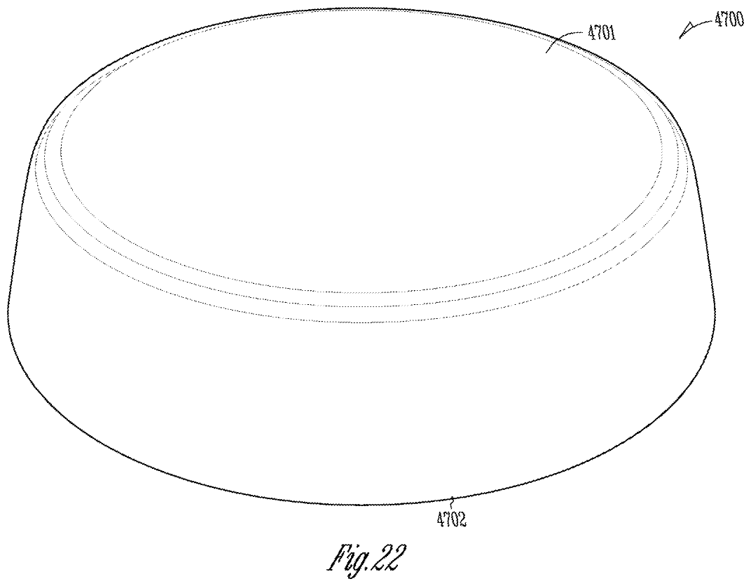

FIG. 22 illustrates a silicon ingot 4700 generated by embodiment of the method of the present invention using a directional solidification apparatus. The ingot is shown with the bottom of the ingot 4701 facing upwards, and the top of the ingot 4702 facing downwards. After being generated by directional crystallization in an embodiment of the directional solidification apparatus, ingot 4700 has the greatest amount of impurities in the last-to-freeze portion, at the top of the ingot 4702. Thus, in some embodiments, the top of the ingot 4702 is removed using, for example, a band saw, to increase the overall purity of the ingot 4700.

### Directional Solidification Apparatus—Method of Using

The present invention can include a method of purifying silicon using the directional solidification apparatus described herein, where the apparatus can be any embodiment of the apparatus. The directional solidification step of the present invention can be performed in any suitable apparatus, using any method, and the examples given herein of using particular embodiments of directional solidification apparatus in a certain way are only one example of performing the directional solidification step. The method of using the directional solidification apparatus described herein can be any suitable method. In one embodiment, the method can include providing or receiving a first silicon. The first silicon can include silicon of any suitable grade of purity. The method can include at least partially melting the first silicon. The method can include fully melting the first silicon. At least partially melting the first silicon can include completely melting the first silicon, almost completely melting the first silicon (over about either 99%, 95%, 90%, 85%, or 80% melted by weight), or partially melting the first silicon (less than about 80% or less melted by weight). Melting the first silicon can provide a first molten silicon. The method can include providing or receiving a directional solidification apparatus. The directional solidification apparatus can be substantially similar to that described above. The method can include directionally solidifying the first silicon, to provide a first molten silicon. In some embodiments, the silicon directionally solidifies approximately starting at the bottom of the directional solidification mold, and approximately ending at the top of the directional solidification mold. The directional solidification can provide a second silicon. The last-to-freeze portion of the second silicon includes a greater concentration of impurities than the first silicon. The portions of the second silicon other than the last-to-freeze portion can include a lower concentration of impurities than the first silicon.

In some embodiments, the second silicon can be a silicon ingot. The silicon ingot can suitable for cutting into solar wafers, for the manufacture of solar cells. The silicon ingot can be cut into solar wafer using, for example, a band saw, a wire saw, or any suitable cutting device.

In some embodiments, the method is performed in a vacuum, in an inert atmosphere, or in ambient air. To perform the method in a vacuum or in an inert atmosphere, the apparatus can be placed in a chamber that is capable of being made a less than atmospheric pressure or of being filling with an atmosphere with a greater concentration of inert gases than ambient air. In some embodiments, argon can be pumped into the apparatus or into a chamber holding the apparatus, to displace oxygen from the apparatus.

In some embodiments, the method includes positioning the top heater described above over the directional solidification mold. The bottom mold, including the directional solidification mold, can be preheated before molten silicon is added. The top heater can be used to preheat the bottom mold.

Preheating the bottom mold can help to prevent excessive quick solidification of silicon on the walls of the mold. The top heater can be used to melt the first silicon. The top heater can be used to transfer heat to the silicon, after it is melted. The top heater can transfer heat to the silicon after it is melted when the silicon is melted in the directional solidification mold. The top heater can be used to control the heat of the top of the silicon. The top heater can be used as an insulator, to control the amount of heat loss at the top of the bottom mold. The first silicon can be melted outside the apparatus, such as in a furnace, and then added to the apparatus. In some embodiments, silicon that is melted outside the apparatus can be further heated to a desired temperature using the top heater after being added to the apparatus.

In directional solidification apparatus that include a top heater including an induction heater, the silicon can be melted prior to being added to the bottom mold. Alternatively, the top heater can include heating elements as well as induction heaters. Induction heating can be more effective with molten silicon. Induction can cause mixing of the molten silicon. In some embodiments, the power can adjusted sufficiently to optimize the amount of mixing, as too much mixing can improve segregation of impurities, but can also create undesirable porosity in the final silicon ingot, such as if too great a quantity of small air bubbles are introduced into the molten silicon.

The directional solidification can include the removal of heat from the bottom of the directional solidification apparatus. The removal of heat can occur in any suitable fashion. For example, the removal of heat can include blowing fans across the bottom of the directional solidification apparatus. The removal of heat can include allowing ambient air to cool the bottom of the apparatus, without the use of fans. The removal of heat can include running a cooling liquid through tubes adjacent to the bottom of the apparatus, though tubes that run through the bottom of the apparatus, through tubes that run through a material on which the apparatus sits, or a combination thereof. Removal of heat from the bottom of the apparatus allows a thermal gradient to be established in the apparatus that causes directional solidification of the molten silicon therein approximately from the bottom of the directional solidification mold to the top of the mold.

Removal of heat from the bottom of the apparatus can be performed for the entire duration of the directional solidification. Multiple cooling methods can be used. For example, the bottom of the apparatus can be liquid cooled and cooled with fans. Fan cooling can occur for part of the directional solidification, and liquid cooling for another, with any suitable amount of overlap or lack thereof between the two cooling methods. Cooling with liquid can occur for part of the directional solidification, and ambient air cooling alone for another part, with any suitable amount of overlap or lack thereof between the two cooling methods. Cooling by setting the apparatus on a cooled block of material can also occur for any suitable duration of the directional solidification, including in any suitable combination with other cooling methods with any suitable amount of overlap. Cooling of the bottom can be performed while heat is being added to the top; for example, while heat is added to the top to increase the temperature of the top, to maintain the temperature of the top, or to allow a particular rate of cooling of the top. All suitable configurations and methods of heating the top of the apparatus, cooling the bottom, and combinations thereof, with any suitable amount of temporal overlap or lack thereof, are encompassed as embodiments of methods of using the directional solidification apparatus to perform the directional solidification step.

The directional solidification can include using the top heater to heat the silicon to at least about 1450° C., and slowly cooling the temperature of the top of the silicon from approximately 1450 to 1410° C. over approximately 10 to 16 hours. The directional solidification can include using the top heater to heat the silicon to at least about 1450° C., and holding the temperature of the top of the silicon approximately constant at between approximately 1425 and 1460° C. for about 10-20 hours, or approximately 14 hours. The directional solidification can include turning off the top heater, allowing the silicon to cool for approximately 4-12 hours, and then removing the top heater from the directional solidification mold.

In one embodiment, the directional solidification includes using the top heater to heat the silicon to at least about 1450° C., and holding the temperature of the top of the silicon approximately constant at between approximately 1425 and 1460° C. for approximately 14 hours. The embodiment can include turning off the top heater, allowing the silicon to cool for approximately 4-12 hours, and then removing the top heater from the directional solidification mold.

In another embodiment, the directional solidification includes using the top heater to heat the silicon to at least about 1450° C., and slowly cooling the temperature of the top of the silicon from approximately 1450 to 1410° C. over approximately 10 to 16 hours. The embodiment includes turning off the top heater, allowing the silicon to cool for approximately 4-12 hours, and then removing the top heater from the directional solidification mold.

The method can include removing the second silicon from the directional solidification apparatus. The silicon can be removed by any suitable method. For example, the silicon can be removed by inverting the apparatus and allowing the second silicon to drop out of the directional solidification mold. In another example, the directional solidification apparatus is parted down the middle to form two halves, allowing the second silicon to be easily removed from the mold.

The method can include removing any suitable section from the directionally solidified second silicon. Preferably, the removal of the suitable section leads to an increase in the overall purity of the silicon ingot. For example, the method can include removing from the directionally solidified second silicon at least part of the last-to-freeze section. Preferably, the last-to-freeze section of the directionally solidified silicon is the top of the ingot, as it is oriented during the bottom-to-top directional solidification. The greatest concentration of impurities generally occurs in the last-to-freeze section of the solidified silicon. Removing the last-to-freeze section thus can remove impurities from the solidified silicon, resulting in a trimmed-second silicon with a lower concentration of impurities than the first silicon. The removal of a section of the silicon can include cutting the solid silicon with a band saw. The removal of a section of the silicon can include shot blasting or etching. Shot blasting or etching can also be used generally to clean or remove any outer surface of the second silicon, not just the last-to-freeze portion. Removing a suitable section from the directionally solidified section can also include removal of impurities from the surface of the silicon using blasting, as described below.

The method of the present invention can optionally include a blasting step, wherein a suitable media is blasted on the surface of the solid silicon to remove impurities therefrom. Blasting can be performed with any suitable media. The method of accelerating the media to high velocity to blast it against the surface of the media can be any suitable method of acceleration. In some embodiments, the media causes abrasion of the surface of the silicon sufficient to remove surface impurities therefrom. In some embodiments, the abrasion may also remove some silicon from the solid silicon, but by also removing surface impurities from the silicon and thereby increasing the average purity of the overall volume of silicon being blasted, a slight loss of silicon is acceptable. Any suitable volume of media can be used for blasting. The blasting can occur at any suitable rate. The blasting can occur for any suitable duration of time. In some embodiments, the blasting can be performed in a suitable chamber to help prevent the media from spreading around the environment in which the blasting occurs.

In one embodiment, a suitable media for blasting includes sand. The sand can be any suitable sand. In another embodiment, a suitable media for blasting includes solid carbon-dioxide, also called dry ice. The dry ice can be ground to any suitable size. Dry ice can be advantageous because it leaves very little or no residual material after the dry ice has sublimed to a gas phase. In some embodiments, dry ice blasting can be used after sand blasting to eliminate particulate matter that can remain after sand blasting.

In various embodiments, the method of accelerating the media to high velocity to blast it against the surface of the media can include the use of pressurized air. The pressurized air can escape from an orifice at high velocity and be used to carry along a suitable media at high velocity toward the silicon, allowing the media to blast the silicon.

### Purified Silicon

The silicon purified by the methods described herein can be pure enough such that the silicon is adequate for formation of solar cells. The silicon purified by the methods described herein can be suitable for use in photovoltaic devices and can contain less boron than phosphorous in ppmw. In some embodiments, it is advantageous to have a higher boron level than phosphorous level in the UMG if the boron level is low enough because it allows the blending of the UMG with polysilicon from the Siemens process and achievement of a higher yield and cell efficiency. Polysilicon from the Siemens process generally has boron and phosphorous levels below about 0.1 ppmw. Blending the UMG with polysilicon having boron and phosphorus levels lower than the UMG reduces the average phosphorus and boron level in the blended UMG/polysilicon. Therefore, the multicrystalline ingot made from UMG silicon with higher boron than phosphorous levels can have P/N junctions closer to the surface in the multicrystalline ingot than a multicrystalline ingot made from UMG silicon with lower boron than phosphorous levels. If the boron level is low enough and the phosphorous level is less than the boron level, it is possible to not have a P/N junction at all. UMG silicon that has higher levels of phosphorous than boron tends to have a P/N junction deeper and further from the surface in the multicrystalline ingot which limits the yield of useful material from the ingot. It can be advantageous in some embodiments if the boron content is lower than about 0.7 ppmw because a higher minimum resistivity can then be obtained at and near the bottom of a multicrystalline ingot grown from the UMG or blended UMG. UMG silicon that has higher levels of either boron and/or phosphorous than 0.7 ppmw is usually compensated to increase the resistivity of the wafers to improve cell efficiencies. UMG silicon that has higher levels of either boron and/or phosphorous than 0.3 ppmw can be compensated to increase the resistivity of the wafers to improve cell efficiencies. Compensation improves average cell efficiency but tends to prevent UMG from having comparable cell efficiencies to polysilicon from the Siemens process due to reduced carrier mobility and increased recombination via mechanisms such as Auger Recombination. The purified silicon with lower phosphorous than boron levels can also be processed into solar cells without blending with polysilicon. In some embodiments, it is possible to not add any dopant, either boron or phosphorous, with solar silicon made from embodiments of the process. Purified UMG silicon made from metallurgical processes with boron less than the phosphorous in ppmw, boron less than 0.7 ppmw, and other metallic impurities less than 1 ppmw can be used to make solar cells.

In some examples, purified UMG silicon made from a metallurgical process with a phosphorous level of about 0.2 ppmw and a boron level of about 0.5 ppmw with other impurities less than 1 ppmw can produce average cell efficiencies between 15.0 and 15.5%. With current standard cell processes purified UMG silicon made from a metallurgical process with a phosphorous level of about 0.40 ppmw and a boron level of about 0.45 ppmw with other impurities less than 0.2 ppmw can produce average cell efficiencies between 15.5 and 16.3% with optimized cell architectures. UMG silicon with a phosphorous level of 2.5 ppmw and a boron level of 1.0 ppmw and other metals below the detection limit for glow discharge mass spectrometer (GDMS), a standard cell line without special processes for UMG can produce cells with efficiency between 14.3-15.0%. Thus, it can be beneficial that the level of phosphorous is less than the level of boron, because of resulting acceptable resistivities and high enough carrier mobility to get good average cell efficiencies.

### EXAMPLES

The present invention can be better understood by reference to the following examples which are offered by way of illustration. The present invention is not limited to the examples given herein.

### Example 1

A single pass mother liquor A was mixed with MG-Si or other silicon feed stock. A molten mixture SP (single pass) B was cooled to grow silicon crystals “SP flakes B” and SP mother liquor B. SP mother liquor B and SP flakes B were separated. The SP mother liquor B was sold as a byproduct to aluminum foundry, die-cast and secondary smelting industry. The mixture was about 40% silicon and 60% aluminum. The mixture was melted to about the liquidus temperature. The mixture was heated to above about 950° C. The mixture was cooled to about 720° C. The mixture yielded about 32% flakes by weight. Cooling took place over about 15 hours. About 2,200 kg or more was used as a batch size.

Double pass (DP) mother liquor B was mixed with MG-Si or other source of silicon. A molten mixture SP A was cooled to grow silicon crystals SP flakes A and SP mother liquor A. The SP mother liquor A and SP flakes A were separated.

The SP A flakes and/or SP B flakes and DP mother liquor A were mixed.

Molten mixture 3 “DP B” was cooled to grow silicon crystals DP flakes B and DP mother liquor B. The DP mother liquor B and DP flakes B were separated.

The SP A flakes and/or SP B flakes and mother liquor TP were mixed. Molten mixture 4 “DP A” was cooled to grow silicon crystals DP flakes A and DP mother liquor A. The DP mother liquor A and DP flakes A were mixed.

The DP A flakes and/or DP B flakes and aluminum were mixed. Molten mixture 5 “TP” was slowly dropped in temperature to grow silicon crystals TP flakes A and TP mother liquor. The TP mother liquor and TP flakes were separated.

The aluminum was dissolved off of TP flakes using HCl and the flakes were placed in plastic baskets with water and HCl and reacted with progressively stronger HCl to dissolve the aluminum into polyaluminum chloride. The polyaluminum chloride was sold as a byproduct for waste or drinking water treatment. The reaction was done between 50-90° C. using heat from the exothermic reaction of the HCl with the aluminum. The flakes were rinsed with water after the HCl reaction. The flakes were dried to remove any traces of the rinsewater.

Any powder or any remaining aluminum and/or foreign contaminate were mechanically removed. The flakes were vibrated over a screen or grate and a bag house was used to pull silicon powder away from flakes. A series of grates was used to separate the flakes from powder balls, refractory contamination, or other foreign objects. The powdered silicon was sold as a byproduct.

The flakes were melted with slag into the molten silicon. The slag was a mixture of NaCO₃+CaO+SiO₂ at 7% by weight of the silicon. The slag can be skimmed off the surface of the bath before pouring. The silicon can be poured through a ceramic foam filter.

A 1.5 ton ingot was directionally solidified from bottom to top. A top heater was used and more thermally conductive bottom than side insulation used on the mold. A fan was used to cool the bottom of the mold. The top can be cut off with a band saw or circular saw with a diamond coated blade. The top can be poured off while it is still liquid. Top or last-to-freeze silicon can be broken off with chunking from mechanical blows or by thermal quenching. The ingot can be blasted with Al₂O₃ media to clean the surface. The top of the last-to-freeze silicon was cut off. The directional solidification and last-to-freeze removal processes were repeated two times.

In one embodiment, the process can produce purified silicon with boron levels less than 0.75, aluminum levels less than 1.0, phosphorous levels less than 0.8 and other metallic element levels totaling less than 1 ppmw. In another embodiment, the process can produce purified silicon with boron levels less than 0.5, aluminum levels less than 0.5, phosphorous levels less than 0.5, metal levels less than 0.25 ppmw and other element levels totaling less than 1 ppmw.

Phosphorous or other N-type dopants can be added to increase the resistivity of the silicon to 0.30 or greater ohm/cm. The process can be used to produce more than 20 tons per month. Other metallic impurities can include one or more of magnesium, titanium, manganese, iron, cobalt, nickel, copper, zince, molybdenum, cadmium, tin, tungsten, lead and uranium.

Silicon from the process, such as last-to-freeze silicon, spills, or scrap can be recycled in the process by placing them back in the process at the same step or an earlier step.

The silicon produced from the process was tested with SIMS (secondary ion mass spectrometry) and had Ca<0.0001, AkO.OI, P 0.172, B 0.623, C 5.205 and O 3.771 pppmw. The silicon was tested with GDMS and had B 0.77, Al 0.22, P 0.26 ppmw and all other tested elements below detection limit. The phosphorous level is lower than boron in ppmw in the purified silicon.

### Example 2

A SP mother liquor A was mixed with MG-Si or other source of silicon.

A molten mixture “SP B” was dropped in temperature to grow silicon crystals “SP flakes B” and SP mother liquor B. The SP mother liquor B and SP flakes B were separated.

A DP mother liquor was mixed with MG-Si or other source of silicon. A molten mixture “SP A” was cooled to grow silicon crystals “SP flakes A” and SP mother liquor A. The SP mother liquor A and SP flakes A were separated.

The SP A flakes and/or SP B flakes were mixed with aluminum. A molten mixture “DP” was slowly dropped in temperature to grow silicon crystals “DP flakes A” and DP mother liquor. The DP mother liquor and DP flakes were separated.

Aluminum was dissolved off of DP flakes using HCl. Powder and any remaining aluminum and/or foreign contaminate were mechanically removed. The flakes were melted with slag and gas was injected with oxygen into the molten silicon.

The silicon was directionally solidified. The top of the last-to-freeze silicon was cut off. Directional solidification and removal of last-to-freeze silicon was repeated two times. In one embodiment, this process produced purified silicon with P 0.29, B 1.2 and Al less than 0.01 ppmw as measured by SIMS. In another embodiment, this process produced purified silicon with P 0.40, B 0.88 and Al less than 0.01 ppmw as measured by SIMS.

This process with 2 directional solidifications produced purified silicon with P 0.40, B 0.40 and Al 0.86 ppmw as measured by SIMS. The process can reduce the aluminum level below the detection limit of GDMS with only 2 directional solidifications.

### Example 3

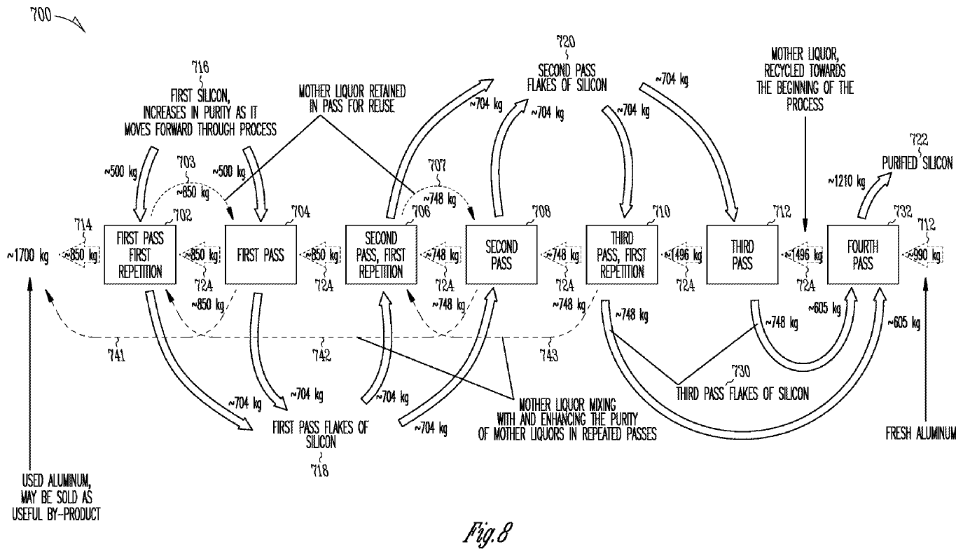

FIG. 8 shows an embodiment of the present invention as a quad pass cascade, performed with four furnaces to produce quad pass silicon flakes 722 with less than 0.52 ppmw Boron. The single pass furnace has a holding capacity of 10,000 kg. For the first pass 704, 2,200 kg of molten 60% aluminum and 40% silicon (850 kg mother liquor 724 from the second pass, 850 kg reused mother liquor 703 from the first repetition of the first pass 702, and 500 kg silicon 716) is poured into a container which can hold the molten mixture where it is allowed to cool for approximately 16 hours, this produces about 704 kg first pass flakes 718 of silicon. Optional gas containing chlorine can be added to the molten mixture before cooling. About 50% of the liquid mother liquor 741 is poured off into sow moulds to be sold for making aluminum foundry alloys as a by-product. The other 50% of the mother liquor 724 (from the first pass 704) or 850 kg is poured back in liquid form or added as solid sows back into the same single pass furnace for the first repetition of the first pass 702. Also 850 kg of second pass mother liquor 742 as liquid or solid is added into the single pass furnace for the first repetition of the first pass 702, along with 500 kg silicon 716. This produces approximately 704 kg of single pass silicon flakes 718 when the molten bath is cooled to grow flakes. For each 2,200 kg batch, 500 kg of metallurgical grade silicon or scrap silicon 716 is added into the furnace. The scrap silicon, silicon purified from another process or metallurgical silicon can have a boron level of approximately less than 5 ppmw. This step is done twice (e.g., the first pass 704 and the first repetition of the first pass 702) in each complete cycle to have balanced amounts of mother liquor and flakes in the process.

Next, in the double pass furnace which has a holding capacity of 10,000 kg, for the second pass 708, 704 kg of single pass flakes 718 are melted with 1,496 kg of mother liquor, 50% mother liquor from a double pass heat (about 748 kg, 724, from second pass 708) and 50% mother liquor from a triple pass heat (about 748 kg, 743) that has been used twice in the triple pass furnace. This produces 704 kg of double pass flakes 720. The mother liquors can be added to the furnaces in liquid or solid form. Half of the 1496 kg mother liquor is used 724 (from second pass 708) for the first repetition of the second pass 706, and the other half of the mother liquor 742 is used to enhance the purity of the mother liquor in the first repetition of the first pass 702. After the repetition of the second pass 706, half of the mother liquor 707 is reused in the second pass 708, and the other half 724 (from repetition of second pass 706) is used in the first pass 704. Scrap silicon can be added to the furnace instead of single pass flakes 718 and can have a boron level less than 2.1 ppmw. As in the first pass, this step is done twice in each complete cycle (e.g., second pass 708, and first repetition of the second pass 706) but can be done 1 or more times to adjust the mass balances and number of times the mother liquor is used.

Next, the triple pass furnace is used which has a holding capacity of 2,200 kg. For the third pass 712, 704 kg of double pass flakes 720 are melted with 1,496 kg of quad pass mother liquor 724. This produces 704 kg of triple pass flakes 730 and 1,496 kg of triple pass mother liquor 724 that has been used once. The triple pass mother liquor 724 (from third pass 712) is completely reused in the same furnace for the first repetition of the third pass 710 with 704 kg of double pass flakes 720. This produces 704 kg of triple pass flakes 730 and 1,496 kg of triple pass mother liquor (724 (from first repetition of the third pass 710) and 743) that has been used twice. Instead of using double pass flakes 720, scrap silicon can be used with boron level less than 1.3 ppmw.

Next, the quad pass furnace is used which has a holding capacity of 2,200 kg. 1,210 kg of triple pass flakes 730 are melted with 990 kg of aluminum 712 containing less than 0.80 ppmw boron. This produces quad pass mother liquor 724 and quad pass flakes 722. Scrap silicon can be used instead of triple pass flakes for this step with boron less than 0.80 ppmw.

Each step can be done by reusing the mother liquor or some percentage of the mother liquor one or more times. It will be clear to one of skill in the art that by adjusting the number of repetitions of the steps, by adjusting the amount of mother liquor recycled, and by adjusting the amount and source of silicon added in each step, the mass balance for the cascade 700 can be evenly balanced. The mother liquor can be used no times in a step and skipped to a lower step.

Scrap silicon, metallurgical silicon or silicon purified by another method can be added at any step of the process instead of flakes for silicon units. The flake generation step can be done 2 or more times, this example shows 4 passes and 7 crystallizations in the cycle. The process can be done in difference size furnaces with different batch sizes. The ratio of silicon to aluminum can be adjusted in each step from 20-70%.

The quad pass flakes 722 are processed in HCl and water and the aluminum level is reduced to around 1000-3500 ppmw. The polyaluminum chloride that is produced can be sold as a by-product for purifying water. The quad pass flakes are then melted in a furnace where they are reacted with slag. Optionally the molten silicon can be filtered or have gases injected in it before directional solidification. Optionally the molten aluminum-silicon mixtures or mother liquors can be filtered.

The molten silicon is then directional solidified and the last to freeze section is removed. The silicon is then directionally solidified again and some portion of the last to freeze silicon is removed. Gas or compounds containing chlorine can be added to the any of the passes before growing the crystals. This process results in purified silicon with B less than 0.45 ppmw, P less than 0.60 ppmw and Al less than 0.50 ppmw. This silicon can be used to make ingots and wafers for making photovoltaic cells with high efficiency above 15.5%. This silicon can be blended with other scrap silicon or silicon purified using other methods to make a feedstock making photovoltaic ingots, wafers and cells. Examples of the purity of silicon purified in the manner of this example are given in the tables below.

TABLE 2
Bulk Analysis of B in Si
Detection limit <0.001 ppmw

| | B | B | | |
|---|---|---|---|---|
| | concentration | concentration | | |
| | (at/cm³) | (at/cm³) | Average | |
| Sample | Analysis 1 | Analysis 2 | (at/cm³) | ppmw |
| 1 | 5.20 × 10¹⁶ | 5.30 × 10¹⁶ | 5.25 × 10¹⁶ | 0.41 |
| 2 | 5.57 × 10¹⁶ | 5.60 × 10¹⁶ | 5.59 × 10¹⁶ | 0.44 |
| 3 | 5.15 × 10¹⁶ | 5.20 × 10¹⁶ | 5.18 × 10¹⁶ | 0.41 |

TABLE 3
Bulk Analysis of P in Si
Detection limit <0.003 ppmw

| | P | P | | |
|---|---|---|---|---|
| | concentration | concentration | | |
| | (at/cm³) | (at/cm³) | Average | |
| Sample | Analysis 1 | Analysis 2 | (at/cm³) | ppmw |
| 1 | 1.78 × 10¹⁶ | 1.78 × 10¹⁶ | 1.78 × 10¹⁶ | 0.39 |
| 2 | 2.36 × 10¹⁶ | 2.40 × 10¹⁶ | 2.38 × 10¹⁶ | 0.53 |
| 3 | 2.70 × 10¹⁶ | 2.68 × 10¹⁶ | 2.69 × 10¹⁶ | 0.60 |

TABLE 4
Bulk analysis of Al in Si

| | Al | Al | | |
|---|---|---|---|---|
| | concentration | concentration | | |
| | (at/cm³) | (at/cm³) | Average | |
| Sample | Analysis 1 | Analysis 2 | (at/cm³) | ppmw |
| 1 | 2.15 × 10¹⁶ | 2.10 × 10¹⁶ | 2.13 × 10¹⁶ | 0.41 |
| 2 | 1.22 × 10¹⁶ | 1.25 × 10¹⁶ | 1.24 × 10¹⁶ | 0.24 |
| 3 | 1.93 × 10¹⁶ | 1.99 × 10¹⁶ | 1.96 × 10¹⁶ | 0.38 |

### Example 4

Silicon carbide resistance elements were used in a top heater insulated with high temperature wool insulation and a steel shell. Molten silicon (1.4 tonnes) was poured into a refractory-lined preheated bottom section of the apparatus. The apparatus had aluminum oxide refractory walls including a draft to allow the silicon to be dumped out after cooling. The walls of the refractory were coated with a thin slip-plane of aluminum oxide refractory and then a second layer of SSi₃N₄ powder. The bottom of the directional solidification mold was made from silicon carbide refractory and the outside of the steel shell was cooled with fans blowing air on the bottom of the outer shell. The heaters were set at 1450° C. for 14 hrs and then the elements were turned off. Six hours later the top heater section was removed and the silicon was allowed to cool to room temperature. The mold was flipped over. The 1.4 tonne ingot was cut in half and the top 25% of the ingot was cut off to remove impurities. The grains were about 1-2 cm in width and 3-10 cm in height, forming columns in the vertical direction similar to a standard ingot from the Bridgeman process.

### Example 5

Silicon carbide resistance elements were used in a top heater insulated with high temperature wool insulation and a steel shell. Molten silicon (0.7 tonnes) was poured into a refractory-lined preheated bottom section of the apparatus. The apparatus had aluminum oxide refractory walls including a middle parting line to remove the silicon ingot. The walls of the refractory were coated with a thin slip-plane of SiO₂ refractory. The bottom of the directional solidification mold was made from graphite and the outside of the steel shell was cooled with fans blowing air on the bottom of the outer shell. The heaters were set at 1450° C. for 12 hours and then the elements were turned off. Six hours later the top heater section was removed and the silicon was allowed to cool to room temperature. The mold was opened at the parting line. The 0.7 tonne ingot was cut in half and the top 15% of the ingot was cut off to remove impurities. The grains were about 1 cm in width and 3-10 cm in height, forming columns in the vertical direction similar to a standard ingot from the Bridgeman process.

The terms and expressions which have been employed are used as terms of description and not of limitation, and there is no intention that in the use of such terms and expressions of excluding any equivalents of the features shown and described or portions thereof, but it is recognized that various modifications are possible within the scope of the invention claimed. Thus, it should be understood that although the present invention has been specifically disclosed by preferred embodiments and optional features, modification and variation of the concepts herein disclosed may be resorted to by those skilled in the art, and that such modifications and variations are considered to be within the scope of this invention as defined by the appended claims.

### ADDITIONAL EMBODIMENTS

The present invention provides for the following exemplary embodiments, the numbering of which is not to be construed as designating levels of importance:

Embodiment 1 provides a method for purification of silicon, including: recrystallizing starting material-silicon from a molten solvent including aluminum to provide final recrystallized-silicon crystals; washing the final recrystallized-silicon crystals with an aqueous acid solution to provide a final acid-washed-silicon; and, directionally solidifying the final acid-washed-silicon to provide final directionally solidified-silicon crystals.

Embodiment 2 provides the method of embodiment 1, further including sand blasting or ice blasting the final directionally solidified-silicon crystals to provide sand- or ice-blasted final directionally solidified-silicon crystals, wherein the average purity of the sand- or ice-blasted final directionally solidified-silicon crystals is greater than the average purity of the final directionally solidified-silicon crystals.

Embodiment 3 provides the method of any one of embodiments 1-2, further including removing a portion of the final directionally solidified-silicon crystals to provide a trimmed final directionally solidified-silicon crystals, wherein the average purity of the trimmed final directionally solidified-silicon crystals is greater than the average purity of the final directionally solidified-silicon crystals.

Embodiment 4 provides the method of any one of embodiments 1-3, wherein the recrystallization of starting material-silicon includes: contacting the starting material-silicon with a solvent metal including the aluminum, sufficient to provide a first mixture; melting the first mixture, sufficient to provide a first molten mixture; cooling the first molten mixture, sufficient to form the final recrystallized-silicon crystals and a mother liquor; and, separating the final recrystallized-silicon crystals and the mother liquor, to provide the final recrystallized-silicon crystals.

Embodiment 5 provides the method of any one of embodiments 1-4, wherein the recrystallization of starting material-silicon includes: contacting the starting material-silicon with a first mother liquor, sufficient to provide a first mixture; melting the first mixture, sufficient to provide a first molten mixture; cooling the first molten mixture, sufficient to form first silicon crystals and a second mother liquor; separating the first silicon crystals and the second mother liquor, to provide the first silicon crystals; contacting the first silicon crystals with a first solvent metal including the aluminum, sufficient to provide a second mixture; melting the second mixture, sufficient to provide a second molten mixture; cooling the second molten mixture, sufficient to form the final recrystallized-silicon crystals and the first mother liquor; and, separating the final recrystallized-silicon crystals and the first mother liquor, to provide the final recrystallized-silicon crystals.

Embodiment 6 provides the method of any one of embodiments 1-5, wherein the recrystallization of starting material-silicon includes: contacting the starting material-silicon with a second mother liquor, sufficient to provide a first mixture; melting the first mixture, sufficient to provide a first molten mixture; cooling the first molten mixture to form first silicon crystals and a third mother liquor; separating the first silicon crystals and the third mother liquor, to provide the first silicon crystals; contacting the first silicon crystals and a first mother liquor, sufficient to provide a second mixture; melting the second mixture, sufficient to provide a second molten mixture; cooling the second molten mixture to form second silicon crystals and the second mother liquor; separating the second silicon crystals and the second mother liquor, to provide the second silicon crystals; contacting the second silicon crystals with a first solvent metal including the aluminum, sufficient to provide a third mixture; melting the third mixture, sufficient to provide a third molten mixture; cooling the third molten mixture to form the final recrystallized-silicon crystals and the first mother liquor; and separating the final recrystallized-silicon crystals and the first mother liquor, to provide the final recrystallized-silicon crystals.

Embodiment 7 provides the method of any one of embodiments 1-6, wherein the washing of the final recrystallized-silicon includes: combining the final recrystallized-silicon with an acid solution sufficiently to allow the final recrystallized-silicon to react at least partially with the acid solution, to provide a first mixture; and, separating the first mixture, to provide the final acid-washed silicon.

Embodiment 8 provides the method of any one of embodiments 1-7, wherein the washing of the final recrystallized-silicon includes: combining the final recrystallized-silicon with an acid solution sufficiently to allow the final recrystallized-silicon to react at least partially with the acid solution, to provide a first mixture; separating the first mixture, to provide an acid-washed silicon and the acid solution; combining the acid-washed silicon with a rinse solution, to provide a fourth mixture; separating the fourth mixture, to provide a wet purified silicon and the rinse solution; and drying the wet purified silicon, sufficient to provide the final acid-washed-silicon.

Embodiment 9 provides the method of any one of embodiments 1-8, wherein the washing of the final recrystallized-silicon includes: combining the final recrystallized-silicon with a weak acid solution sufficiently to allow the first complex to react at least partially with the weak acid solution, to provide a first mixture; separating the first mixture, to provide a third silicon-aluminum complex and the weak acid solution; combining the third silicon-aluminum complex with a strong acid solution sufficiently to allow the third complex to react at least partially with the strong acid solution, to provide a third mixture; separating the third mixture, to provide a first silicon and the strong acid solution; combining the first silicon with a first rinse solution, to provide a fourth mixture; separating the fourth mixture, to provide a wet purified silicon and the first rinse solution; and drying the wet purified silicon, sufficient to provide the final acid-washed-silicon.

Embodiment 10 provides the method of embodiment 9, further including: separating the first mixture, to provide a second silicon-aluminum complex and the weak acid solution; combining the second silicon-aluminum complex with a medium acid solution sufficiently to allow the second complex to react at least partially with the medium acid solution, to provide a second mixture; and separating the second mixture, to provide a third silicon-aluminum complex and the medium acid solution.

Embodiment 11 provides the method of any one of embodiments 9-10, further including: separating the fourth mixture, to provide a second silicon and the first rinse solution; combining the second silicon with a second rinse solution, to provide a fifth mixture; and separating the fifth mixture, to provide the wet silicon and the second rinse solution.

Embodiment 12 provides the method of any one of embodiments 1-11, wherein the washing of the final recrystallized-silicon includes: combining the final recrystallized-silicon with a weak HCl solution sufficiently to allow the first complex to react at least partially with the weak HCl solution, to provide a first mixture; separating the first mixture, to provide a third silicon-aluminum complex and the weak HCl solution; combining the third silicon-aluminum complex with a strong HCl solution sufficiently to allow the third complex to react at least partially with the strong HCl solution, to provide a third mixture; separating the third mixture, to provide a first silicon and the strong HCl solution; combining the first silicon with a first rinse solution, to provide a fourth mixture; separating the fourth mixture, to provide a wet purified silicon and the first rinse solution; drying the wet purified silicon, sufficient to provide the final acid-washed-silicon; removing portions of the weak HCl solution from the weak HCl solution to maintain the pH and specific gravity of the weak HCl solution; transferring portions of strong HCl solution to the weak HCl solution to maintain the pH of the weak HCl solution, the volume of the weak HCl solution, the specific gravity of the medium HCl solution, or a combination thereof; adding portions of a bulk HCl solution to the strong HCl solution to maintain the pH of the strong HCl solution, the volume of the strong HCl solution, the specific gravity of the strong HCl solution, or a combination thereof; transferring portions of the first rinse solution to the strong HCl solution to maintain the pH of the strong HCl solution, the volume of the strong HCl solution, the specific gravity of the strong HCl solution, or a combination thereof; adding fresh water to the second rinse solution to maintain the volume of the second rinse solution.

Embodiment 13 provides the method of any one of embodiments 1-12, wherein the washing of the final recrystallized-silicon includes: combining the final recrystallized-silicon with a weak HCl solution sufficiently to allow the first complex to react at least partially with the weak HCl solution, to provide a first mixture; separating the first mixture, to provide a second silicon-aluminum complex and weak HCl solution; combining the second silicon-aluminum complex with a medium HCl solution sufficiently to allow the second complex to react at least partially with the medium HCl solution, to provide a second mixture; separating the second mixture, to provide a third silicon-aluminum complex and a medium HCl solution; combining the third silicon-aluminum complex with a strong HCl solution sufficiently to allow the third complex to react at least partially with the strong HCl solution, to provide a third mixture; separating the third mixture, to provide a first silicon and a strong HCl solution; combining the first silicon with a first rinse solution, to provide a fourth mixture; separating the fourth mixture, to provide a second silicon and a first rinse solution; combining the second silicon with a second rinse solution, to provide a fifth mixture; separating the fifth mixture, to provide a wet purified silicon and a second rinse solution; drying the wet purified silicon, sufficient to provide the final acid-washed-silicon; removing portions of the weak HCl solution from the weak HCl solution to maintain the pH and specific gravity of the weak HCl solution; transferring portions of medium HCl solution to the weak HCl solution to maintain the pH of the weak HCl solution, the volume of the weak HCl solution, the specific gravity of the weak HCl solution, or a combination thereof; transferring portions of strong HCl solution to the medium HCl solution to maintain the pH of the medium HCl solution, the volume of the medium HCl solution, the specific gravity of the medium HCl solution, or a combination thereof; adding portions of a bulk HCl solution to the strong HCl solution to maintain the pH of the strong HCl solution, the volume of the strong HCl solution, the specific gravity of the strong HCl solution, or a combination thereof; transferring portions of the first rinse solution to the strong HCl solution to maintain the pH of the strong HCl solution, the volume of the strong HCl solution, the specific gravity of the strong HCl solution, or a combination thereof; transferring portions of the second rinse solution to the first rinse solution to maintain the volume of the first rinse solution; adding fresh water to the second rinse solution to maintain the volume of the second rinse solution.

Embodiment 14 provides the method of any one of embodiments 1-13, wherein the directional solidification of the final acid-washed-silicon includes two sequential directional solidifications, to provide the final directionally solidified-silicon crystals.

Embodiment 15 provides the method of any one of embodiments 1-14, wherein the directional solidification of the final acid-washed-silicon includes performing a directional solidification of the final acid-washed-silicon in a crucible including: an interior for the production of an ingot, wherein the ingot includes a multiplicity of blocks; and, an exterior shape approximately matching the interior shape of a furnace wherein the molten material that solidifies to form the ingot is produced.

Embodiment 16 provides the crucible of embodiment 15, wherein the blocks include a grid, wherein compared to a grid in a square-shaped crucible, the percentage of side or center blocks relative to the percentage of corner blocks is increased.

Embodiment 17 provides the crucible of any one of embodiments 15-16, wherein the perimeter of the crucible includes approximately eight major sides, wherein the eight sides include two sets of approximately opposing first sides of approximately equal length, and two sets of approximately opposing second sides of approximately equal length, wherein the first sides alternate with the second sides.

Embodiment 18 provides the method of any one of embodiments 1-17, wherein the directional solidification of the final acid-washed-silicon includes performing a directional solidification of the final acid-washed-silicon using a crucible including: an interior for the production of an ingot; an exterior shape approximately matching the interior shape of a furnace wherein molten material that solidifies to form the ingot is produced; wherein the ingot includes a multiplicity of blocks; wherein the multiplicity of blocks include a grid; wherein the exterior shape matching the interior shape of the furnace allows the generation of a larger number of blocks than the number of blocks that can be generated from the furnace using a crucible with a square shape; wherein the interior shape of the furnace includes an approximately round shape; and, wherein the perimeter of the crucible includes approximately eight major sides, wherein the eight sides include two sets of approximately opposing longer sides of approximately equal length, and two sets of approximately opposing shorter sides of approximately equal length, wherein the longer sides alternate with the shorter sides.

Embodiment 19 provides the method of any one of embodiments 1-18, wherein the directional solidification of the final acid-washed-silicon includes performing a directional solidification of the final acid-washed-silicon in an apparatus including: a directional solidification mold including at least one refractory material; an outer jacket; and an insulating layer disposed at least partially between the directional solidification mold and the outer jacket.

Embodiment 20 provides the method of any one of embodiments 1-19, wherein the directional solidification of the final acid-washed-silicon includes: providing a directional solidification apparatus, wherein the apparatus includes a directional solidification mold including at least one refractory material; an outer jacket; and an insulating layer disposed at least partially between the directional solidification mold and the outer jacket; at least partially melting the final acid-washed-silicon to provide a first molten silicon; and directionally solidifying the first molten silicon in the directional solidification mold to provide a second silicon.

Embodiment 21 provides the method of embodiments 20, further including positioning a heater over the directional solidification mold, including positioning one or more heating members selected from a heating element and an induction heater over the directional solidification mold.

Embodiment 22 provides the method of any one of embodiments 1-21, wherein the directional solidification of the final acid-washed-silicon includes performing a directional solidification of the final acid-washed-silicon using an apparatus including: a directional solidification mold including a refractory material; a top layer, including a slip-plane refractory, the top layer configured to protect the remainder of the directional solidification mold from damage when directionally solidified silicon is removed from the mold; an outer jacket, including steel; an insulating layer, including insulating brick, a refractory material, a mixture of refractory materials, insulating board, ceramic paper, high temperature wool, or a mixture thereof, the insulating layer disposed at least partially between one or more side walls of the directional solidification mold and one or more side walls of the outer jacket; wherein one or more side walls of the directional solidification mold include aluminum oxide, wherein a bottom of the directional solidification mold includes silicon carbide, graphite, or a combination thereof; and a top heater, including one or more heating members, each of the heating members including a heating element or an induction heater; wherein the heating element includes silicon carbide, molybdenum disilicide, graphite, or a combination thereof; insulation, including insulating brick, a refractory, a mixture of refractories, insulating board, ceramic paper, high temperature wool, or a combination thereof; and an outer jacket, including stainless steel; wherein the insulation is disposed at least partially between the one or more heating members and the top heater outer jacket, wherein the apparatus is configured to be used more than twice for the directional solidification of silicon.

Embodiment 23 provides the apparatus or method of any one or any combination of embodiments 1-22 optionally configured such that all elements or options recited are available to use or select from.

What is claimed is:

1. A method for purification of silicon, comprising:
recrystallizing starting material silicon from solvent metal comprising aluminum, wherein the recrystallizing comprises:
contacting the starting material silicon with the solvent metal comprising the aluminum;
if necessary, melting the starting material silicon and the solvent metal comprising the aluminum to provide a first molten mixture; and
cooling the first molten mixture to form recrystallized silicon crystals;
washing the recrystallized silicon crystals with aqueous acid, the washing comprising:
combining the recrystallized silicon crystals with a first acid solution having a first acid concentration to provide a first wash mixture to allow the recrystallized silicon crystals to react at least partially with the first acid solution to form a first silicon-aluminum complex;
separating the first silicon-aluminum complex from the first wash mixture;
combining the separated first silicon-aluminum complex with a second acid solution having a second acid concentration to provide a second wash mixture to allow the first silicon-aluminum complex to react at least partially with the second acid solution to form a first silicon, wherein the second acid concentration is higher than the first acid concentration;
separating the first silicon from the second wash mixture to provide an acid-washed silicon:
combining the acid-washed silicon with a first rinse solution to provide a first rinse mixture; and
separating silicon from the first rinse mixture to provide a purified silicon; and
directionally solidifying the purified silicon to provide a directionally solidified silicon, wherein directionally solidifying the purified silicon comprises performing a directional solidification of the purified silicon in a top-heater crucible comprising:
a steel shell including an outer surface;
a bottom comprising silicon carbide refractory or graphite;
refractory walls comprising (i) a thin slip-plane of aluminum oxide refractory and a layer of Si₃N₄ powder, or (ii) a thin slip-plane of SiO₂ refractory; and
an interior for the production of an ingot, wherein the interior comprises a draft for dumping the solidified silicon from the top-heater crucible after cooling or a middle parting line for removing the solidified silicon.

2. The method of claim 1, further comprising sand blasting or ice blasting the directionally solidified silicon to provide sand- or ice-blasted silicon, wherein the average purity of the sand- or ice-blasted silicon is greater than the average purity of the directionally solidified silicon.

3. The method of claim 1, further comprising removing a portion of the directionally solidified silicon to provide a trimmed silicon, wherein the average purity of the trimmed silicon is greater than the average purity of the directionally solidified silicon.

4. The method of claim 1, wherein cooling the mixture, sufficient to form comprises forming first silicon crystals and a second mother liquor, wherein the recrystallizing further comprises:
separating the first silicon crystals from the second mother liquor;
contacting the separated first silicon crystals with a first solvent metal comprising the aluminum to provide a second mixture;
melting the second mixture to provide a second molten mixture;
cooling the second molten mixture to form the recrystallized silicon crystals and a first mother liquor; and
separating the recrystallized silicon crystals from the first mother liquor,
wherein at least a portion of the solvent metal in the step of contacting the starting material silicon with the solvent metal comprises the first mother liquor.

5. The method of claim 1, wherein cooling the first molten mixture comprises forming first silicon crystals and a third mother liquor, wherein the recrystallizing further comprises:
separating the first silicon crystals from the third mother liquor;
contacting the separated first silicon crystals and a first mother liquor to provide a second mixture;
melting the second mixture to provide a second molten mixture;
cooling the second molten mixture to form second silicon crystals and a second mother liquor;
separating the second silicon crystals from the second mother liquor;
contacting the second silicon crystals with a first solvent metal comprising the aluminum to provide a third mixture;
melting the third mixture to provide a third molten mixture;
cooling the third molten mixture to form the recrystallized silicon crystals and the first mother liquor; and
separating the recrystallized silicon crystals from the first mother liquor,
wherein at least a portion of the solvent metal in the step of contacting the starting material silicon with the solvent metal comprises the first mother liquor.

6. The method of claim 1, further comprising:
prior to directionally solidifying the purified silicon, drying the purified silicon.

7. The method of claim 1, further comprising:
prior to combining the first silicon-aluminum complex with the second acid solution, combining the first silicon-aluminum complex with a third acid solution having a third acid concentration to provide a third wash mixture to allow the first silicon-aluminum complex to react at least partially with the third acid solution to form a third silicon-aluminum complex, wherein the third acid concentration is higher than the first acid concentration and lower than the second acid concentration; and
separating the third silicon-aluminum complex from the third acid solution,
wherein the separated third silicon-aluminum complex is combined with the second acid solution to form the second wash mixture.

8. The method of claim 1, further comprising:
prior to combining the acid-washed silicon with the with the first rinse solution,
combining the separated first silicon with a second rinse solution to provide a second rinse mixture; and
separating the first silicon from the second rinse mixture, to provide the acid-washed silicon that is combined with the first rinse solution to provide the first rings mixture.

9. The method of claim 1, wherein the first acid solution comprises a first HCl solution having a first HCl concentration and the second acid solution comprises a second HCl solution having a second HCl concentration that is higher than the first HCl concentration, wherein the washing of the recrystallized silicon crystals further comprises:
after separating the first silicon from the second wash mixture and before combining the acid-washed silicon with the first rinse solution, combining the first silicon with a third HCl solution to provide a third wash mixture, wherein the third HCl solution comprises a third HCl concentration that is higher than the first HCl concentration and the second HCl concentration, and wherein the first silicon reacts at least partially with the third HCl solution, to form a second silicon;
separating the second silicon from the third wash mixture, to provide a first silicon and the strong HCl solution the acid-washed silicon that is combined with the first rinse solution to provide the first rinse mixture;
wherein after separating the purified silicon from the first rinse mixture the purified silicon is wet, the method further comprising;
drying the wet purified silicon to provide a dried purified silicon, wherein directionally solidifying the purified silicon comprises directionally solidifying the dried purified silicon;
removing a portion of the first HCl solution to maintain the pH and specific gravity of the first HCl solution;
transferring a portion of the third HCl solution to the first HCl solution to maintain the pH of the first HCl solution, the volume of the first HCl solution, the specific gravity of the first HCl solution, or a combination thereof;
adding a portion of a bulk HCl solution to the third HCl solution to maintain the pH of the third HCl solution, the volume of the third HCl solution, the specific gravity of the third HCl solution, or a combination thereof;
transferring a portion of the first rinse solution to the third HCl solution to maintain the pH of the third HCl solution, the volume of the third HCl solution, the specific gravity of the third HCl solution, or a combination thereof; and
adding fresh water to the first rinse solution to maintain the volume of the first rinse solution.

10. A method for purification of silicon, the method comprising:
recrystallizing starting material silicon from solvent metal comprising aluminum, wherein the recrystallizing comprises:
contacting the starting material silicon with a molten solvent comprising the aluminum to provide a first mixture;
melting the first mixture to provide a first molten mixture; and
cooling the first molten mixture to form recrystallized silicon crystals;
washing the recrystallized silicon crystals, wherein the washing comprises:
combining the silicon crystals with a first HCl solution having a first HCl concentration;
allowing the recrystallized silicon crystals to react at least partially with the first HCl solution, to provide a first silicon-aluminum complex in a first wash mixture;
separating the first silicon aluminum complex and from the first wash mixture;
combining the first silicon-aluminum complex with a second HCl solution having a second HCl concentration that is higher than the first HCl concentration;
allowing the first silicon-aluminum complex to react at least partially with the second HCl solution, to provide a second silicon-aluminum complex in a second wash mixture;
separating the second silicon-aluminum complex from the second wash mixture;
combining the second silicon-aluminum complex with a third HCl solution having a third HCl concentration that is higher than the first HCl concentration and the second HCl concentration;
allowing the second silicon-aluminum complex to react at least partially with the third HCl solution, to provide a first silicon in a third wash mixture;
separating the first silicon from the third wash mixture;
combining the first silicon with a first rinse solution, to provide a second silicon in a first rinse mixture;
separating the second silicon from the first rinse mixture;
combining the second silicon with a second rinse solution, to provide a purified silicon in a second rinse mixture; and
separating the purified silicon from the second rinse mixture; and
wherein the washing further comprises at least one of:
removing a portion of the first HCl solution to maintain a pH of the first HCl solution, a volume of the first HCl solution, a specific gravity of the first HCl solution, or a combination thereof;
transferring a portion of the second HCl solution to the first HCl solution to maintain the pH of the first HCl solution, the volume of the first HCl solution, the specific gravity of the first HCl solution, or a combination thereof;
transferring a portion of the third HCl solution to the second HCl solution to maintain a pH of the second HCl solution, a volume of the second HCl solution, a specific gravity of the second HCl solution, or a combination thereof;
adding a portion of a bulk HCl solution to the third HCl solution to maintain a pH of the third HCl solution, a volume of the third HCl solution, a specific gravity of the third HCl solution, or a combination thereof;
transferring a portion of the first rinse solution to the third HCl solution to maintain the pH of the third HCl solution, the volume of the strong third HCl solution, the specific gravity of the third HCl solution, or a combination thereof; transferring a portion of the second rinse solution to the first rinse solution to maintain a volume of the first rinse solution; or
adding fresh water to the second rinse solution to maintain a volume of the second rinse solution; and
directionally solidifying the purified silicon to provide a directionally solidified silicon, wherein directionally solidifying the purified silicon comprises performing a directional solidification of the purified silicon in a top-heater crucible comprising:
a steel shell including an outer surface;
a bottom comprising silicon carbide refractory or graphite;
refractory walls comprising (i) a thin slip-plane of aluminum oxide refractory and a layer of Si₃N₄ powder, or (ii) a thin slip-plane of SiO₂ refractory; and
an interior for the production of an ingot, wherein the interior comprises a draft for dumping the solidified silicon from the top-heater crucible after cooling or a middle parting line for removing the solidified silicon.

11. The method of claim 1, wherein directionally solidifying the purified silicon comprises two sequential directional solidifications.

12. The method of claim 1, wherein the bottom comprises silicon carbide refractory, the refractory walls comprise a thin slip-plane of aluminum oxide refractory and a layer of Si₃N₄ powder, and the interior comprises a draft for dumping the solidified silicon from the top-heater crucible after cooling.

13. The method of claim 1, wherein the bottom comprises graphite, the refractory walls comprise a thin slip-plane of SiO₂ refractory, and the interior comprises a middle parting line for removing the solidified silicon.

14. The method of claim 1, wherein directionally solidifying the purified silicon comprises performing a directional solidification of the purified silicon in an apparatus comprising:
a directional solidification mold including at least one refractory material;
an outer jacket; and
an insulating layer disposed at least partially between the directional solidification mold and the outer jacket.

15. The method of claim 1, wherein directionally solidifying the purified silicon comprises:
at least partially melting the purified silicon to provide a first molten silicon; and
directionally solidifying the first molten silicon in a directional solidification mold to provide the directionally solidified silicon.

16. The method of claim 15, wherein directionally solidifying the purified silicon further comprises positioning a heater over the directional solidification mold.

17. The method of claim 10, further comprising drying the purified silicon to provide a dried purified silicon, wherein the dried purified silicon is directionally solidified to provide the directionally solidified silicon.

18. The method of claim 10, further comprising removing a portion of the directionally solidified silicon to provide a trimmed silicon, wherein the average purity of the trimmed silicon is greater than the average purity of the directionally solidified silicon.

19. The method of claim 10, further comprising sand blasting or ice blasting the directionally solidified silicon to provide sand- or ice-blasted silicon, wherein the average purity of the sand- or ice-blasted silicon is greater than the average purity of the directionally solidified silicon.

20. The method of claim 10, wherein directionally solidifying the purified silicon comprises:
at least partially melting the purified silicon to provide a first molten silicon; and
directionally solidifying the first molten silicon in a directional solidification mold to provide the directionally solidified silicon.
